(19) United States
(12) Patent Application Publication
(10) Pub. No.: US 2025/0255174 A1
(43) Pub. Date: Aug. 7, 2025

(54) LIGHT-EMITTING DEVICE, ELECTRONIC APPARATUS INCLUDING THE SAME, AND ORGANOMETALLIC COMPOUND

(71) Applicant: Samsung Electronics Co., Ltd., Suwon-si (KR)

(72) Inventors: Jong Soo Kim, Suwon-si (KR); Daun Jeong, Hwaseong-si (KR); Yeonkyung Lee, Suwon-si (KR); Hwang Suk Kim, Suwon-si (KR); Minsik Min, Suwon-si (KR); Hyejin Bae, Suwon-si (KR); Joonghee Won, Suwon-si (KR); Yeon Sook Chung, Suwon-si (KR); Hyesung Choi, Suwon-si (KR); Joon Heo, Suwon-si (KR)

(21) Appl. No.: 19/013,983

(22) Filed: Jan. 8, 2025

(30) Foreign Application Priority Data
Feb. 1, 2024 (KR) 10-2024-0016219

(51) Int. Cl. H10K 85/30; C09K 11/06; H10K 85/40; H10K 85/60; H10K 101/10

(52) U.S. Cl. CPC H10K 85/346; C09K 11/06; H10K 85/40; H10K 85/633; H10K 85/654; H10K 85/656; H10K 85/6572; H10K 85/6574; H10K 85/658; H10K 2101/10

(57) ABSTRACT

A light-emitting device including a first electrode, a second electrode facing the first electrode, and an interlayer arranged between the first electrode and the second electrode including an emission layer. The interlayer includes an organometallic compound represented by Formula 1 and satisfying Condition 1:

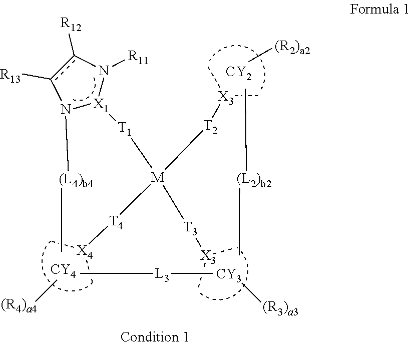

a minimum value of interior angles of an imaginary triangle including three atoms Y₁ to Y₃ as vertexes in the organometallic compound is less than 39°. Detailed descriptions of Formula 1 and Condition 1 are provided herein.

### CROSS-REFERENCE TO RELATED APPLICATION

This application is based on and claims priority to Korean Patent Application No. 10-2024-0016219, filed on Feb. 1, 2024, in the Korean Intellectual Property Office and all benefits accruing therefrom under 35 U.S.C. § 119, the content of which is herein incorporated by reference in its entirety.

### BACKGROUND

### 1. Field

The disclosure relates to a light-emitting device, an electronic apparatus including the same, and an organometallic compound.

### 2. Description of the Related Art

Self-emissive devices (for example, organic light-emitting devices) in light-emitting devices can have wide viewing angles, high contrast ratios, short response times, and excellent characteristics in terms of luminance, driving voltage, and response speed and produce full-color images.

A light-emitting device may include an anode, a hole transport region, an emission layer, an electron transport region, and a cathode, which are sequentially arranged. Holes injected from the anode may move toward the emission layer through the hole transport region. Electrons injected from the cathode may move toward the emission layer through the electron transport region. Carriers, such as holes and electrons, may recombine in the emission layer to produce excitons. When the excitons drop from an excited state to a ground state, light may be generated.

A need remains for light-emitting devices with improved luminescence characteristics.

### SUMMARY

Provided are a light-emitting device having improved luminescence characteristics in a low-grayscale region and an electronic apparatus having improved display quality.

Additional aspects will be set forth in part in the description which follows and, in part, will be apparent from the description, or may be learned by practice of the presented embodiments of the disclosure.

According to an aspect of the disclosure, a light-emitting device includes a first electrode, a second electrode facing the first electrode, and an interlayer arranged between the first electrode and the second electrode and including an emission layer,
wherein the interlayer may include an organometallic compound represented by Formula 1 and satisfying Condition 1:

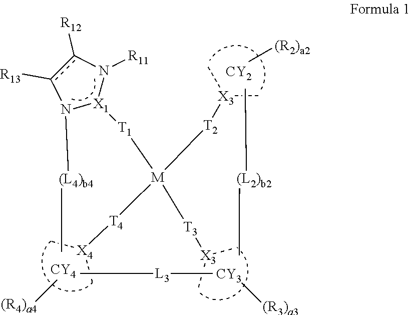

wherein, in Formula 1,
M may be platinum (Pt), palladium (Pd), gold (Au), silver (Ag), nickel (Ni), or copper (Cu),
T₁ to T₄ may each independently be a single bond, oxygen (O), or sulfur (S),
X₁ to X₄ may each independently be carbon (C) or nitrogen (N),
ring CY₂ to ring CY₄ may each independently be a C₅-C₆₀ carbocyclic group or a C₁-C₆₀ heterocyclic group,
L₂ to L₄ may each independently be a single bond, O, N(Z₁), or C(Z₁)(Z₂),
b₂ and b₄ may each be an integer from 0 to 2,
when b₂ is 0, (L₂)_{b2} may not be present, and when b₄ is 0, (L₄)_{b4} may not be present,
Z₁, Z₂, R₁₁ to R₁₃, and R₂ to R₄ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₅-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
adjacent two of R₁₁ to R₁₃ may optionally be bonded to each other to form a C₅-C₆₀ carbocyclic group or a C₁-C₆₀ heterocyclic group,
a2 to a4 may each be an integer from 1 to 30,
a group represented by [symbol] may be a single bond or a double bond,
R₁₀ₐ may be
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof,
a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be
hydrogen, deuterium, —F, —Cl, —Br, —I, a hydroxyl group, a cyano group, or a nitro group, or
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof,

### Condition 1

a minimum value of interior angles of an imaginary triangle including three atoms Y₁ to Y₃ as vertexes in the organometallic compound is less than 39°,
wherein, in Formula 1 and Condition 1,
a plane including 3 atoms, excluding an atom farthest from M among 4 atoms of i) T₁ or X₁ when T₁ is a single bond, ii) T₂ or X₂ when T₂ is a single bond, iii) T₃ or X₃ when T₃ is a single bond, and iv) T₄ or X₄ when T₄ is a single bond may be defined as a first plane,
the first plane may include an x axis, which is an imaginary straight line including M and L₃, and a y axis, which is an imaginary straight line including M and perpendicular to the x axis, wherein the x axis may include a positive direction directed from M towards L₃ and a negative direction directed from L₃ towards M,
an atom farthest from the first plane may be defined as Y₁,
among atoms included in a moiety represented by

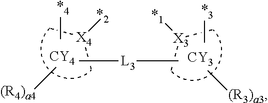

an atom farthest from the y axis in the positive direction of the x axis may be defined as Y₂,
an atom farthest from the y axis in the negative direction of the x axis may be defined as Y₃,
*₁ indicates a binding site to T₃ in Formula 1,
*₂ indicates a binding site to T₄ in Formula 1,
*₃ indicates a binding site to (L₂)_{b2} in Formula 1, and
*₄ indicates a binding site to (L₄)_{b4} in Formula 1.

According to another aspect of the disclosure, an electronic apparatus includes the light-emitting device.

According to another aspect of the disclosure, provided is an organometallic compound represented by Formula 1 and satisfying Condition 1.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an embodiment of a light-emitting device; and

FIG. 2 is a graph illustrating capacitance (farads, F) versus voltage (volts, V) of the light-emitting devices of Comparative Example A1 and Example A1.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms.

These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

According to an aspect of the disclosure, a light-emitting device may include: a first electrode; a second electrode facing the first electrode; and an interlayer arranged between the first electrode and the second electrode and including an emission layer, wherein the interlayer may include an organometallic compound represented by Formula 1 and satisfying Condition 1.

The term “interlayer” as used herein refers to a single layer or multiple layers between the first electrode and the second electrode of the light-emitting device. The interlayer may further include an organic compound in addition to the organometallic compound.

The first electrode may be a hole injection electrode or an anode, and the second electrode may be an electron injection electrode or a cathode.

The interlayer may further include a hole transport region arranged between the first electrode and the emission layer and an electron transport region arranged between the emission layer and the second electrode. The hole transport region may include a hole injection layer, a hole transport layer, an electron blocking layer, an emission auxiliary layer, or any combination thereof. The electron transport region may include an electron injection layer, an electron transport layer, an electron control layer, a hole blocking layer, a buffer layer, or any combination thereof.

The emission layer may include the organometallic compound. That is, the organometallic compound may be present in the emission layer.

The interlayer may further include, in addition to the organometallic compound, a first compound, a second compound, a third compound, or any combination thereof, and the organometallic compound, the first compound, the second compound, and the third compound may be different from each other. The emission layer may include the first compound, the second compound, the third compound, or any combination thereof. That is, the first compound, the second compound, and the third compound may be present in the emission layer.

### Organometallic Compound

In an embodiment, the organometallic compound may be represented by Formula 1 and may satisfy Condition 1:

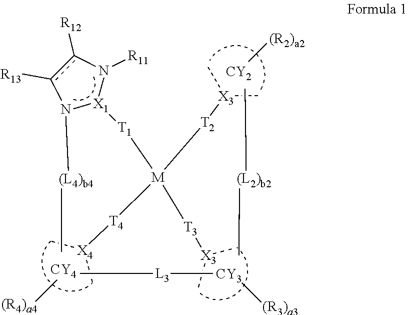

wherein, in Formula 1,
M may be platinum (Pt), palladium (Pd), gold (Au), silver (Ag), nickel (Ni), or copper (Cu),
T₁ to T₄ may each independently be a single bond, oxygen (O), or sulfur (S),
X₁ to X₄ may each independently be carbon (C) or nitrogen (N),
ring CY₂ to ring CY₄ may each independently be a C₅-C₆₀ carbocyclic group or a C₁-C₆₀ heterocyclic group,
L₂ to L₄ may each independently be a single bond, O, N(Z₁), or C(Z₁)(Z₂),
b₂ and b₄ may each be an integer from 0 to 2,
when b₂ is 0, (L₂)_{b2} may not be present, and when b₄ is 0, (L₄)_{b4} may not be present,
Z₁, Z₂, R₁₁ to R₁₃, and R₂ to R₄ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₅-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
adjacent two of R₁₁ to R₁₃ may optionally be bonded to each other to form a C₅-C₆₀ carbocyclic group or a C₁-C₆₀ heterocyclic group,
a2 to a4 may each be an integer from 1 to 30,
a group represented by [symbol] may be a single bond or a double bond,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof,

Condition 1
a minimum value of interior angles of an imaginary triangle including three atoms Y₁ to Y₃ as vertexes in the organometallic compound is less than 39°,
wherein, in Formula 1 and Condition 1,
a plane including 3 atoms, excluding an atom farthest from M among 4 atoms of i) T₁ or X₁ when T₁ is a single bond, ii) T₂ or X₂ when T₂ is a single bond, iii) T₃ or X₃ when T₃ is a single bond, and iv) T₄ or X₄ when T₄ is a single bond may be defined as a first plane,
the first plane may include an x axis, which is an imaginary straight line including M and L₃, and a y axis, which is an imaginary straight line including M and perpendicular to the x axis, wherein the x axis may include a positive direction directed from M towards L₃ and a negative direction directed from L₃ towards M,
an atom farthest from the first plane may be defined as Y₁,
among atoms included in a moiety represented by

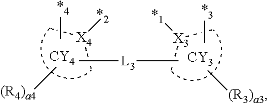

an atom farthest from the y axis in the positive direction of the x axis may be defined as Y₂,
an atom farthest from the y axis in the negative direction of the x axis may be defined as Y₃,
*₁ indicates a binding site to T₃ in Formula 1,
*₂ indicates a binding site to T₄ in Formula 1,
*₃ indicates a binding site to (L₂)_{b2} in Formula 1, and
*₄ indicates a binding site to (L₄)_{b4} in Formula 1.

### Description of Formula 1

In an embodiment, M in Formula 1 may be Pt or Pd.

In an embodiment, at least one of T₁ to T₄ in Formula 1 may be a single bond. For example, T₁ to T₄ may each be a single bond.

In an embodiment, at least one of X₁ to X₄ may be N, and at least one of the others may be C. For example, X₁ may be C, and X₂ may be N. More specifically, X₁ may be carbon or a carbene moiety.

When T₁ to T₄ is each a single bond, at least one of a bond between X₁ and M, a bond between X₂ and M, a bond between X₃ and M, and a bond between X₄ and M may be a coordinate bond, and at least one of the others may be a covalent bond. For example, the bond between X₁ and M may be a coordinate bond.

The expression “when b₂ is 0, (L₂)_{b2} may not be present” means “in Formula 1, ring CY₂ and ring CY₃ may not be directly linked via M.”

The expression “when b₄ is 0, (L₄)_{b4} may not be present” means “in Formula 1, a moiety represented by

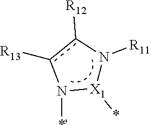

and ring CY₄ may not be directly linked via M.”

In an embodiment, T₁ to T₄ may each be a single bond, and an atom farthest from M, from among X₁ to X₄, may be X₂. That is, the first plane may be a plane including X₁, X₃, and X₄.

The first plane may include M and L₃ in Formula 1. For example, the first plane may be a plane including X₁, X₃, X₄, M, and L₃. When the first plane does not include M and/or L₃, a straight line which is an imaginary straight line including M and L₃ projected orthogonally to the first plane may be defined as the x axis.

An imaginary straight line which i) includes M, ii) is included in the first plane, and iii) is perpendicular to the x axis may be defined as the y axis. An imaginary straight line which i) includes a point (coordinate) which is M projected orthogonally to the first plane when the first plane does not include M, ii) is included in the first plane, and iii) is perpendicular to the x axis may be defined as the y axis.

In an embodiment, in Formula 1, a moiety represented by

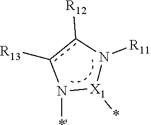

may be i) a 5-membered ring, ii) a condensed ring of a 5-membered ring and a 6-membered ring, or iii) a condensed ring of a 5-membered ring, a 6-membered ring, and a 9-membered ring. For example, in Formula 1, a moiety represented by

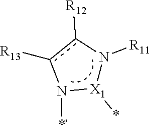

may be i) a 5-membered ring, ii) a condensed ring of one 5-membered ring and one 6-membered ring, iii) a condensed ring of one 5-membered ring, four 6-membered rings, and one 9-membered ring, or iv) a condensed ring of two 5-membered rings, five 6-membered rings, and one 9-membered ring.

In an embodiment, in the organometallic compound, Y₁, an atom farthest from the first plane may be included in a moiety represented by

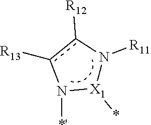

or a moiety represented by

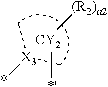

### in Formula 1.

In an embodiment, in the organometallic compound, Y₃, an atom farthest from the y axis in the positive direction of the x axis may be included in a moiety represented by

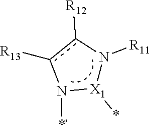

or a moiety represented by

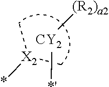

### in Formula 1.

For example, Y₁ and Y₃ may each be included in a moiety represented by

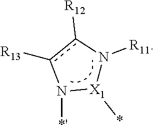

Y₁ may be included in R₁₁, and Y₃ may be included in R₁₂.

In another example, Y₁ may be included in a moiety represented by

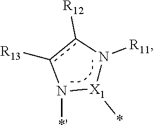

and Y₃ may be included in a moiety represented by

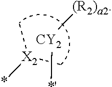

Y₁ may be included in R₁₁ or R₁₂, and Y₃ may be included in R₂. When R₂ is hydrogen, the expression “Y₃ may be included in R₂” means “Y₃ may be hydrogen.”

In another example, Y₁ may be included in a moiety represented by

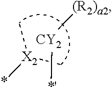

and Y₃ may be included in a moiety represented by

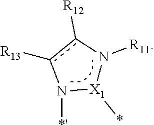

Y₁ may be included in R₂, and Y₃ may be included in R₁₁ or R₁₂.

In an embodiment, adjacent two of R₁₁ to R₁₃ may optionally be bonded to each other to form a C₅-C₆₀ carbocyclic group or a C₁-C₆₀ heterocyclic group. R₁₁ and R₁₂ may be bonded to each other to form a C₅-C₆₀ carbocyclic group or a C₁-C₆₀ heterocyclic group, or R₁₁ and R₁₂ may not be bonded to each other. R₁₂ and R₁₃ may optionally be bonded to each other to form a C₅-C₆₀ carbocyclic group or a C₁-C₆₀ heterocyclic group.

For example, R₁₂ may be an ethenyl group, R₁₃ may be an ethenyl group, and R₁₂ and R₁₃ may be bonded to each other to form a benzene group.

Referring to Formula 1 and Compound 1 below, for example, R₁₁ may be a benzene group (hereinafter, a second benzene group; BZ2) substituted with a benzene group (hereinafter, a first benzene group; BZ1), R₁₂ may be an ethenyl group substituted with a benzene group (hereinafter, a third benzene group; BZ3), R₁₃ may be an ethenyl group, and R₁₂ and R₁₃ may be bonded to each other to form a benzene group (hereinafter, a fourth benzene group; BZ4). In this case, the first benzene group (BZ1) and the third benzene group (BZ3) may optionally be bonded to each other to form a C₅-C₆₀ carbocyclic group or a C₁-C₆₀ heterocyclic group, and the expression “the first benzene group (BZ1) and the third benzene group (BZ3) may be bonded to each other” may be included in the expression “R₁₁ and R₁₂ may be bonded to each other.” More specifically, in Formula 1, a moiety represented by

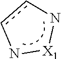

and the fourth benzene group (BZ4) may be condensed with each other to form a benzimidazole group, and as the first benzene group (BZ1) and the third benzene group (BZ3) are bonded to each other, the benzimidazole group, the first benzene group (BZ1), the second benzene group (BZ2), and the third benzene group (BZ3) may be condensed with each other to form an N-containing C₈-C₁₅ heterocyclic group (CY₉). The N-containing C₈-C₁₅ heterocyclic group (CY₉) may be a 9-membered ring:

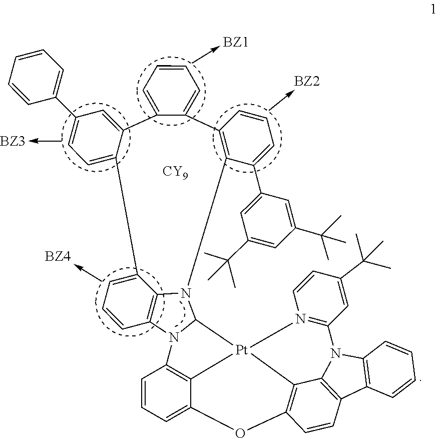

In an embodiment, a group represented by

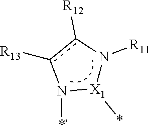

in Formula 1 may be a group represented by any one of Formulae CY1-1 to CY1-4:

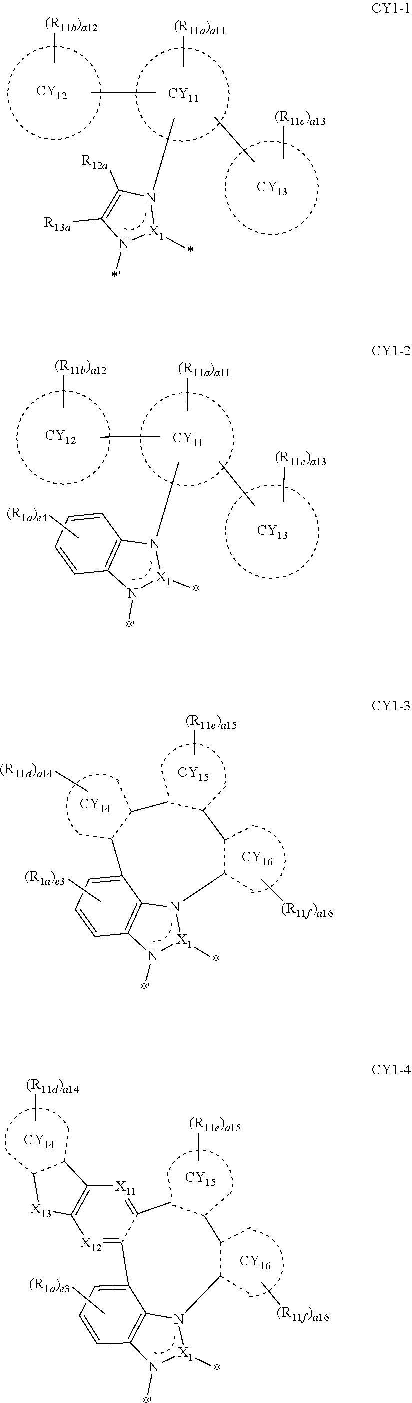

wherein, in Formulae CY1-1 to CY1-4,
X₁ is the same as described in connection with Formula 1,
X₁₁ may be N, C(H), C(D), or C(E₁₁),
X₁₂ may be N, C(H), C(D), or C(E₁₂),
X₁₃ may be O, S, N(E₁₃), or C(E₁₃)(E₁₄),
D indicates deuterium,
R₁ₐ, R₁₁ₐ, and R_{11f} are each the same as described in connection with R₁₀ₐ,
R₁₂ₐ is the same as described in connection with R₁₂,
R₁₃ₐ is the same as described in connection with R₁₃,
R_{11b}, R_{11c}, R_{11d}, R₁₁ₑ, and E₁₁ to E₁₄ may each independently be deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), or —P(═O)(Q₂₁)(Q₂₂),
R₁ₐ, R₁₁ₐ to R_{11f}, R₁₂ₐ, and R₁₃ₐ may not be bonded to each other,
ring CY₁₁ to ring CY₁₆ may each independently be a C₅-C₁₀ mono-carbocyclic group or a C₁-C₁₀ mono-heterocyclic group,
e3 may be an integer from 0 to 3,
e4 may be an integer from 0 to 4,
a11 to a16 may each be an integer from 0 to 5, and
* indicates to a binding site to T₁ in Formula 1, and *′ indicates a binding site to (L₄)_{b4} in Formula 1.

In an embodiment, in Condition 1, Y₁ and Y₃ may each be included in a moiety

represented by

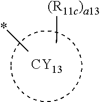

in Formulae CY1-1 and CY1-2. For example, R_{11c} may be deuterium, and Y₁ may be R_{11c}. When a13 is 0, CY₁₃ which does not include substituent R_{11c} may include a ring-forming atom and a hydrogen atom bonded to the ring-forming atom, and Y₁ may be hydrogen bonded to the ring-forming atom of CY₁₃.

In an embodiment, in Condition 1, Y₁ and Y₃ may each be included in a moiety represented by

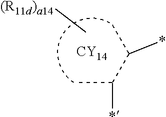

in Formulae CY1-3 and CY1-4. For example, R_{11d} may be a phenyl group, and Y₁ may be hydrogen included in R_{11d}. In another example, R_{11d} may be a triphenylsilyl group (—Si(Ph)₃), wherein “Ph” indicates a phenyl group, and Y₁ may be hydrogen included in R_{11d}. In another example, when a14 is 0, CY₁₄ which does not include substituent R_{11d} may include a ring-forming atom and a hydrogen atom bonded to the ring-forming atom, and Y₁ may be hydrogen bonded to the ring-forming atom of CY₁₄.

In an embodiment, in Formulae CY1-1 to CY1-4, ring CY₁₁ to ring CY₁₆ may each be a C₅-C₁₀ mono-carbocyclic group. ring CY₁₁ to ring CY₁₆ may each be a 6-membered ring. For example, ring CY₁₁ to ring CY₁₆ may each be a benzene group.

In an embodiment, in Formula CY1-4, at least one of X₁₁ to X₁₃ may be nitrogen or include nitrogen. For example, X₁₁ may be C(H), C(D), or C(E₁₁), X₁₂ may be C(H), C(D), or C(E₁₂), and X₁₃ may be N(E₁₃).

In an embodiment, a group represented by

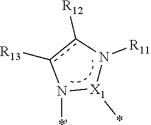

in Formula 1 may be a group represented by any one of Formulae CY1-1(1) to CY1-4(1):

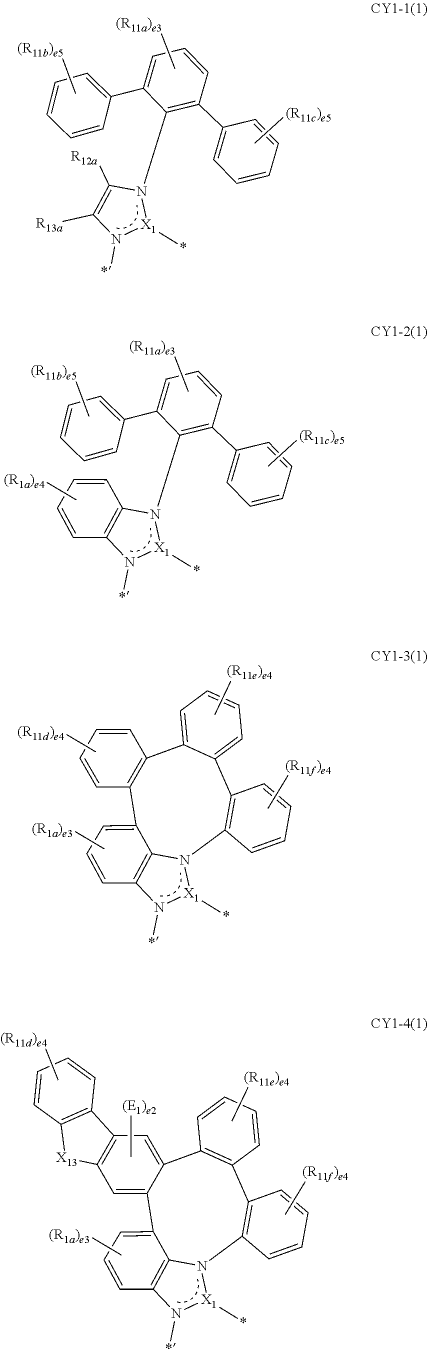

wherein * indicates to a binding site to T₁ in Formula 1, and *′ indicates a binding site to (L₄)_{b4} in Formula 1,
in Formulae CY1-1(1) to CY1-4(1),
X₁ is the same as described in connection with Formula 1,
X₁₃ may be O, S, N(E₁₃), or C(E₁₃)(E₁₄),
R₁ₐ, R₁₁ₐ, and R_{11f} are each the same as described in connection with R₁₀ₐ,
R₁₂ₐ is the same as described in connection with R₁₂,
R₁₃ₐ is the same as described in connection with R₁₃,
R_{11b}, R_{11c}, R_{11d}, R₁₁ₑ, E₁, and E₁₃ to E₁₄ may each independently be deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), or —P(═O)(Q₂₁)(Q₂₂),
R₁ₐ, R₁₁ₐ to R_{11f}, R₁₂ₐ, R₁₃ₐ, E₁, and E₁₃ to E₁₄ may not be bonded to each other,
e2 may be an integer from 0 to 2,
e3 may be an integer from 0 to 3,
e4 may be an integer from 0 to 4, and
e5 may be an integer from 0 to 5.

In an embodiment, in Formulae CY1-1(1) and CY1-2(1), at least one of R_{11b} in the number of e5 and at least one of R_{11c} in the number of e5 may be different from each other.

Referring to Formulae CY1-1(1) and CY1-2(1), the organometallic compound may include a terphenyl group, and referring to Formulae CY1-3(1) and CY1-4(1), the organometallic compound may include a 9-membered ring including N as a ring-forming atom. That is, the organometallic compound may include a terphenyl group or a 9-membered ring or include both of a terphenyl group and a 9-membered ring. More specifically, the organometallic compound may include a substituted or unsubstituted terphenyl group, a substituted or unsubstituted 9-membered ring, or any combination thereof. A substituent of each of the substituted 9-membered ring and the substituted terphenyl group may be: deuterium (—D), a C₁-C₆₀ alkyl group, a phenyl group, or a triphenylsilyl group; or a C₁-C₆₀ alkyl group or a phenyl group, each substituted with deuterium, a C₁-C₆₀ alkyl group, a phenyl group, a triphenylsilyl group, or any combination thereof.

In an embodiment, ring CY₂ may be a C₁-C₆₀ heterocyclic group. ring CY₂ may be a single ring. ring CY₂ may be a 6-membered ring. For example, ring CY₂ may be a pyridine group, a pyrimidine group, a pyrazine group, a pyridazine group, or a triazine group.

In an embodiment, in Formula 1, a moiety represented by

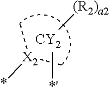

may be a group represented by Formula CY2-1:

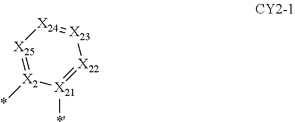

wherein * indicates to a binding site to T₂ in Formula 1, and *′ indicates a binding site to (L₂)_{b2} in Formula 1, and
in Formula CY2-1,
X₂ is the same as defined in Formula 1,
X₂₁ may be N or C, X₂₂ may be N or C(E₂₂), X₂₃ may be N or C(E₂₃), X₂₄ may be N or C(E₂₄), and X₂₅ may be N or C(E₂₅), and E₂₂ to E₂₅ are each the same as described in connection with R₂ in Formula 1.

In an embodiment, at least one of X₂ and X₂₁ to X₂₅ may be N.

In an embodiment, X₂₃ may be C(E₂₃), and E₂₃ may be:
deuterium (—D), a C₁-C₆₀ alkyl group, or a phenyl group; or
a C₁-C₆₀ alkyl group or a phenyl group, each substituted with deuterium, a C₁-C₆₀ alkyl group, a phenyl group, or any combination thereof.

In an embodiment, X₂₄ may be C(E₂₄), and E₂₄ may be:
deuterium (—D), a C₁-C₆₀ alkyl group, or a phenyl group; or
a C₁-C₆₀ alkyl group or a phenyl group, each substituted with deuterium, a C₁-C₆₀ alkyl group, a phenyl group, or any combination thereof.

In an embodiment, in Condition 1, Y₁ and Y₃ may each be included in a group represented by Formula CY2-1. For example, X₂₃ may be C(E₂₃), E₂₃ may be a tert-butyl group, and Y₁ and/or Y₃ may be hydrogen included in E₂₃. In another example, X₂₄ may be C(E₂₄), E₂₄ may be a phenyl group substituted with a tert-butyl group, and Y₁ and/or Y₃ may be hydrogen included in a tert-butyl group included in E₂₄.

In an embodiment, ring CY₃ in Formula 1 may be a polycyclic group in which at least one carbocyclic group and at least one heterocyclic group are condensed. ring CY₃ may be a polycyclic group in which at least one 5-membered ring and at least one 6-membered ring are condensed. ring CY₃ may be a polycyclic group in which one 5-membered ring and two 6-membered rings are condensed. For example, ring CY₃ may be a carbazole group.

In an embodiment, a group represented by

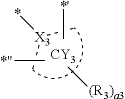

in Formula 1 may be a group represented by Formula CY3-1:

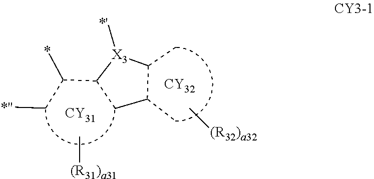

wherein * indicates a binding site to T₃ in Formula 1, *′ indicates a binding site to (L₂)_{b2} in Formula 1, and *″ indicates a binding site to L₃ in Formula 1, and
in Formula CY3-1,
X₃ is the same as defined in Formula 1,
R₃₁ and R₃₂ are each the same as described in connection with R₃ in Formula 1,
ring CY₃₁ and ring CY₃₂ may each independently be a C₅-C₁₀ mono-carbocyclic group or a C₁-C₁₀ mono-heterocyclic group, and
a31 and a32 may each be an integer from 1 to 8.

In an embodiment, in Formula CY3-1, ring CY₃₁ and ring CY₃₂ may each be a C₅-C₁₀ mono-carbocyclic group. ring CY₃₁ and ring CY₃₂ may each be a 6-membered ring. For example, ring CY₃₁ and ring CY₃₂ may each be a benzene group.

In an embodiment, in Formula CY3-1, X₃ may be N.

In an embodiment, in Formula 1, ring CY₄ may be a C₁-C₂₀ carbocyclic group. ring CY₄ may be a single ring. ring CY₄ may be a 6-membered ring. For example, ring CY₄ may be a benzene group, a pyridine group, a pyrimidine group, a pyrazine group, a pyridazine group, or a triazine group. More specifically, ring CY₄ may be a benzene group.

In an embodiment, a group represented by

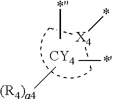

in Formula 1 may be a group represented by Formula CY4-1:

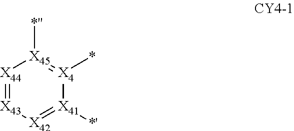

wherein * indicates a binding site to T₄ in Formula 1, *′ indicates a binding site to L₃ in Formula 1, and *″ indicates a binding site to (L₄)_{b4} in Formula 1, and
in Formula CY4-1,
X₄ is the same as defined in Formula 1,
X₄₁ may be N or C(E₄₁), X₄₂ may be N or C(E₄₂), X₄₃ may be N or C(E₄₃), X₄₄ may be N or C(E₄₄), and X₄₅ may be N or C(E₄₅), and
E₄₁ to E₄₅ are each the same as described in connection with R₄ in Formula 1.

In an embodiment, at least one of X₄ and X₄₁ to X₄₅ may be carbon or include carbon.

In an embodiment, at least one of L₂ to L₄ in Formula 1 may be a single bond, and at least one of the others may be O. For example, L₂ and L₄ may each be a single bond, and L₃ may be O.

### Specific Examples of Organometallic Compound

In an embodiment, the organometallic compound may be any one of Compounds 1 to 5:

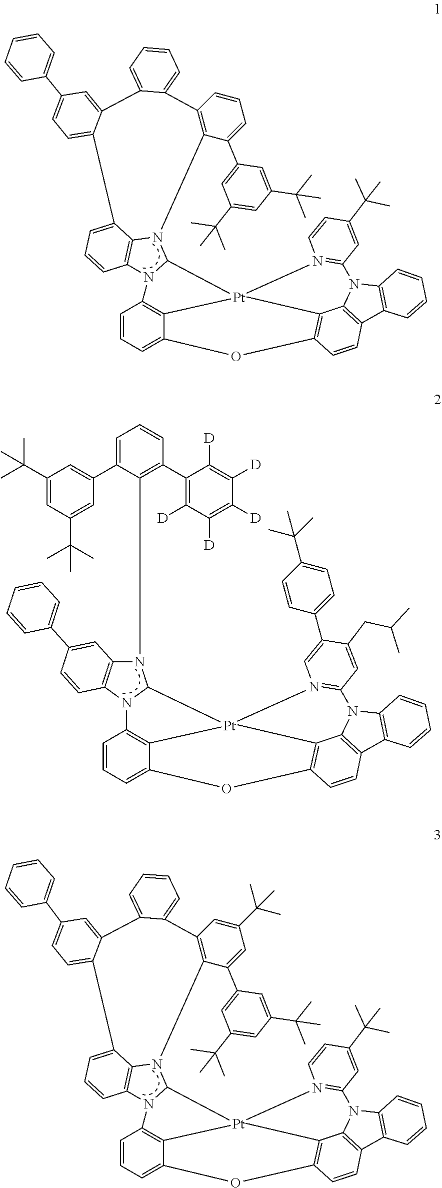

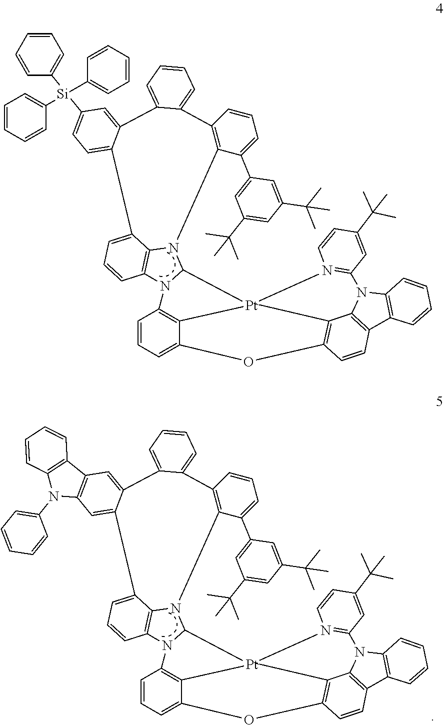

### Description of Condition 1

With respect to each of Compounds 1 to 5, the first plane, x axis, y axis, and atoms Y₁ to Y₃ according to Condition 1 are as described below. This is based on the results of analysis of molecular structures of the compounds conducted by using the density functional theory (DFT) B3LYP. As each compound has a steric structure in a three-dimensional space, the analysis results were determined based on the structure in the space. Although each compound allows intramolecular motion, such as vibration, rotation, etc., the analysis results below were determined based on a most stable state and a longest occupied structure of each compound.

### Analysis Result of Compound 1

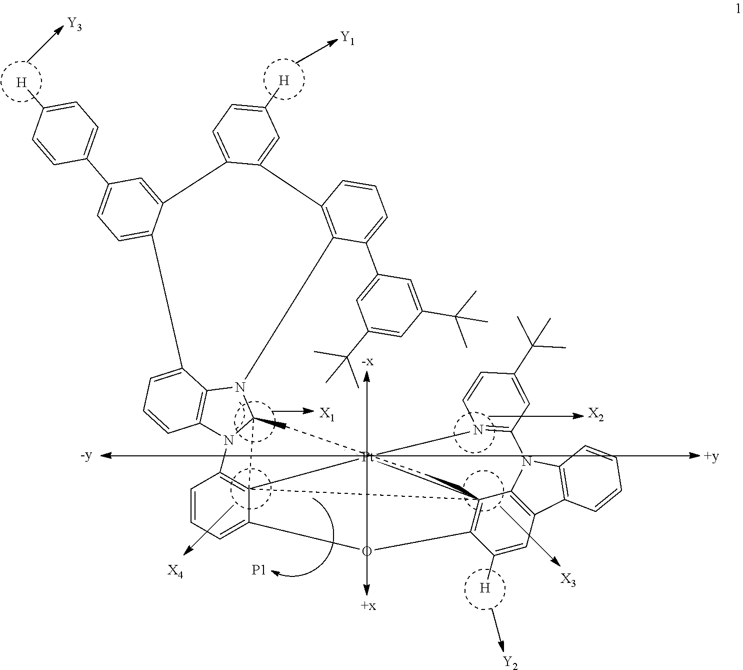

As described above, in Compound 1, T₁ to T₄ may each be a single bond, X₁, X₃, and X₄ may each be carbon (C), X₂ may be nitrogen (N), M may be platinum (Pt), and L₃ may be oxygen (O). As a distance between M (Pt) and X₁ (C) is 2.085 angstroms (Å), a distance between M (Pt) and X₂ (C) is 2.169 Å, a distance between M (Pt) and X₃ (C) is 2.017 Å, and a distance between M (Pt) and X₄ (C) is 1.969 Å, a plane including X₁ (C), X₃ (C), and X₄ (C) may be defined as a first plane P1. The first plane P1 may further include M (Pt) and L₃ (O). An imaginary straight line including M (Pt) and L₃ (O) may be defined as the x axis (+x, −x). Of the x axis (+x, −x), a direction directed from M (Pt) towards L₃ (O) may be defined as a positive direction (+x) of the x axis, and of the x axis (+x, −x), a direction directed from L₃ (O) towards M (Pt) may be defined as a negative direction (−x) of the x axis. Among straight lines of the first plane P1, an imaginary straight line which includes M (Pt) and is perpendicular to the x axis (+x, −x) may be defined as the y axis (+y, −y). In Compound 1, hydrogen (H), which is an atom farthest from the first plane P1 may be defined as atom Y₁. Among atoms included in a moiety represented by

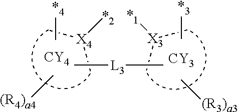

in Formula 1, hydrogen (H) which is an atom farthest from the y axis (+y, −y) in the positive direction of the x axis (+x) may be defined as atom Y₂. Hydrogen (H) which is an atom farthest from the y axis (+y, −y) in the negative direction of the x axis (−x) may be defined as atom Y₃.

### Analysis Result of Compound 2

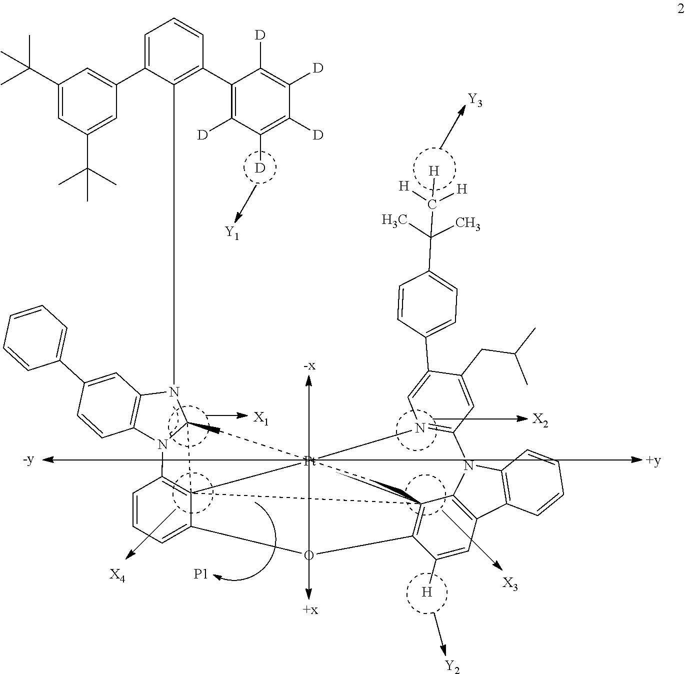

As described above, in Compound 2, T₁ to T₄ may each be a single bond, X₁, X₃, and X₄ may each be carbon (C), X₂ may be nitrogen (N), M may be platinum (Pt), and L₃ may be oxygen (O). As a distance between M (Pt) and X₁ (C) is 2.069 Å, a distance between M (Pt) and X₂ (C) is 2.180 Å, a distance between M (Pt) and X₃ (C) is 1.976 Å, and a distance between M (Pt) and X₄ (C) is 2.012 Å, a plane including X₁ (C), X₃ (C), and X₄ (C) may be defined as the first plane P1. The first plane P1 may further include M (Pt) and L₃ (O). An imaginary straight line including M (Pt) and L₃ (O) may be defined as the x axis (+x, −x). Of the x axis (+x, −x), a direction directed from M (Pt) towards L₃ (O) may be defined as a positive direction (+x) of the x axis, and of the x axis (+x, −x), a direction directed from L₃ (O) towards M (Pt) may be defined as a negative direction (−x) of the x axis. Among straight lines of the first plane P1, an imaginary straight line which includes M (Pt) and is perpendicular to the x axis (+x, −x) may be defined as the y axis (+y, −y). In Compound 2, deuterium (D), which is an atom farthest from the first plane P1 may be defined as atom Y₁. Among atoms included in a moiety represented by

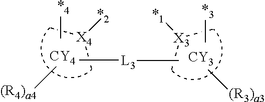

in Formula 1, hydrogen (H) which is an atom farthest from the y axis (+y, −y) in the positive direction of the x axis (+x) may be defined as atom Y₂. Hydrogen (H) which is an atom farthest from the y axis (+y, −y) in the negative direction of the x axis (−x) may be defined as atom Y₃.

### Analysis Result of Compound 3

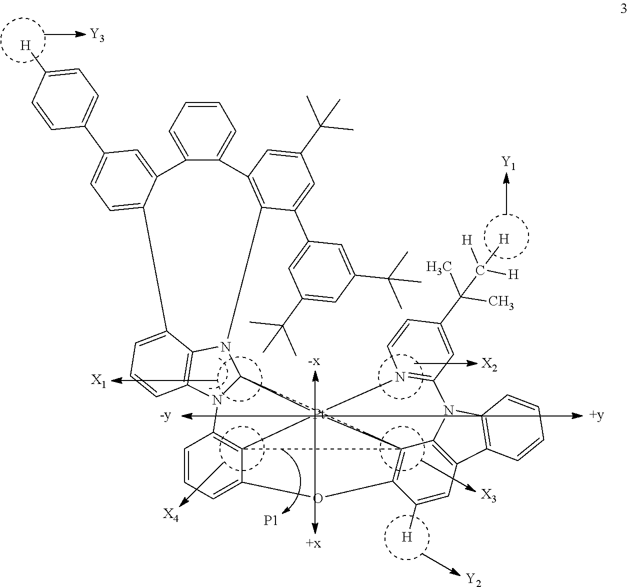

As described above, in Compound 3, T₁ to T₄ may each be a single bond, X₁, X₃, and X₄ may each be carbon (C), X₂ may be nitrogen (N), M may be platinum (Pt), and L₃ may be oxygen (O). As a distance between M (Pt) and X₁ (C) is 2.086 Å, a distance between M (Pt) and X₂ (C) is 2.169 Å, a distance between M (Pt) and X₃ (C) is 1.974 Å, and a distance between M (Pt) and X₄ (C) is 2.014 Å, a plane including X₁ (C), X₃ (C), and X₄ (C) may be defined as the first plane P1. The first plane P1 may further include M (Pt) and L₃ (O). An imaginary straight line including M (Pt) and L₃ (O) may be defined as the x axis (+x, −x). Of the x axis (+x, −x), a direction directed from M (Pt) towards L₃ (O) may be defined as a positive direction (+x) of the x axis, and of the x axis (+x, −x), a direction directed from L₃ (O) towards M (Pt) may be defined as a negative direction (−x) of the x axis. Among straight lines of the first plane P1, an imaginary straight line which includes M (Pt) and is perpendicular to the x axis (+x, −x) may be defined as the y axis (+y, −y). In Compound 3, hydrogen (H), which is an atom farthest from the first plane P1 may be defined as atom Y₁. Among atoms included in a moiety represented by

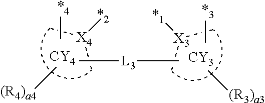

in Formula 1, hydrogen (H) which is an atom farthest from the y axis (+y, −y) in the positive direction of the x axis (+x) may be defined as atom Y₂. Hydrogen (H) which is an atom farthest from the y axis (+y, −y) in the negative direction of the x axis (−x) may be defined as atom Y₃.

### Analysis Result of Compound 4

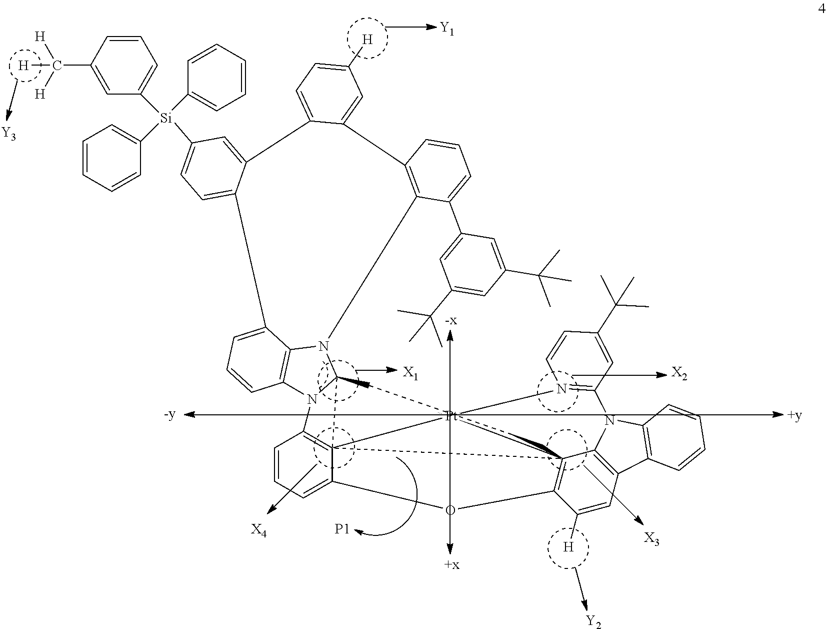

As described above, in Compound 4, T₁ to T₄ may each be a single bond, X₁, X₃, and X₄ may each be carbon (C), X₂ may be nitrogen (N), M may be platinum (Pt), and L₃ may be oxygen (O). As a distance between M (Pt) and X₁ (C) is 2.086 Å, a distance between M (Pt) and X₂ (C) is 2.169 Å, a distance between M (Pt) and X₃ (C) is 1.971 Å, and a distance between M (Pt) and X₄ (C) is 2.016 Å, a plane including X₁ (C), X₃ (C), and X₄ (C) may be defined as the first plane P1. The first plane P1 may further include M (Pt) and L₃ (O). An imaginary straight line including M (Pt) and L₃ (O) may be defined as the x axis (+x, −x). Of the x axis (+x, −x), a direction directed from M (Pt) towards L₃ (O) may be defined as a positive direction (+x) of the x axis, and of the x axis (+x, −x), a direction directed from L₃ (O) towards M (Pt) may be defined as a negative direction (−x) of the x axis. Among straight lines of the first plane P1, an imaginary straight line which includes M (Pt) and is perpendicular to the x axis (+x, −x) may be defined as the y axis (+y, −y). In Compound 4, hydrogen (H), which is an atom farthest from the first plane P1 may be defined as atom Y₁. Among atoms included in a moiety represented by

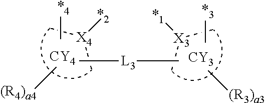

in Formula 1, hydrogen (H) which is an atom farthest from the y axis (+y, −y) in the positive direction of the x axis (+x) may be defined as atom Y₂. Hydrogen (H) which is an atom farthest from the y axis (+y, −y) in the negative direction of the x axis (−x) may be defined as atom Y₃.

### Analysis Result of Compound 5

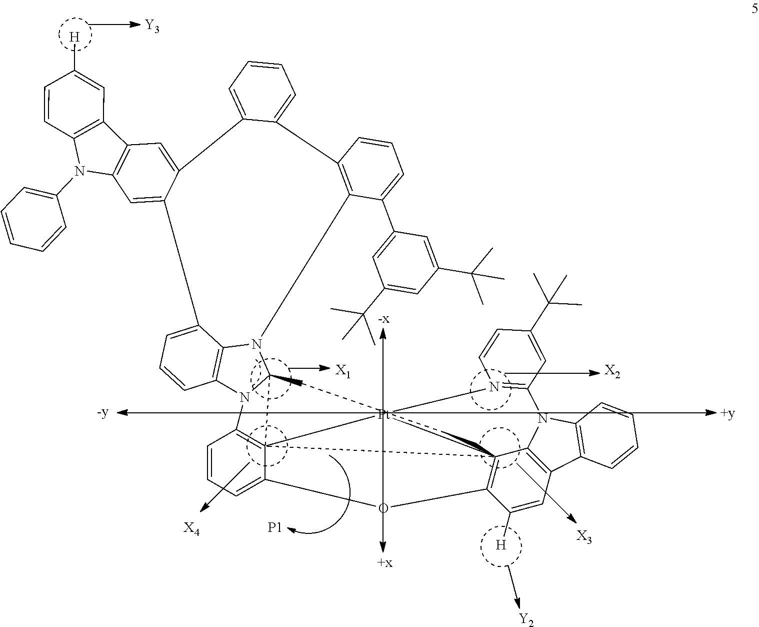

As described above, in Compound 5, T₁ to T₄ may each be a single bond, X₁, X₃, and X₄ may each be carbon (C), X₂ may be nitrogen (N), M may be platinum (Pt), and LU may be oxygen (O). As a distance between M (Pt) and X₁ (C) is 2.059 Å, a distance between M (Pt) and X₂ (C) is 2.187 Å, a distance between M (Pt) and X₃ (C) is 2.004 Å, and a distance between M (Pt) and X₄ (C) is 2.023 Å, a plane including X₁ (C), X₃ (C), and X₄ (C) may be defined as the first plane P1. The first plane P1 may further include M (Pt) and L₃ (O). An imaginary straight line including M (Pt) and L₃ (O) may be defined as the x axis (+x, −x). Of the x axis (+x, −x), a direction directed from M (Pt) towards L₃ (O) may be defined as a positive direction (+x) of the x axis, and of the x axis (+x, −x), a direction directed from L₃ (O) towards M (Pt) may be defined as a negative direction (−x) of the x axis. Among straight lines of the first plane P1, an imaginary straight line which includes M (Pt) and is perpendicular to the x axis (+x, −x) may be defined as the y axis (+y, −y). In Compound 5, hydrogen (H), which is an atom farthest from the first plane P1 may be defined as atom Y₁. Among atoms included in a moiety represented by

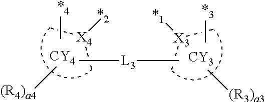

in Formula 1, hydrogen (H) which is an atom farthest from the y axis (+y, −y) in the positive direction of the x axis (+x) may be defined as atom Y₂. Hydrogen (H) which is an atom farthest from the y axis (+y, −y) in the negative direction of the x axis (−x) may be defined as atom Y₃.

### Analysis Result of Comparative Compound CE1

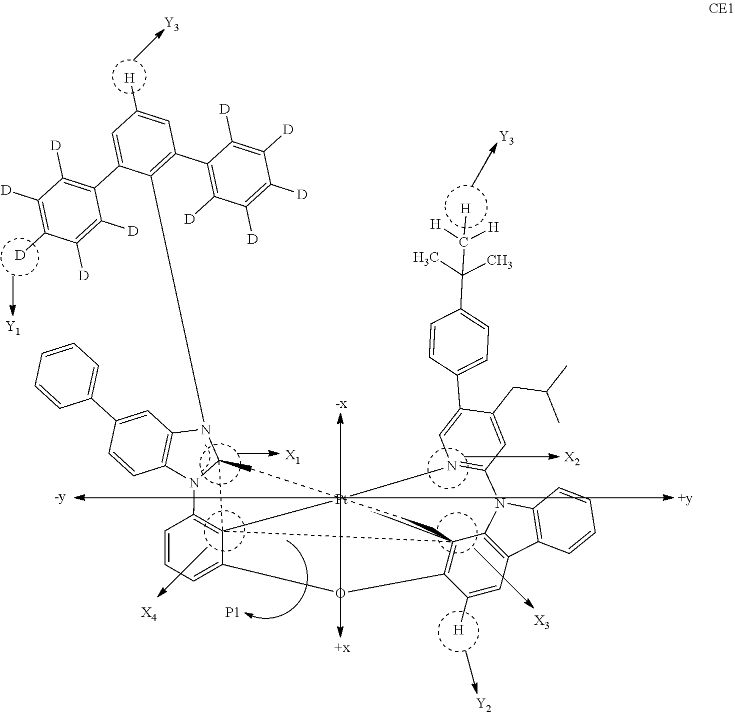

As indicated above, Comparative Compound CE1 may meet a category of Formula 1 described above. In Comparative Compound CE1, T₁ to T₄ may each be a single bond, X₁, X₃, and X₄ may each be carbon (C), X₂ may be nitrogen (N), M may be platinum (Pt), and L₃ may be oxygen (O). As a distance between M (Pt) and X₁ (C) is 2.064 Å, a distance between M (Pt) and X₂ (C) is 2.176 Å, a distance between M (Pt) and X₃ (C) is 1.967 Å, and a distance between M (Pt) and X₄ (C) is 2.016 Å, a plane including X₁ (C), X₃ (C), and X₄ (C) may be defined as the first plane P1. The first plane P1 may further include M (Pt) and L₃ (O). An imaginary straight line including M (Pt) and L₃ (O) may be defined as the x axis (+x, −x). Of the x axis (+x, −x), a direction directed from M (Pt) towards L₃ (O) may be defined as a positive direction (+x) of the x axis, and of the x axis (+x, −x), a direction directed from L₃ (O) towards M (Pt) may be defined as a negative direction (−x) of the x axis. Among straight lines of the first plane P1, an imaginary straight line which includes M (Pt) and is perpendicular to the x axis (+x, −x) may be defined as the y axis (+y, −y). In Comparative Compound CE1, deuterium (D), which is an atom farthest from the first plane P1 may be defined as atom Y₁. Among atoms included in a moiety represented by

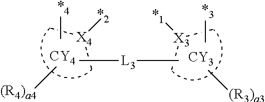

in Formula 1, hydrogen (H) which is an atom farthest from the y axis (+y, −y) in the positive direction of the x axis (+x) may be defined as atom Y₂. Hydrogen (H) which is an atom farthest from the y axis (+y, −y) in the negative direction of the x axis (−x) may be defined as atom Y₃.

### Analysis Result of Comparative Compound CE2

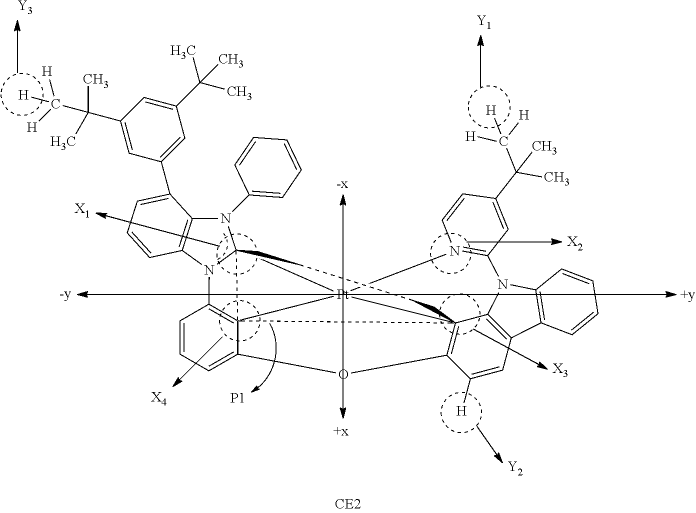

As indicated above, Comparative Compound CE2 may meet a category of Formula 1 described above. In Comparative Compound CE2, T₁ to T₄ may each be a single bond, X₁, X₃, and X₄ may each be carbon (C), X₂ may be nitrogen (N), M may be platinum (Pt), and L₃ may be oxygen (O). As a distance between M (Pt) and X₁ (C) is 2.052 Å, a distance between M (Pt) and X₂ (C) is 2.169 Å, a distance between M (Pt) and X₃ (C) is 1.965 Å, and a distance between M (Pt) and X₄ (C) is 2.016 Å, a plane including X₁ (C), X₃ (C), and X₄ (C) may be defined as the first plane P1. The first plane P1 may further include M (Pt) and L₃ (O). An imaginary straight line including M (Pt) and L₃ (O) may be defined as the x axis (+x, −x). Of the x axis (+x, −x), a direction directed from M (Pt) towards L₃ (O) may be defined as a positive direction (+x) of the x axis, and of the x axis (+x, −x), a direction directed from L₃ (O) towards M (Pt) may be defined as a negative direction (−x) of the x axis. Among straight lines of the first plane P1, an imaginary straight line which includes M (Pt) and is perpendicular to the x axis (+x, −x) may be defined as the y axis (+y, −y). In Comparative Compound CE2, hydrogen (H), which is an atom farthest from the first plane P1 may be defined as atom Y₁. Among atoms included in a moiety represented by

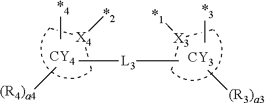

in Formula 1, hydrogen (H) which is an atom farthest from the y axis (+y, −y) in the positive direction of the x axis (+x) may be defined as atom Y₂. Hydrogen (H) which is an atom farthest from the y axis (+y, −y) in the negative direction of the x axis (−x) may be defined as atom Y₃.

### Analysis Result of Comparative Compound CE3

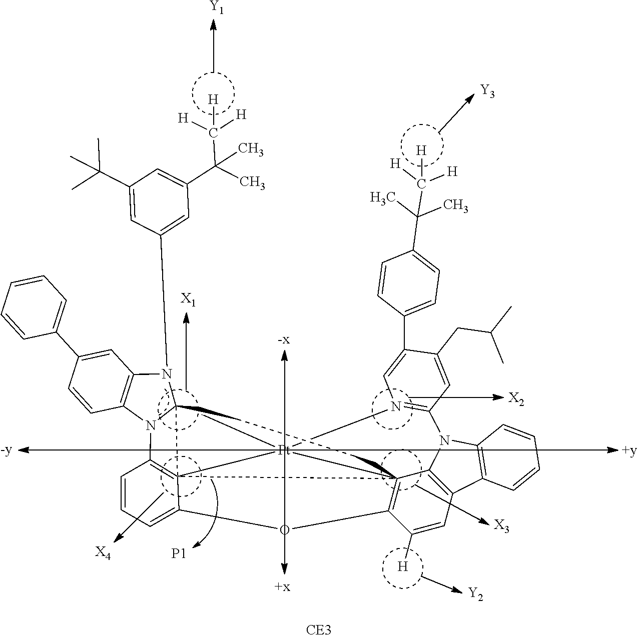

As indicated above, Comparative Compound CE3 may meet a category of Formula 1 described above. In Comparative Compound CE3, T₁ to T₄ may each be a single bond, X₁, X₃, and X₄ may each be carbon (C), X₂ may be nitrogen (N), M may be platinum (Pt), and L₃ may be oxygen (O). As a distance between M (Pt) and X₁ (C) is 2.055 Å, a distance between M (Pt) and X₂ (C) is 2.165 Å, a distance between M (Pt) and X₃ (C) is 1.977 Å, and a distance between M (Pt) and X₄ (C) is 2.012 Å, a plane including X₁ (C), X₃ (C), and X₄ (C) may be defined as the first plane P1. The first plane P1 may further include M (Pt) and L₃ (O). An imaginary straight line including M (Pt) and L₃ (O) may be defined as the x axis (+x, −x). Of the x axis (+x, −x), a direction directed from M (Pt) towards L₃ (O) may be defined as a positive direction (+x) of the x axis, and of the x axis (+x, −x), a direction directed from L₃ (O) towards M (Pt) may be defined as a negative direction (−x) of the x axis. Among straight lines of the first plane P1, an imaginary straight line which includes M (Pt) and is perpendicular to the x axis (+x, −x) may be defined as the y axis (+y, −y). In Comparative Compound CE3, hydrogen (H), which is an atom farthest from the first plane P1 may be defined as atom Y₁. Among atoms included in a moiety represented by

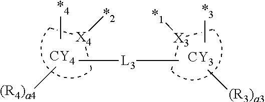

in Formula 1, hydrogen (H) which is an atom farthest from the y axis (+y, −y) in the positive direction of the x axis (+x) may be defined as atom Y₂. Hydrogen (H) which is an atom farthest from the y axis (+y, −y) in the negative direction of the x axis (−x) may be defined as atom Y₃.

### Analysis Result of Comparative Compound CE4

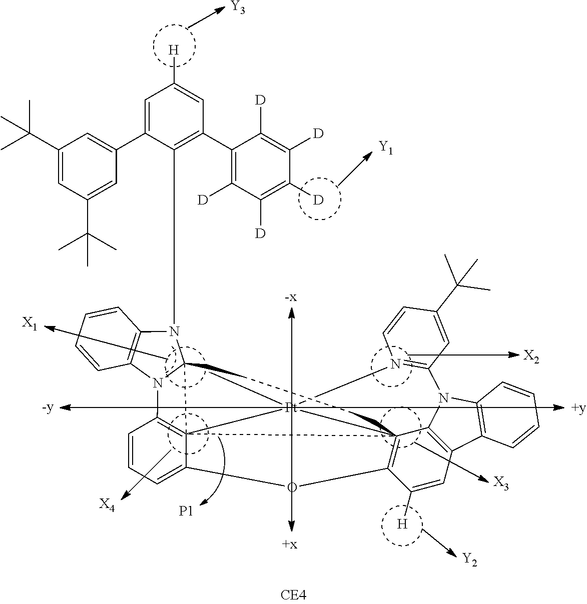

As indicated above, Comparative Compound CE4 may meet a category of Formula 1 described above. In Comparative Compound CE4, T₁ to T₄ may each be a single bond, X₁, X₃, and X₄ may each be carbon (C), X₂ may be nitrogen (N), M may be platinum (Pt), and L₃ may be oxygen (O). As a distance between M (Pt) and X₁ (C) is 2.067 Å, a distance between M (Pt) and X₂ (C) is 2.186 Å, a distance between M (Pt) and X₃ (C) is 1.963 Å, and a distance between M (Pt) and X₄ (C) is 2.023 Å, a plane including X₁ (C), X₃ (C), and X₄ (C) may be defined as the first plane P1. The first plane P1 may further include M (Pt) and L₃ (O). An imaginary straight line including M (Pt) and L₃ (O) may be defined as the x axis (+x, −x). Of the x axis (+x, −x), a direction directed from M (Pt) towards L₃ (O) may be defined as a positive direction (+x) of the x axis, and of the x axis (+x, −x), a direction directed from L₃ (O) towards M (Pt) may be defined as a negative direction (−x) of the x axis. Among straight lines of the first plane P1, an imaginary straight line which includes M (Pt) and is perpendicular to the x axis (+x, −x) may be defined as the y axis (+y, −y). In Comparative Compound CE4, deuterium (D), which is an atom farthest from the first plane P1 may be defined as atom Y₁. Among atoms included in a moiety represented by

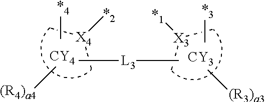

in Formula 1, hydrogen (H) which is an atom farthest from the y axis (+y, −y) in the positive direction of the x axis (+x) may be defined as atom Y₂. Hydrogen (H) which is an atom farthest from the y axis (+y, −y) in the negative direction of the x axis (−x) may be defined as atom Y₃.

### Analysis Result of Comparative Compound CE5

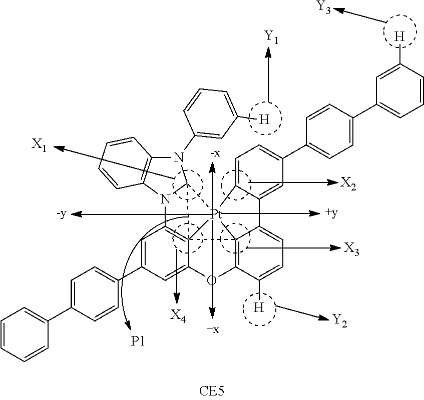

As indicated above, Comparative Compound CE5 may meet a category of Formula 1 described above. In Comparative Compound CE5, T₁ to T₄ may each be a single bond, X₁, X₃, and X₄ may each be carbon (C), X₂ may be nitrogen (N), M may be platinum (Pt), and L₃ may be oxygen (O). As a distance between M (Pt) and X₁ (C) is 2.080 Å, a distance between M (Pt) and X₂ (C) is 2.201 Å, a distance between M (Pt) and X₃ (C) is 1.982 Å, and a distance between M (Pt) and X₄ (C) is 2.010 Å, a plane including X₁ (C), X₃ (C), and X₄ (C) may be defined as the first plane P1. The first plane P1 may further include M (Pt) and L₃ (O). An imaginary straight line including M (Pt) and L₃ (O) may be defined as the x axis (+x, −x). Of the x axis (+x, −x), a direction directed from M (Pt) towards L₃ (O) may be defined as a positive direction (+x) of the x axis, and of the x axis (+x, −x), a direction directed from L₃ (O) towards M (Pt) may be defined as a negative direction (−x) of the x axis. Among straight lines of the first plane P1, an imaginary straight line which includes M (Pt) and is perpendicular to the x axis (+x, −x) may be defined as the y axis (+y, −y). In Comparative Compound CE5, hydrogen (H), which is an atom farthest from the first plane P1 may be defined as atom Y₁. Among atoms included in a moiety represented by

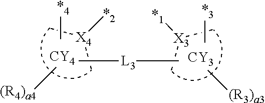

in Formula 1, hydrogen (H) which is an atom farthest from the y axis (+y, −y) in the positive direction of the x axis (+x) may be defined as atom Y₂. Hydrogen (H) which is an atom farthest from the y axis (+y, −y) in the negative direction of the x axis (−x) may be defined as atom Y₃.

In an embodiment, a minimum value of interior angles of an imaginary triangle including three atoms Y₁ to Y₃ as vertexes in the organometallic compound as described above may be less than 39°. More specifically, the minimum value of the interior angles of the imaginary triangle may be less than 37°. For example, the minimum value of the interior angles of the imaginary triangle may be less than 36°^{, less than} 35°, less than 34°, less than 33°, less than 32°, less than 31°, or less than 30°. In another example, the minimum value of the interior angles of the imaginary triangle may be greater than 10°, greater than 15°, greater than 20°, greater than 23°, greater than 25°, greater than 27°, greater than 28°, greater than 29°, greater than 30°, greater than 31°, greater than 32°, greater than 33°, or greater than 34°.

In an embodiment, <Y₁Y₂Y₃ or <Y₂Y₃Y₁ may have a minimum value of the interior angles of the imaginary triangle. That is, the minimum value of the interior angles of the imaginary triangle may not be <Y₃Y₁Y₂. For example, the minimum value of the interior angles of the imaginary triangle may be <Y₂Y₃Y₁.

### Description of Condition 2

In an embodiment, the organometallic compound may further satisfy Condition 2:
Condition 2
a minimum value of side lengths of an imaginary triangle including three atoms Y₁ to Y₃ as vertexes in the organometallic compound may be 8 Å or greater, and
in Condition 2, atoms Y₁ to Y₃ are as defined in Condition 1.

More specifically, a minimum value of side lengths of an imaginary triangle including three atoms Y₁ to Y₃ as vertexes in the organometallic compound may be 8.5 Å or greater. For example, the minimum value of the side lengths of the imaginary triangle may be 9.0 Å or greater, 9.5 Å or greater, 10.0 Å or greater, 10.5 Å or greater, 10.8 Å or greater, 10.9 Å or greater, 11.0 Å or greater, 11.1 Å or greater, 11.2 Å or greater, or 11.3 Å or greater. In another example, the minimum value of the side lengths of the imaginary triangle may be 20.0 Å or less, 18.0 Å or less, 15.0 Å or less, 14.0 Å or less, 13.0 Å or less, 12.5 Å or less, 12.3 Å or less, 12.1 Å or less, 12.0 Å or less, 11.5 Å or less, 11.4 Å or less, or 11.3 Å or less.

In an embodiment, a distance between Y₁ and Y₂ or a distance between Y₁ and Y₃ may have a minimum value of the side lengths of the imaginary triangle. That is, the minimum value of the side lengths of the imaginary triangle may not be a distance between Y₂ and Y₃. For example, the minimum value of the side lengths of the imaginary triangle may be the distance between Y₁ and Y₂.

Compared to a blue light-emitting device using a fluorescent dopant, a blue light-emitting device using a phosphorescent dopant (or sensitizer) may have increased capacitance in a low-grayscale region, which may lead to occurrence of light leakage (or increased light leakage) and decreased color purity. To overcome such issues, applying a particular material to a hole transport region has been studied. According to the disclosure, regardless of application of a particular material to a hole transport region, a phosphorescent dopant (or sensitizer) capable of reducing the capacitance and criteria for selecting such phosphorescent dopant (or sensitizer) may be provided. When an organometallic compound satisfying Condition 1 and/or Condition 2 described above is applied to a light-emitting device, the capacitance thereof may be improved. Accordingly, improvement in luminescence characteristics in a low-grayscale region of the light-emitting device, for example, prevention of turn-on and/or prevention of smudge may be achieved, and an electronic apparatus having improved quality may be implemented by using the light-emitting device.

### First Compound

In an embodiment, the interlayer may further include a first compound including an azine group including at least one nitrogen. The emission layer may include the first compound. That is, the first compound may be present in the emission layer. The first compound may be an electron-transporting host. The first compound may include a pyridine group, a pyrimidine group, a pyrazine group, a pyridazine group, a triazine group, or any combination thereof. The first compound may be represented by Formula 10:

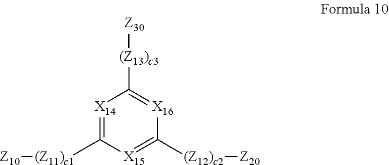

wherein, in Formula 10,
X₁₄ may be N, CH, or C(Z₁₄), X₁₅ may be N, CH, or C(Z₁₅), X₁₆ may be N, CH, or C(Z₁₆), and at least one of X₁₄ to X₁₆ may be N,
Z₁₁ to Z₁₃ may each independently be *—Si(Ar₁)(Ar₂)—*′, a C₅-C₆₀ carbocyclic group unsubstituted or substituted with at least one R₀, or a C₁-C₆₀ heterocyclic group unsubstituted or substituted with at least one R₀,
c1 to c3 may each independently be 0, 1, 2, or 3, i) when c1 is 0, *—(Z₁₁)_{c1}—*′ may be a single bond, ii) when c2 is 0, *—(Z₁₂)_{c2}—*′ may be a single bond, and iii) when c3 is 0, *—(Z₁₃)_{c3}—*′ may be a single bond,
Z₁₀, Z₂₀, and Z₃₀ may each independently be *—Si(Ar₁₁)(Ar₁₂)(Ar₁₃), a C₅-C₆₀ carbocyclic group unsubstituted or substituted with at least one R₀, or a C₁-C₆₀ heterocyclic group unsubstituted or substituted with at least one R₀,
Ar₁, Ar₂, and Ar₁₁ to Ar₁₃ may each independently be a C₅-C₆₀ carbocyclic group unsubstituted or substituted with at least one R₀ or a C₁-C₆₀ heterocyclic group unsubstituted or substituted with at least one R₀, and
R₀ and Z₁₄ to Z₁₆ may each independently be
deuterium, a C₁-C₆₀ alkyl group, or a deuterated C₁-C₆₀ alkyl group; or
a C₅-C₆₀ carbocyclic group or a C₁-C₆₀ heterocyclic group, each unsubstituted or substituted with deuterium, a C₁-C₆₀ alkyl group, a deuterated C₁-C₆₀ alkyl group, a C₅-C₆₀ carbocyclic group, a C₁-C₆₀ heterocyclic group, or any combination thereof.

For example, one selected from X₁₄ to X₁₆ may be N. In another example, two selected from X₁₄ to X₁₆ may be N. In another example, all of X₁₄ to X₁₆ may be N.

In an embodiment, Z₁₁ to Z₁₃ may each independently be *—Si(Ar₁)(Ar₂)—*′, a benzene group unsubstituted or substituted with at least one R₀, or a carbazole group unsubstituted or substituted with at least one R₀. For example, Z₁₁ to Z₁₃ may each independently be a group represented by one of Formulae 10(1) to 10(4):

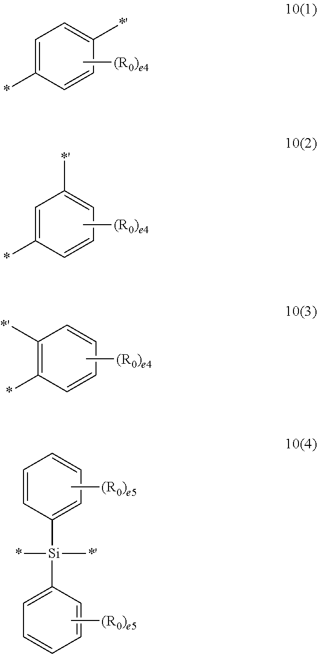

wherein, in Formulae 10(1) to 10(4),
R₀ is the same as described herein,
e4 may be an integer from 0 to 4,
e5 may be an integer from 0 to 5, and
* and *′ each indicate a binding site to a neighboring atom.

In an embodiment, in Formula 10,
i) c1 may be 1, 2, or 3, and c2 and c3 may each be 0;
ii) c1 and c2 may each independently be 1, 2, or 3, and c3 may be 0; or
iii) c1, c2, and c3 may each independently be 1, 2, or 3.

In an embodiment, at least one of Z₁₀, Z₂₀, and Z₃₀ may be:
*—Si(Ar₁₁)(Ar₁₂)(Ar₁₃); or
an N-carbazolyl group unsubstituted or substituted with deuterium, a C₁-C₂₀ alkyl group, a phenyl group, an N-carbazolyl group, or any combination thereof.

For example, at least one of Z₁₀, Z₂₀, and Z₃₀ may be a group represented by Formula 10(5) or 10(6):

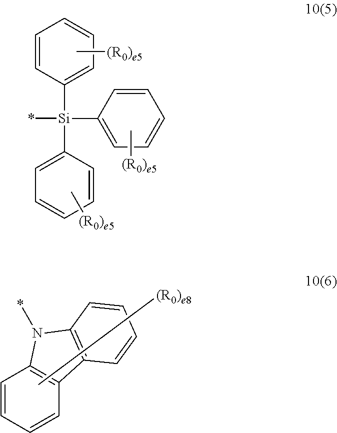

wherein, in Formulae 10(5) and 10(6),
R₀ is the same as described herein,
e5 may be an integer from 0 to 5,
e8 may be an integer from 0 to 8, and
* indicates a binding site to a neighboring atom.

In an embodiment, in Formula 10,
i) Z₁₀, Z₂₀, and Z₃₀ may be identical to each other;
ii) Z₁₀ and Z₂₀ may be identical to each other, and Z₃₀ may be different from Z₁₀ and Z₂₀; or
iii) Z₁₀, Z₂₀, and Z₃₀ may be different from each other.

In an embodiment, Ar₁, Ar₂, and Ar₁₁ to Ar₁₃ may each independently be a phenyl group unsubstituted or substituted with deuterium, a C₁-C₂₀ alkyl group, a phenyl group, an N-carbazolyl group, or any combination thereof.

In an embodiment, R₀ and Z₁₄ to Z₁₆ may each independently be:
deuterium, a C₁-C₂₀ alkyl group, or a deuterated C₁-C₂₀ alkyl group; or
a phenyl group or an N-carbazolyl group, each unsubstituted or substituted with deuterium, a C₁-C₂₀ alkyl group, a phenyl group, an N-carbazolyl group, or any combination thereof.

In an embodiment, the first compound may be a compound represented by Formula 10-1 or 10-2:

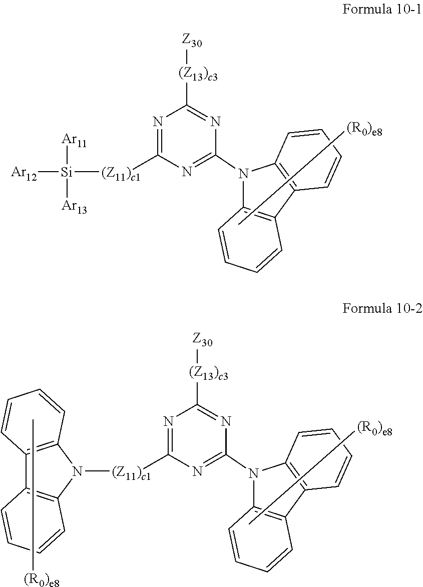

wherein, in Formulae 10-1 and 10-2,
Z₁₁, Z₁₃, Z₃₀, c1, c3, R₀, e8, and Ar₁₁ to Ar₁₃ are each the same as described above.

In an embodiment, the second compound may satisfy at least one of Conditions 11 to 13:
Condition 11
Z₁₀ in Formula 2 is a phenyl group or an N-carbazolyl group, each unsubstituted or substituted with deuterium, a C₁-C₂₀ alkyl group, a phenyl group, an N-carbazolyl group, or any combination thereof;
Condition 12
Z₁₀ in Formula 2 is *—Si(Ph)(Ph)(Ph); and
Condition 13
at least one of Z₁₁ to Z₁₃ in Formula 2 is an ortho-phenylene group or a meta-phenylene group, each unsubstituted or substituted with deuterium, a C₁-C₂₀ alkyl group, a phenyl group, an N-carbazolyl group, or any combination thereof.

In Condition 12, “Ph” refers to a phenyl group.

In an embodiment, the second compound may satisfy at least one of Conditions 14 and 15:
Condition 14
the second compound includes at least one deuterium; and
Condition 15
the second compound includes at least one tert-butyl group.

### Specific Examples of the First Compound

In an embodiment, the first compound may be selected from: Compounds E1 to E47; and a compound in which at least one hydrogen is substituted with deuterium, the compound being included in any one of Compounds E1 to E47:

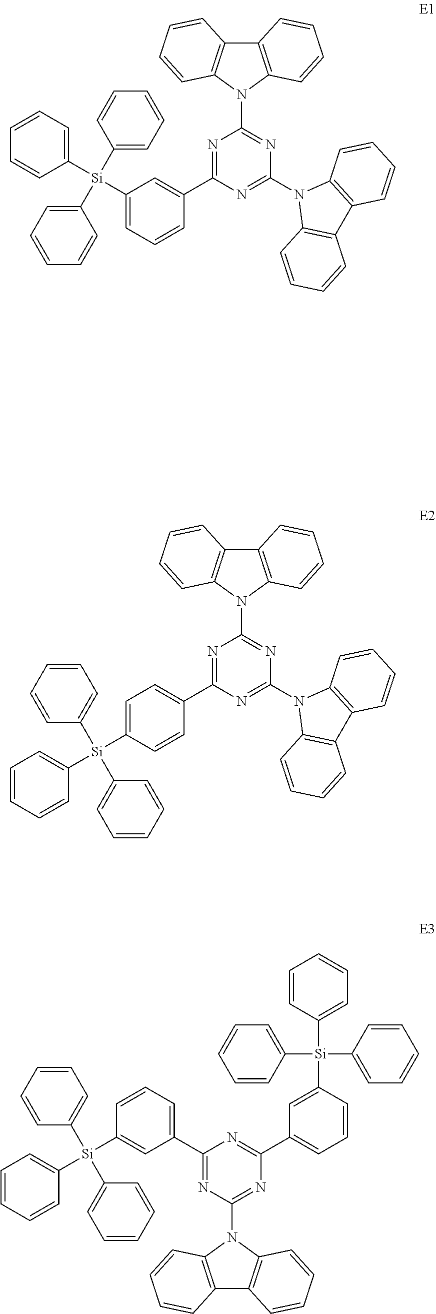 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1]

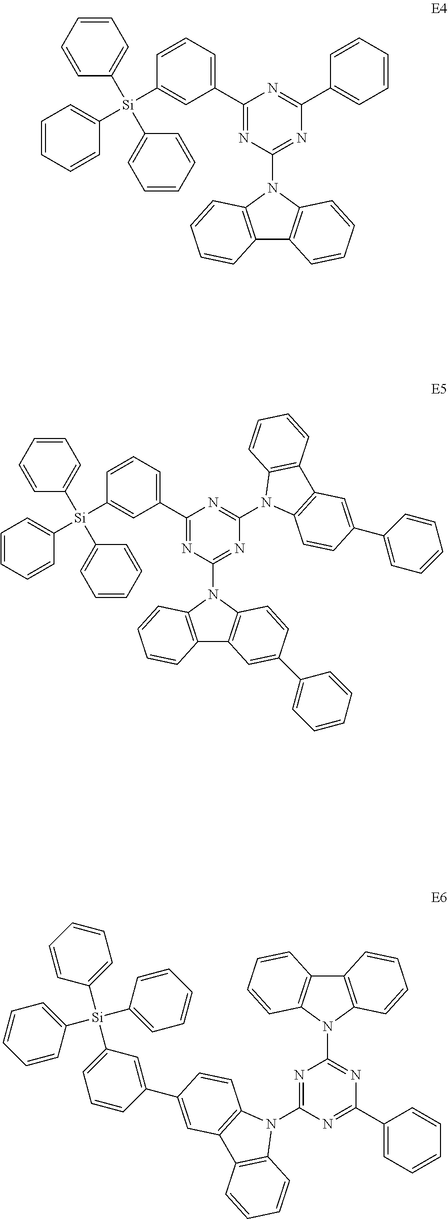 [SMILES: c1ccc(-c2nc(-c3cccc([Si](c4ccccc4)(c4ccccc4)c4ccccc4)c3)nc(-n3c4ccccc4c4ccccc43)n2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4cc(-c5ccccc5)ccc43)n2)cc1 ; c1ccc(-c2nc(-n3c4ccccc4c4ccccc43)nc(-n3c4ccccc4c4cc(-c5cccc([Si](c6ccccc6)(c6ccccc6)c6ccccc6)c5)ccc43)n2)cc1]

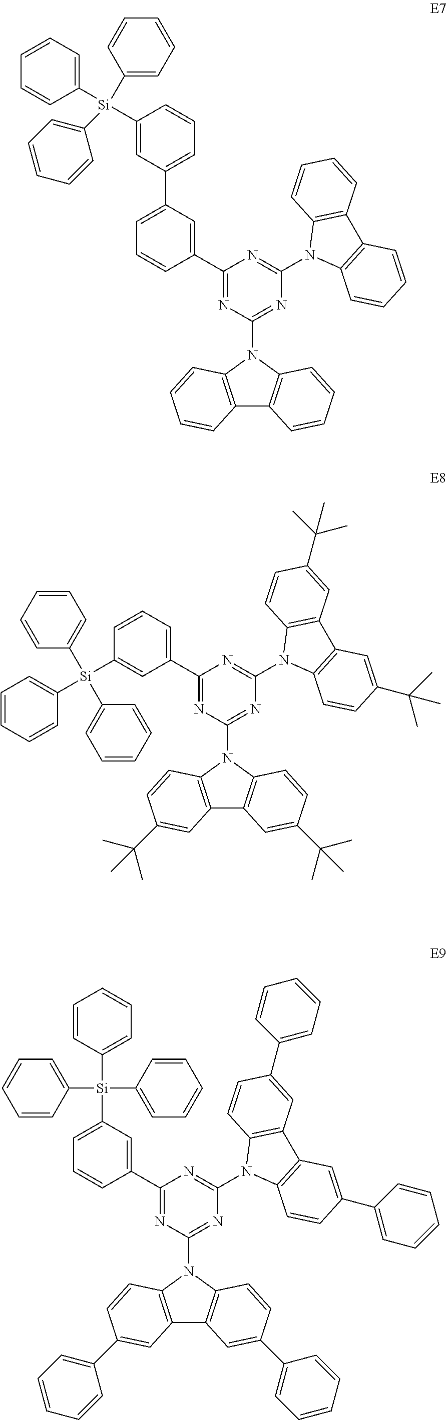 [SMILES: c1ccc([Si](c2ccccc2)(c2ccccc2)c2cccc(-c3cccc(-c4nc(-n5c6ccccc6c6ccccc65)nc(-n5c6ccccc6c6ccccc65)n4)c3)c2)cc1 ; CC(C)(C)c1ccc2c(c1)c1cc(C(C)(C)C)ccc1n2-c1nc(-c2cccc([Si](c3ccccc3)(c3ccccc3)c3ccccc3)c2)nc(-n2c3ccc(C(C)(C)C)cc3c3cc(C(C)(C)C)ccc32)n1 ; c1ccc(-c2ccc3c(c2)c2cc(-c4ccccc4)ccc2n3-c2nc(-c3cccc([Si](c4ccccc4)(c4ccccc4)c4ccccc4)c3)nc(-n3c4ccc(-c5ccccc5)cc4c4cc(-c5ccccc5)ccc43)n2)cc1]

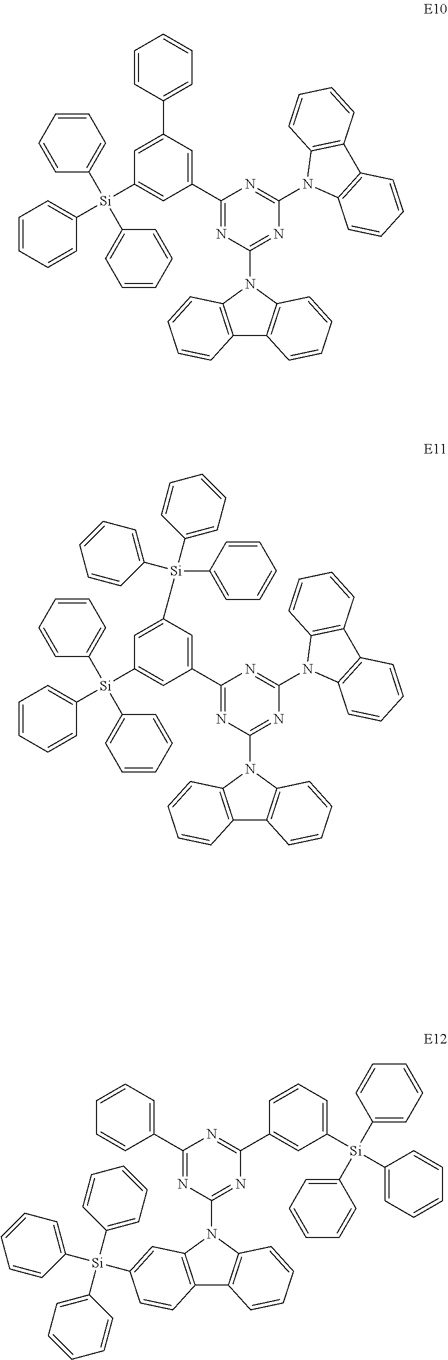 [SMILES: c1ccc(-c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1 ; c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1 ; c1ccc(-c2nc(-c3cccc([Si](c4ccccc4)(c4ccccc4)c4ccccc4)c3)nc(-n3c4ccccc4c4ccc([Si](c5ccccc5)(c5ccccc5)c5ccccc5)cc43)n2)cc1]

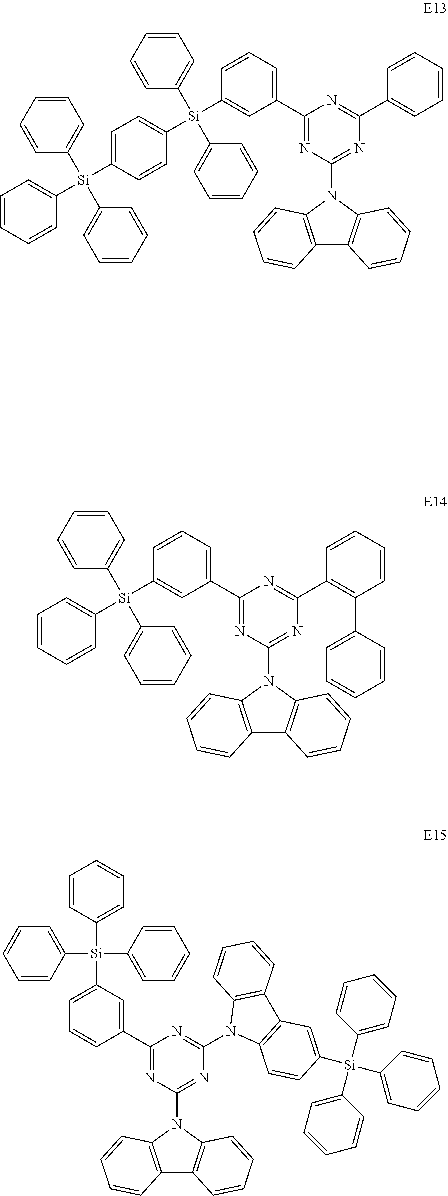 [SMILES: c1ccc(-c2nc(-c3cccc([Si](c4ccccc4)(c4ccccc4)c4ccc([Si](c5ccccc5)(c5ccccc5)c5ccccc5)cc4)c3)nc(-n3c4ccccc4c4ccccc43)n2)cc1 ; c1ccc(-c2ccccc2-c2nc(-c3cccc([Si](c4ccccc4)(c4ccccc4)c4ccccc4)c3)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5cc([Si](c6ccccc6)(c6ccccc6)c6ccccc6)ccc54)n3)c2)cc1]

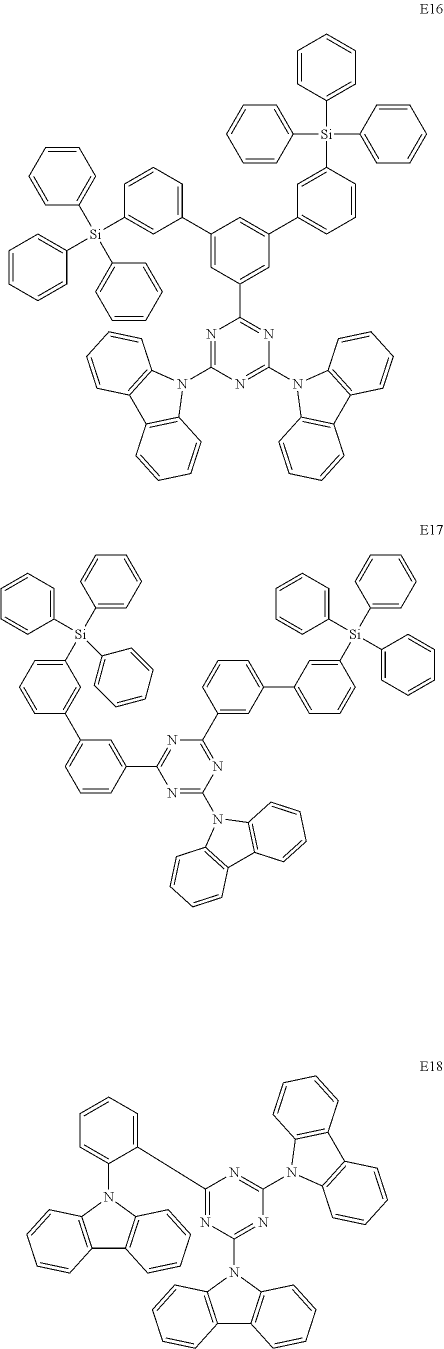 [SMILES: c1ccc([Si](c2ccccc2)(c2ccccc2)c2cccc(-c3cc(-c4cccc([Si](c5ccccc5)(c5ccccc5)c5ccccc5)c4)cc(-c4nc(-n5c6ccccc6c6ccccc65)nc(-n5c6ccccc6c6ccccc65)n4)c3)c2)cc1 ; c1ccc([Si](c2ccccc2)(c2ccccc2)c2cccc(-c3cccc(-c4nc(-c5cccc(-c6cccc([Si](c7ccccc7)(c7ccccc7)c7ccccc7)c6)c5)nc(-n5c6ccccc6c6ccccc65)n4)c3)c2)cc1 ; c1ccc(-n2c3ccccc3c3ccccc32)c(-c2nc(-n3c4ccccc4c4ccccc43)nc(-n3c4ccccc4c4ccccc43)n2)c1]

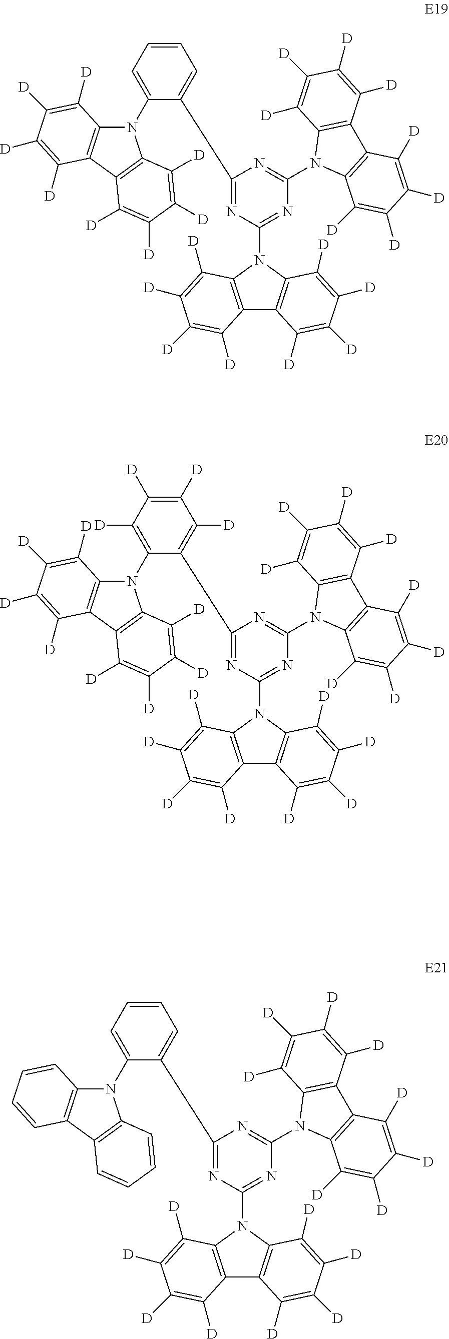

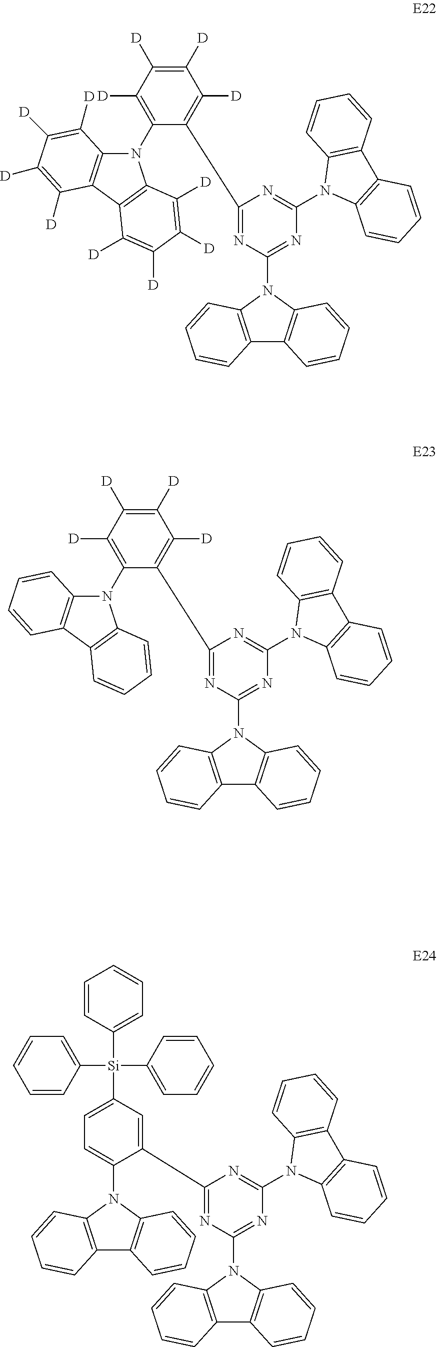 [SMILES: [2H]c1c([2H])c([2H])c(-n2c3c([2H])c([2H])c([2H])c([2H])c3c3c([2H])c([2H])c([2H])c([2H])c32)c(-c2nc(-n3c4ccccc4c4ccccc43)nc(-n3c4ccccc4c4ccccc43)n2)c1[2H] ; [2H]c1c([2H])c([2H])c(-n2c3ccccc3c3ccccc32)c(-c2nc(-n3c4ccccc4c4ccccc43)nc(-n3c4ccccc4c4ccccc43)n2)c1[2H] ; c1ccc([Si](c2ccccc2)(c2ccccc2)c2ccc(-n3c4ccccc4c4ccccc43)c(-c3nc(-n4c5ccccc5c5ccccc54)nc(-n4c5ccccc5c5ccccc54)n3)c2)cc1]

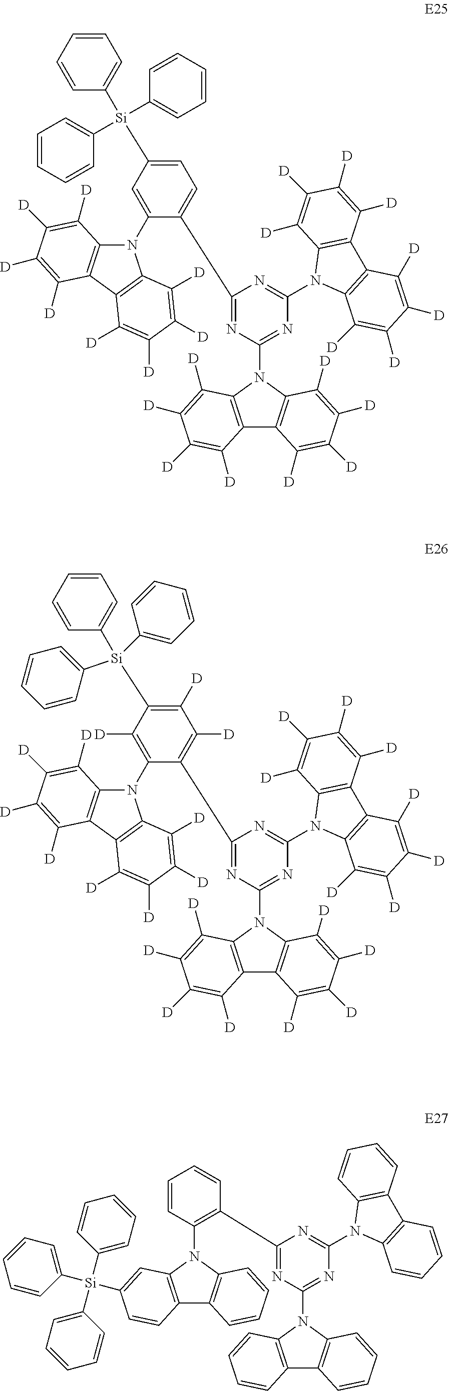

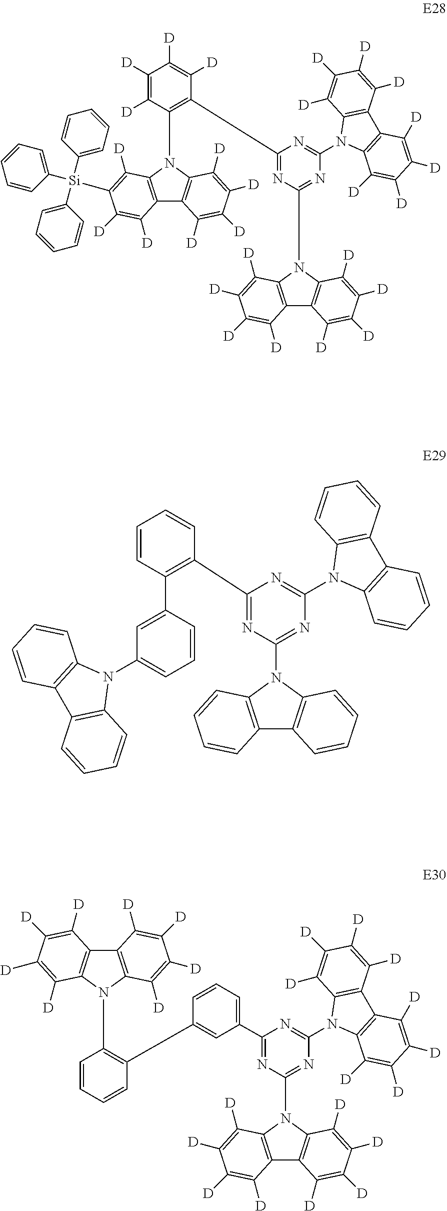

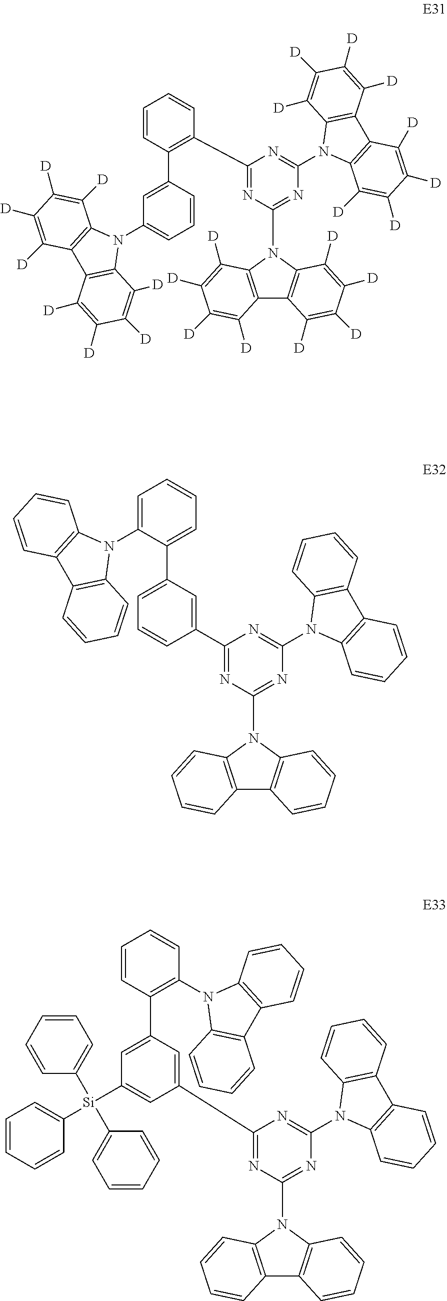 [SMILES: [2H]c1c([2H])c([2H])c2c(c1[2H])c1c([2H])c([2H])c([2H])c([2H])c1n2-c1cccc(-c2ccccc2-c2nc(-n3c4c([2H])c([2H])c([2H])c([2H])c4c4c([2H])c([2H])c([2H])c([2H])c43)nc(-n3c4c([2H])c([2H])c([2H])c([2H])c4c4c([2H])c([2H])c([2H])c([2H])c43)n2)c1 ; c1cc(-c2nc(-n3c4ccccc4c4ccccc43)nc(-n3c4ccccc4c4ccccc43)n2)cc(-c2ccccc2-n2c3ccccc3c3ccccc32)c1 ; c1ccc([Si](c2ccccc2)(c2ccccc2)c2cc(-c3nc(-n4c5ccccc5c5ccccc54)nc(-n4c5ccccc5c5ccccc54)n3)cc(-c3ccccc3-n3c4ccccc4c4ccccc43)c2)cc1]

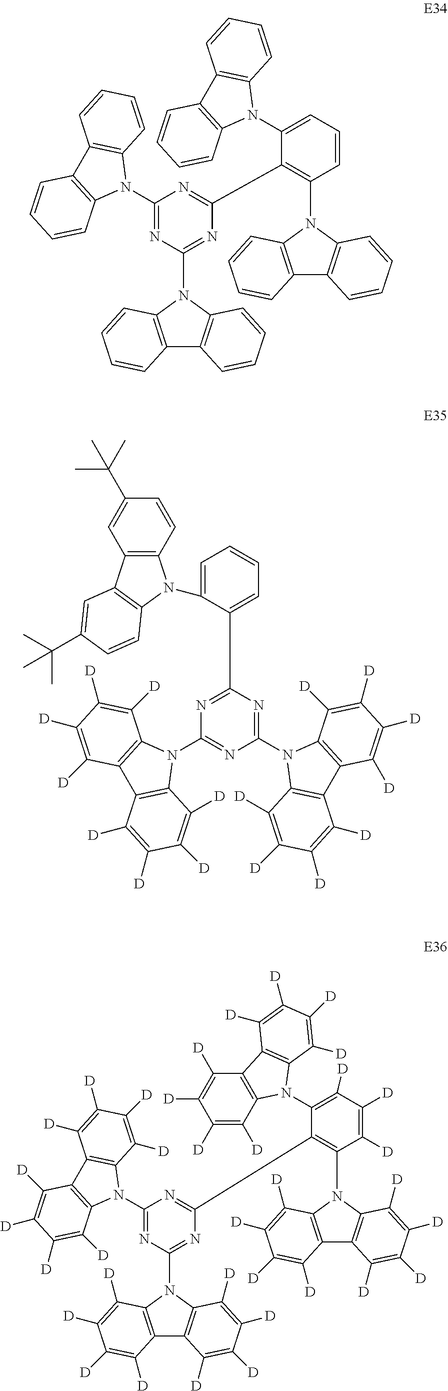

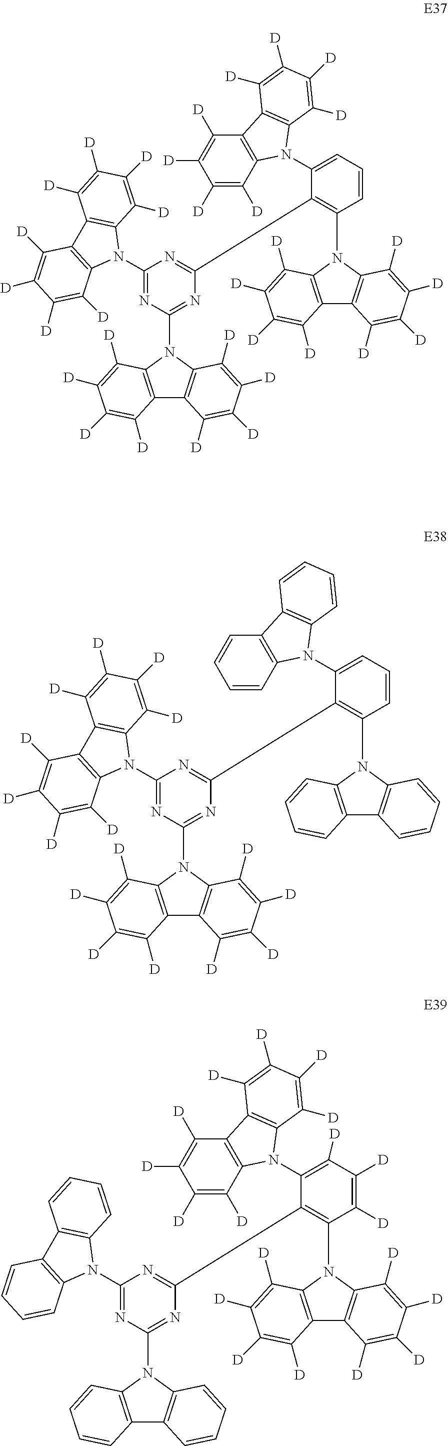

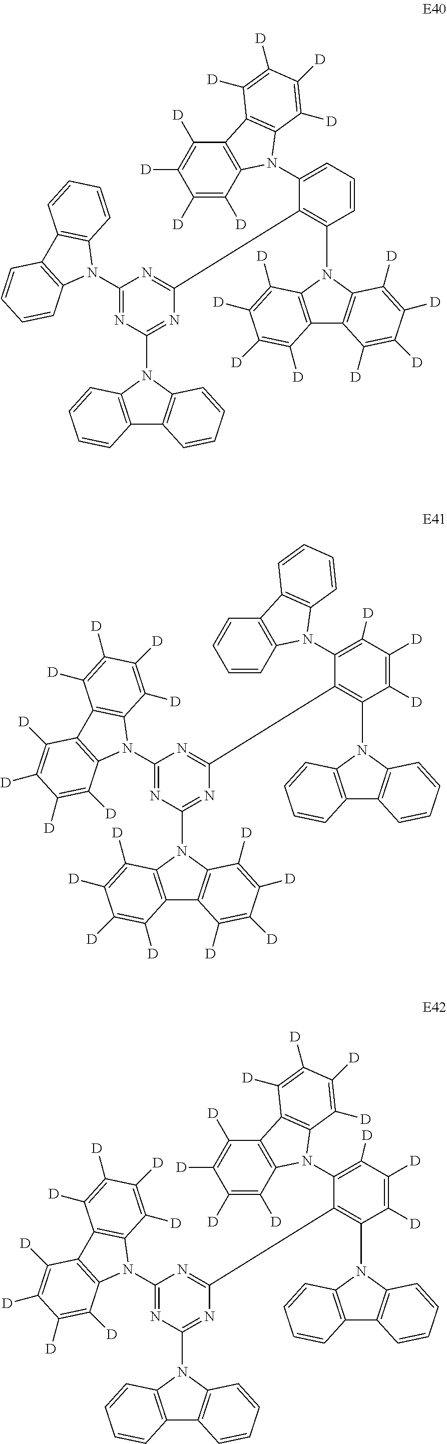

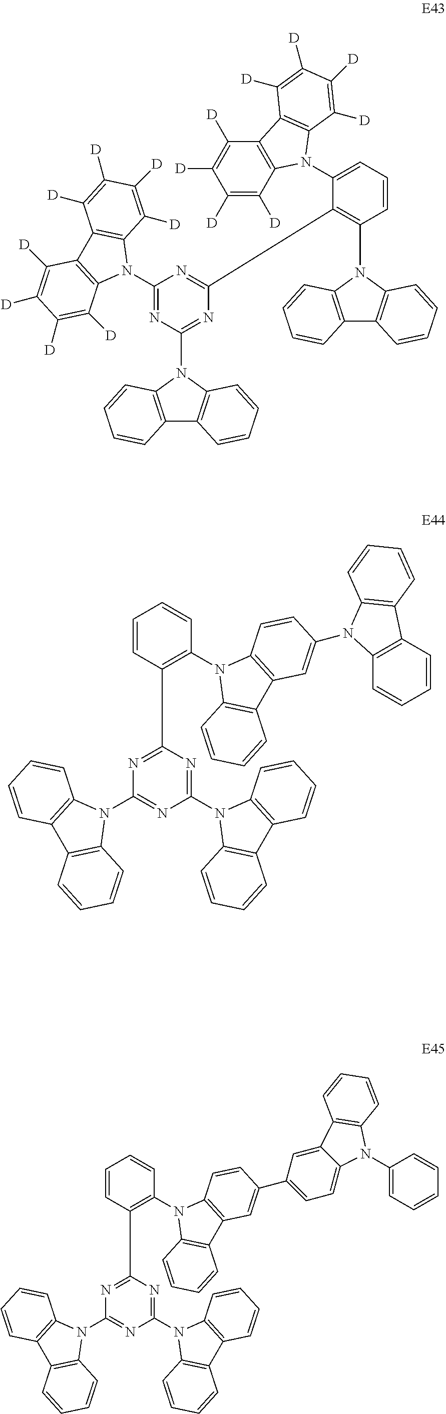 [SMILES: [2H]c1c([2H])c([2H])c2c(c1[2H])c1c([2H])c([2H])c([2H])c([2H])c1n2-c1nc(-c2c(-n3c4ccccc4c4ccccc43)cccc2-n2c3c([2H])c([2H])c([2H])c([2H])c3c3c([2H])c([2H])c([2H])c([2H])c32)nc(-n2c3ccccc3c3ccccc32)n1 ; c1ccc(-n2c3ccccc3c3cc(-n4c5ccccc5c5ccccc54)ccc32)c(-c2nc(-n3c4ccccc4c4ccccc43)nc(-n3c4ccccc4c4ccccc43)n2)c1 ; c1ccc(-n2c3ccccc3c3cc(-c4ccc5c(c4)c4ccccc4n5-c4ccccc4-c4nc(-n5c6ccccc6c6ccccc65)nc(-n5c6ccccc6c6ccccc65)n4)ccc32)cc1]

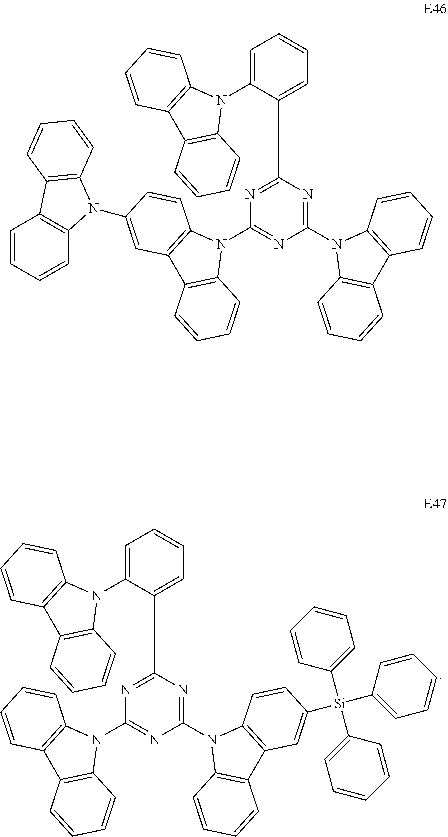 [SMILES: c1ccc(-n2c3ccccc3c3ccccc32)c(-c2nc(-n3c4ccccc4c4ccccc43)nc(-n3c4ccccc4c4cc(-n5c6ccccc6c6ccccc65)ccc43)n2)c1 ; c1ccc([Si](c2ccccc2)(c2ccccc2)c2ccc3c(c2)c2ccccc2n3-c2nc(-c3ccccc3-n3c4ccccc4c4ccccc43)nc(-n3c4ccccc4c4ccccc43)n2)cc1]

### Second Compound

In an embodiment, the interlayer may further include a second compound including at least one carbazole group. The emission layer may include the second compound. That is, the second compound may be present in the emission layer. The second compound may be a hole-transporting host. An energy level of a lowest triplet excited state (T₁) of the second compound may be 2.8 electronvolts (eV) or greater. For example, the T₁ energy level may be 2.9 eV or greater, 3.0 eV or greater, or 3.3 eV or greater. The second compound may be a compound represented by any one of Formulae 20-1 to 20-3:

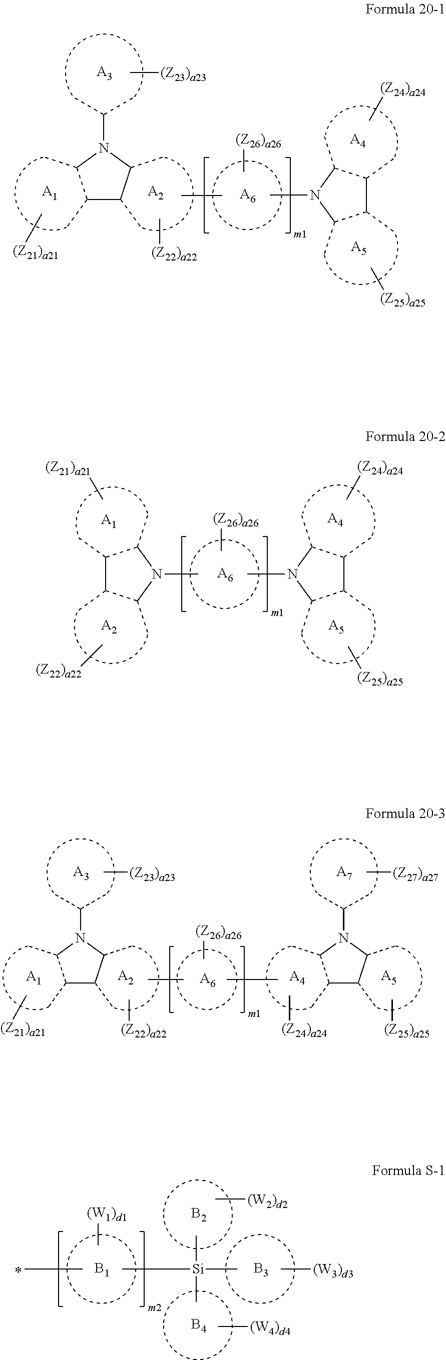

wherein, in Formulae 20-1, 20-2, 20-3, and S-1,
Z₂₁ to Z₂₇ may each independently be
a group represented by Formula S-1;
hydrogen, deuterium, a C₁-C₆₀ alkyl group, a deuterated C₁-C₆₀ alkyl group, a C₁-C₆₀ alkoxy group, or a deuterated C₁-C₆₀ alkoxy group; or
a π electron-rich C₅-C₆₀ cyclic group unsubstituted or substituted with deuterium, a C₁-C₆₀ alkyl group, a C₁-C₆₀ alkoxy group, a π electron-rich C₅-C₆₀ cyclic group, or any combination thereof,
a21 to a27 may each independently be an integer from 1 to 20,
ring A₁ to ring A₇ and ring B₁ to ring B₄ may each be a π electron-rich C₅-C₆₀ cyclic group,
m1 and m2 may each independently be 0, 1, 2, or 3, i) when m1 is 0, a group represented by

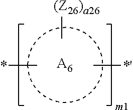

may be a single bond, and ii) when m2 is 0, a group represented by

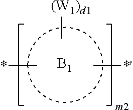

may be a single bond,
W₁ to W₄ may each independently be
hydrogen, deuterium, a C₁-C₆₀ alkyl group, a deuterated C₁-C₆₀ alkyl group, a C₁-C₆₀ alkoxy group, or a deuterated C₁-C₆₀ alkoxy group; or
a π electron-rich C₅-C₆₀ cyclic group unsubstituted or substituted with deuterium, a C₁-C₆₀ alkyl group, a C₁-C₆₀ alkoxy group, a π electron-rich C₅-C₆₀ cyclic group, or any combination thereof, and
d1 to d4 may each independently be an integer from 1 to 20.

In an embodiment, in Formulae 20-1, 20-2, and 20-3, Z₂₁ to Z₂₇ may each independently be:
a group represented by Formula S-1;
hydrogen, deuterium, a C₁-C₂₀ alkyl group, a deuterated C₁-C₂₀ alkyl group, a C₁-C₂₀ alkoxy group, or a deuterated C₁-C₂₀ alkoxy group; or
a benzene group, a naphthalene group, a furan group, a thiophene group, a pyrrole group, a cyclopentadiene group, a silole group, a benzofuran group, a benzothiophene group, an indole group, an indene, benzosilole group, a dibenzofuran group, a dibenzothiophene group, a carbazole group, a fluorene group, a dibenzosilole group, a benzofurocarbazole group, a benzothienocarbazole group, an indolocarbazole group, an indenocarbazole group, or a benzosilolocarbazole group, each unsubstituted or substituted with deuterium, a C₁-C₂₀ alkyl group, a deuterated C₁-C₂₀ alkyl group, a C₁-C₂₀ alkoxy group, a deuterated C₁-C₂₀ alkoxy group, a phenyl group, a deuterated phenyl group, a biphenyl group, a deuterated biphenyl group, a terphenyl group, a deuterated terphenyl group, a naphthyl group, a furanyl group, a thiophenyl group, a pyrrolyl group, a cyclopentadienyl group, a silolyl group, a benzofuranyl group, a benzothiophenyl group, an indolyl group, an indenyl group, a benzosilolyl group, a dibenzofuranyl group, a deuterated dibenzofuranyl group, a dibenzothiophenyl group, a deuterated dibenzothiophenyl group, a carbazolyl group, a deuterated carbazolyl group, a fluorenyl group, a dibenzosilolyl group, a benzofurocarbazolyl group, a benzothienocarbazolyl group, an indolocarbazolyl group, an indeno carbazolyl group, a benzosilolocarbazolyl group, or any combination thereof.

For example, in Formulae 20-1, 20-2, and 20-3, Z₂₁ to Z₂₇ may each independently be:
a group represented by Formula S-1;
hydrogen, deuterium, a C₁-C₂₀ alkyl group, or a deuterated C₁-C₂₀ alkyl group; or
a benzene group, a dibenzofuran group, a dibenzothiophene group, a carbazole group, a benzofurocarbazole group, a benzothienocarbazole group, or an indolocarbazole group, each unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, a terphenyl group, a deuterated terphenyl group, a dibenzofuranyl group, a deuterated dibenzofuranyl group, a dibenzothiophenyl group, a deuterated dibenzothiophenyl group, a carbazolyl group, a deuterated carbazolyl group, or any combination thereof.

In an embodiment, at least one of Z₂₁ to Z₂₆ in Formula 20-1, at least one of Z₂₁, Z₂₂, and Z₂₄ to Z₂₆ in Formula 20-2, and at least one of Z₂₁ to Z₂₇ in Formula 20-3 may be a group represented by Formula S-1. For example, in Formula 20-1, i) Z₂₁, ii) Z₂₃, iii) Z₂₄, or iv) Z₂₃ and Z₂₄ may each be a group represented by Formula S-1. In another example, in Formula 20-2, Z₂₆ may be a group represented by Formula S-1.

In another embodiment, Z₂₁ to Z₂₆ in Formula 20-1, Z₂₁, Z₂₂, and Z₂₄ to Z₂₆ in Formula 20-2, and Z₂₁ to Z₂₇ in Formula 20-3 may not each be a group represented by Formula S-1.

In an embodiment, in Formulae 20-1, 20-2, 20-3, and S-1, ring A₁ to ring A₇ and ring B₁ to ring B₄ may each independently be a benzene group, a naphthalene group, a furan group, a thiophene group, a pyrrole group, a cyclopentadiene group, a silole group, a benzofuran group, a benzothiophene group, an indole group, an indene group, a benzosilole group, a dibenzofuran group, a dibenzothiophene group, a carbazole group, a fluorene group, a dibenzosilole group, a benzofurocarbazole group, a benzothienocarbazole group, an indolocarbazole group, an indenocarbazole group, or a benzosilolocarbazole group.

Rings A₁, A₂, A₄, and A₅ may each independently be a benzene group, a benzofuran group, a benzothiophene group, or an indole group. rings A₃, A₆, A₇, and B₁ to B₄ may each independently be a benzene group, a dibenzofuran group, a dibenzothiophene group, a carbazole group, a benzofurocarbazole group, a benzothienocarbazole group, or an indolocarbazole group.

In Formula S-1, W₁ to W₄ may each independently be:
hydrogen, deuterium, a C₁-C₂₀ alkyl group, a deuterated C₁-C₂₀ alkyl group, a C₁-C₂₀ alkoxy group, or a deuterated C₁-C₂₀ alkoxy group; or
a benzene group, a naphthalene group, a furan group, a thiophene group, a pyrrole group, a cyclopentadiene group, a silole group, a benzofuran group, a benzothiophene group, an indole group, an indene, benzosilole group, a dibenzofuran group, a dibenzothiophene group, a carbazole group, a fluorene group, a dibenzosilole group, a benzofurocarbazole group, a benzothienocarbazole group, an indolocarbazole group, an indenocarbazole group, or a benzosilolocarbazole group, each unsubstituted or substituted with deuterium, a C₁-C₂₀ alkyl group, a deuterated C₁-C₂₀ alkyl group, a C₁-C₂₀ alkoxy group, a deuterated C₁-C₂₀ alkoxy group, a phenyl group, a deuterated phenyl group, a biphenyl group, a deuterated biphenyl group, a terphenyl group, a deuterated terphenyl group, a naphthyl group, a furanyl group, a thiophenyl group, a pyrrolyl group, a cyclopentadienyl group, a silolyl group, a benzofuranyl group, a benzothiophenyl group, an indolyl group, an indenyl group, a benzosilolyl group, a dibenzofuranyl group, a deuterated dibenzofuranyl group, a dibenzothiophenyl group, a deuterated dibenzothiophenyl group, a carbazolyl group, a deuterated carbazolyl group, a fluorenyl group, a dibenzosilolyl group, a benzofurocarbazolyl group, a benzothienocarbazolyl group, an indolocarbazolyl group, an indeno carbazolyl group, a benzosilolocarbazolyl group, or any combination thereof.

### Specific Examples of the Second Compound

In an embodiment, the second compound may be selected from: Compounds H1 to H108; and a compound in which at least one hydrogen is substituted with deuterium, the compound being included in any one of Compounds H1 to H108:

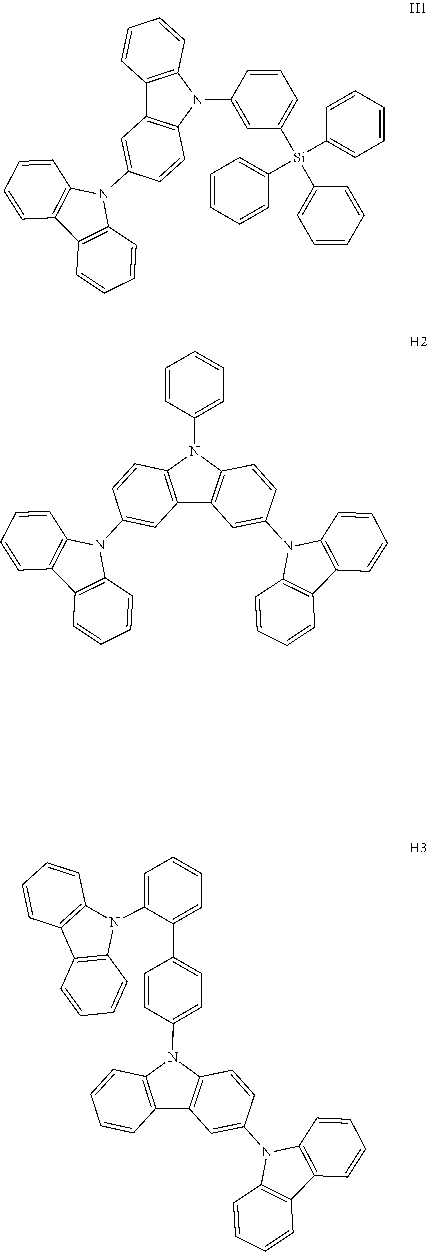 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc(-n2c3ccc(-n4c5ccccc5c5ccccc54)cc3c3cc(-n4c5ccccc5c5ccccc54)ccc32)cc1 ; c1ccc(-n2c3ccccc3c3ccccc32)c(-c2ccc(-n3c4ccccc4c4cc(-n5c6ccccc6c6ccccc65)ccc43)cc2)c1]

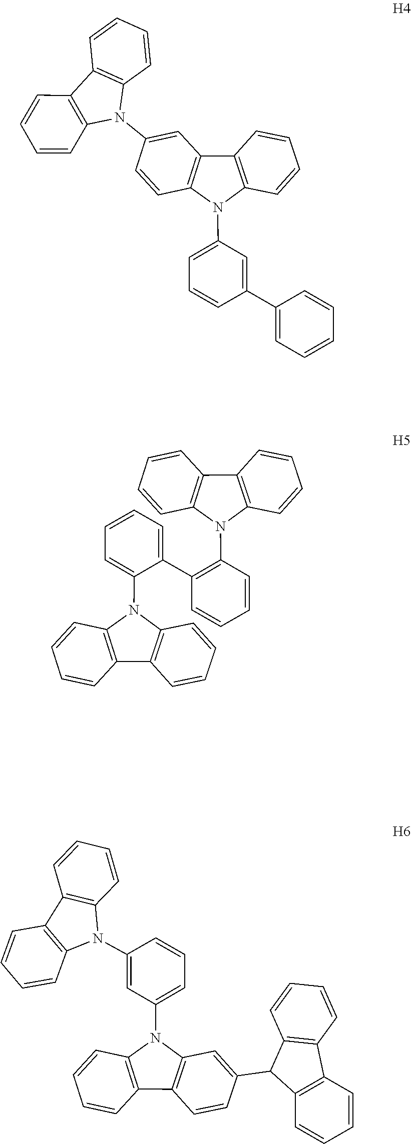 [SMILES: c1ccc(-c2cccc(-n3c4ccccc4c4cc(-n5c6ccccc6c6ccccc65)ccc43)c2)cc1 ; c1ccc(-n2c3ccccc3c3ccccc32)c(-c2ccccc2-n2c3ccccc3c3ccccc32)c1 ; c1cc(-n2c3ccccc3c3ccccc32)cc(-n2c3ccccc3c3ccc(C4c5ccccc5-c5ccccc54)cc32)c1]

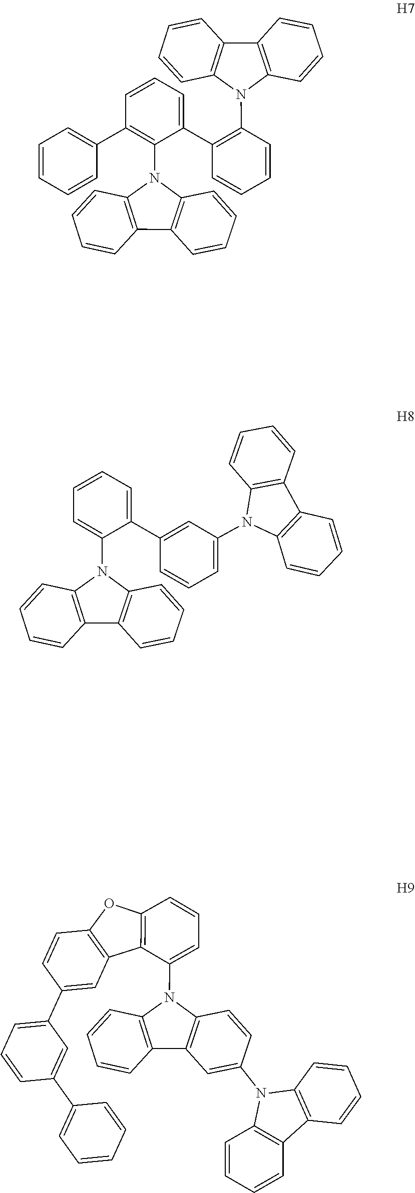 [SMILES: c1ccc(-c2cccc(-c3ccccc3-n3c4ccccc4c4ccccc43)c2-n2c3ccccc3c3ccccc32)cc1 ; c1cc(-c2ccccc2-n2c3ccccc3c3ccccc32)cc(-n2c3ccccc3c3ccccc32)c1 ; c1ccc(-c2cccc(-c3ccc4oc5cccc(-n6c7ccccc7c7cc(-n8c9ccccc9c9ccccc98)ccc76)c5c4c3)c2)cc1]

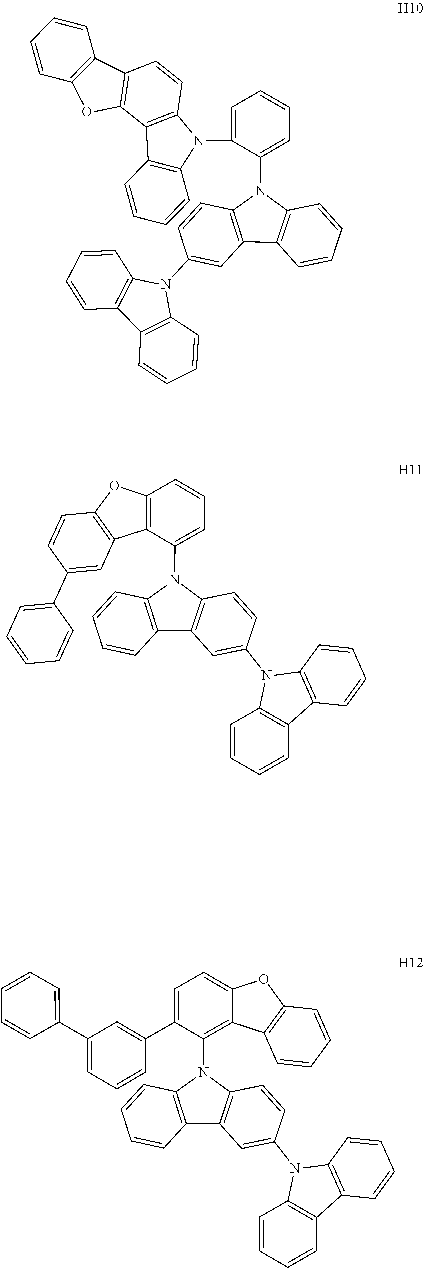 [SMILES: c1ccc(-n2c3ccccc3c3c4oc5ccccc5c4ccc32)c(-n2c3ccccc3c3cc(-n4c5ccccc5c5ccccc54)ccc32)c1 ; c1ccc(-c2ccc3oc4cccc(-n5c6ccccc6c6cc(-n7c8ccccc8c8ccccc87)ccc65)c4c3c2)cc1 ; c1ccc(-c2cccc(-c3ccc4oc5ccccc5c4c3-n3c4ccccc4c4cc(-n5c6ccccc6c6ccccc65)ccc43)c2)cc1]

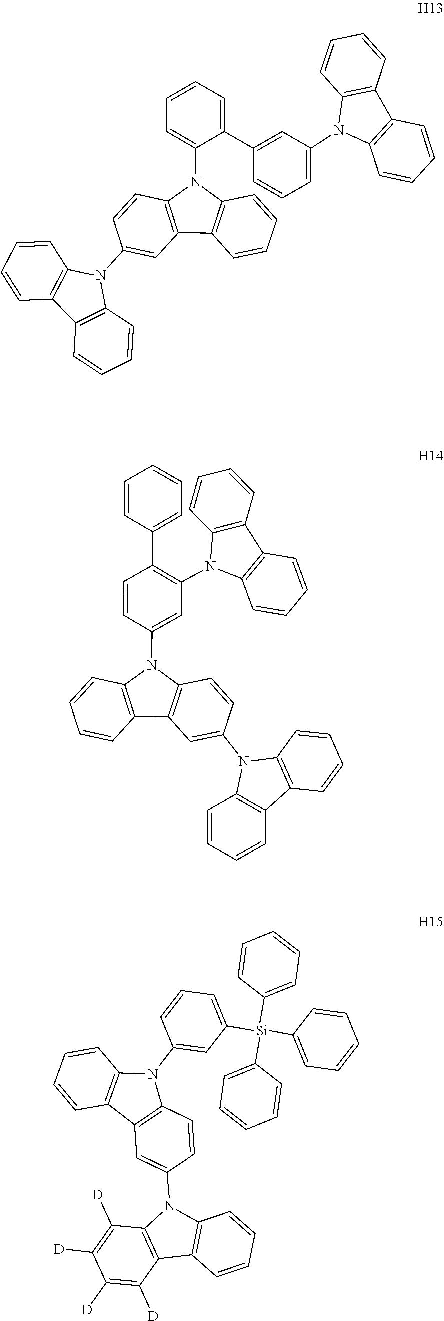 [SMILES: c1cc(-c2ccccc2-n2c3ccccc3c3cc(-n4c5ccccc5c5ccccc54)ccc32)cc(-n2c3ccccc3c3ccccc32)c1 ; c1ccc(-c2ccc(-n3c4ccccc4c4cc(-n5c6ccccc6c6ccccc65)ccc43)cc2-n2c3ccccc3c3ccccc32)cc1 ; [2H]c1c([2H])c([2H])c2c(c1[2H])c1ccccc1n2-c1ccc2c(c1)c1ccccc1n2-c1cccc([Si](c2ccccc2)(c2ccccc2)c2ccccc2)c1]

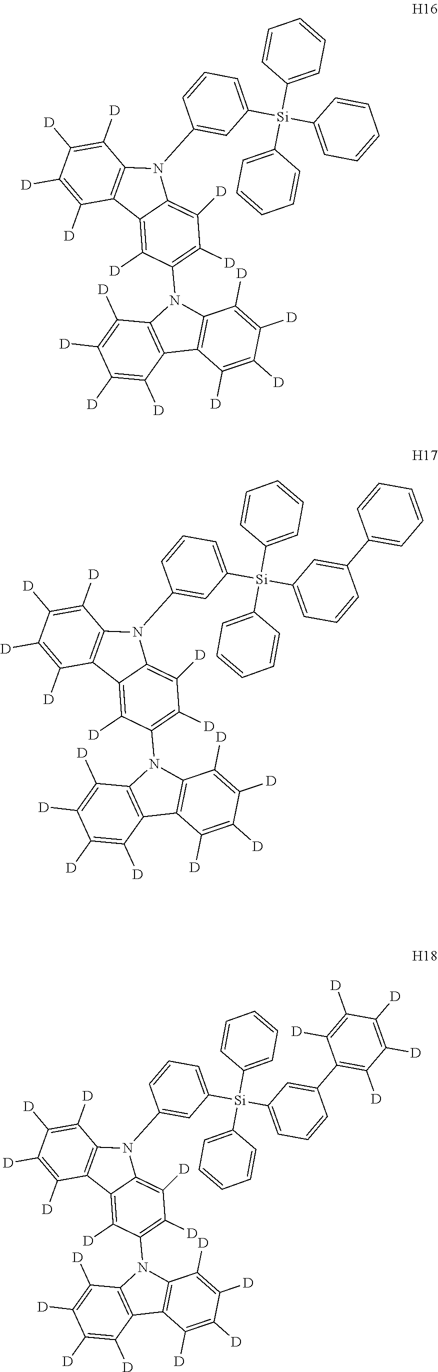

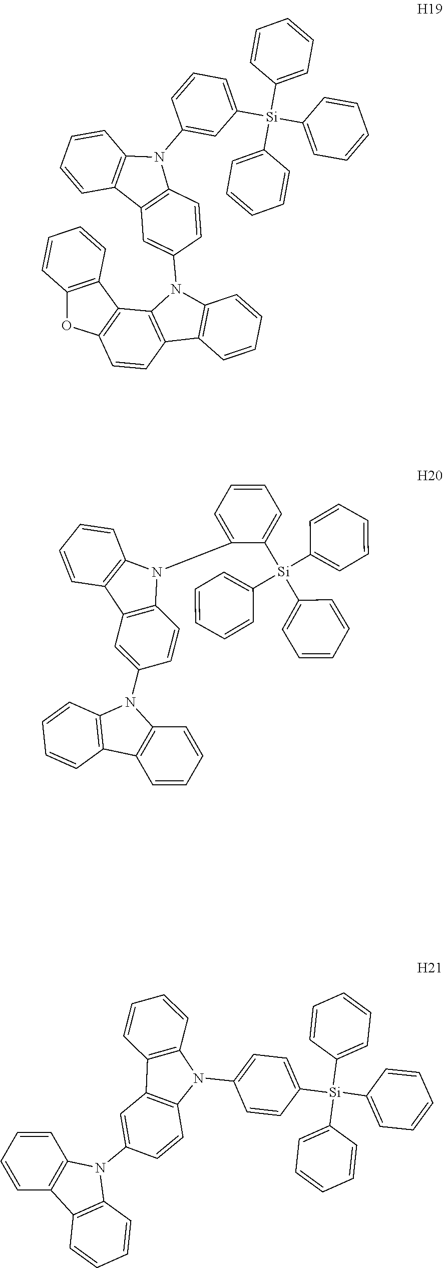 [SMILES: c1ccc([Si](c2ccccc2)(c2ccccc2)c2cccc(-n3c4ccccc4c4cc(-n5c6ccccc6c6ccc7oc8ccccc8c7c65)ccc43)c2)cc1 ; c1ccc([Si](c2ccccc2)(c2ccccc2)c2ccccc2-n2c3ccccc3c3cc(-n4c5ccccc5c5ccccc54)ccc32)cc1 ; c1ccc([Si](c2ccccc2)(c2ccccc2)c2ccc(-n3c4ccccc4c4cc(-n5c6ccccc6c6ccccc65)ccc43)cc2)cc1]

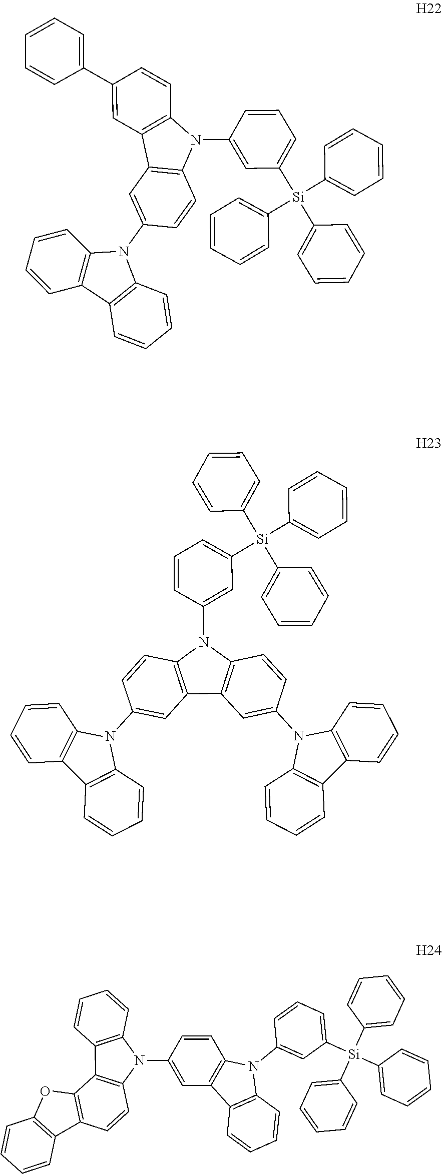 [SMILES: c1ccc(-c2ccc3c(c2)c2cc(-n4c5ccccc5c5ccccc54)ccc2n3-c2cccc([Si](c3ccccc3)(c3ccccc3)c3ccccc3)c2)cc1 ; c1ccc([Si](c2ccccc2)(c2ccccc2)c2cccc(-n3c4ccc(-n5c6ccccc6c6ccccc65)cc4c4cc(-n5c6ccccc6c6ccccc65)ccc43)c2)cc1 ; c1ccc([Si](c2ccccc2)(c2ccccc2)c2cccc(-n3c4ccccc4c4cc(-n5c6ccccc6c6c7oc8ccccc8c7ccc65)ccc43)c2)cc1]

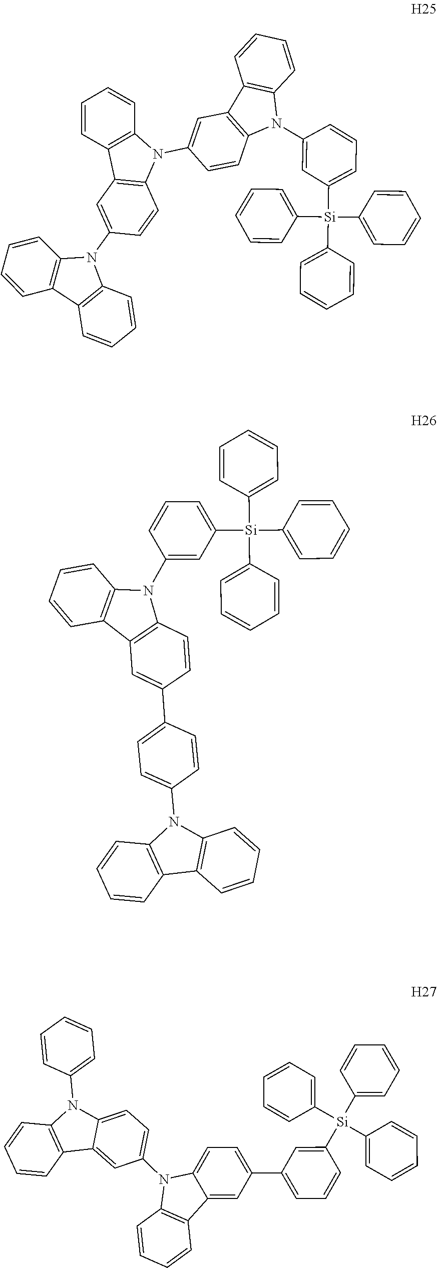 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2cccc(-n3c4ccccc4c4cc(-c5ccc(-n6c7ccccc7c7ccccc76)cc5)ccc43)c2)cc1 ; c1ccc(-n2c3ccccc3c3cc(-n4c5ccccc5c5cc(-c6cccc([Si](c7ccccc7)(c7ccccc7)c7ccccc7)c6)ccc54)ccc32)cc1]

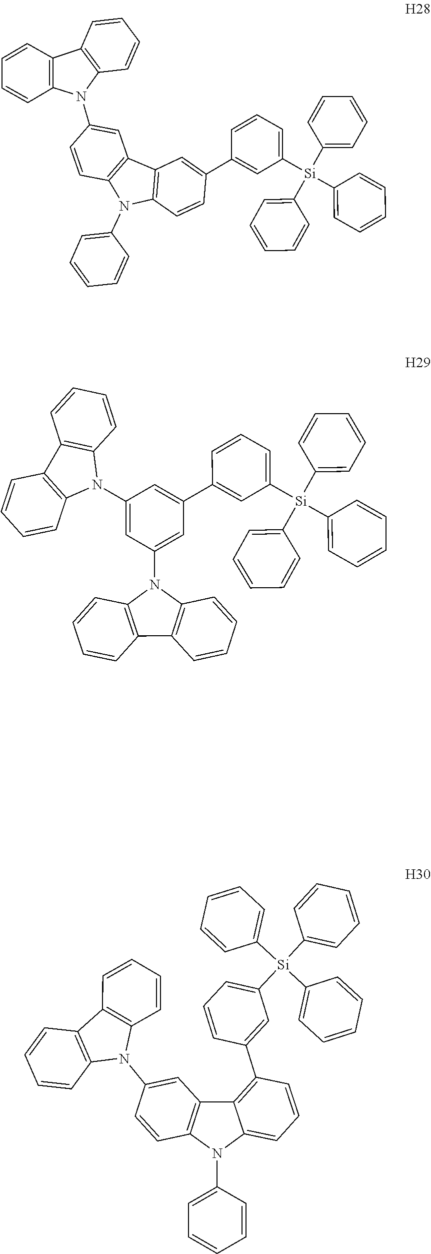 [SMILES: c1ccc(-n2c3ccc(-c4cccc([Si](c5ccccc5)(c5ccccc5)c5ccccc5)c4)cc3c3cc(-n4c5ccccc5c5ccccc54)ccc32)cc1 ; c1ccc([Si](c2ccccc2)(c2ccccc2)c2cccc(-c3cc(-n4c5ccccc5c5ccccc54)cc(-n4c5ccccc5c5ccccc54)c3)c2)cc1 ; c1ccc(-n2c3ccc(-n4c5ccccc5c5ccccc54)cc3c3c(-c4cccc([Si](c5ccccc5)(c5ccccc5)c5ccccc5)c4)cccc32)cc1]

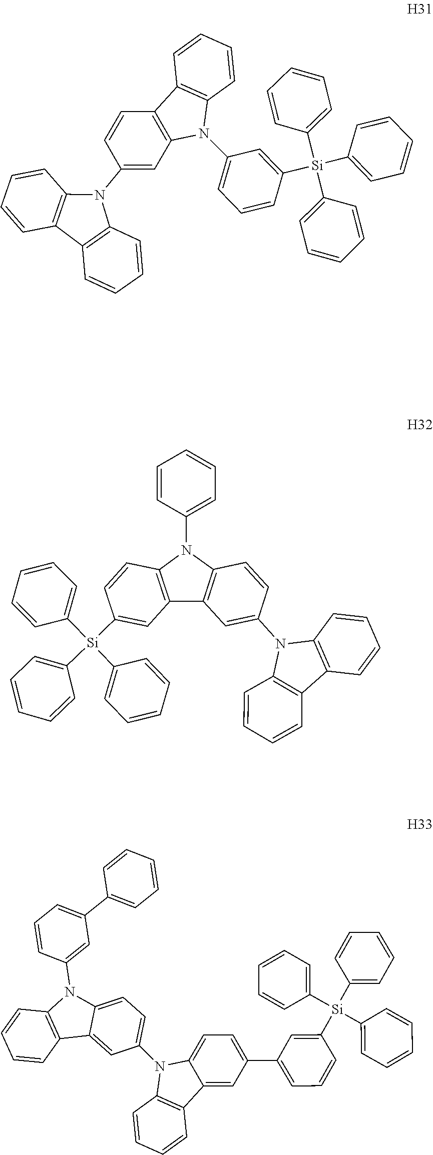 [SMILES: c1ccc([Si](c2ccccc2)(c2ccccc2)c2cccc(-n3c4ccccc4c4ccc(-n5c6ccccc6c6ccccc65)cc43)c2)cc1 ; c1ccc(-n2c3ccc(-n4c5ccccc5c5ccccc54)cc3c3cc([Si](c4ccccc4)(c4ccccc4)c4ccccc4)ccc32)cc1 ; c1ccc(-c2cccc(-n3c4ccccc4c4cc(-n5c6ccccc6c6cc(-c7cccc([Si](c8ccccc8)(c8ccccc8)c8ccccc8)c7)ccc65)ccc43)c2)cc1]

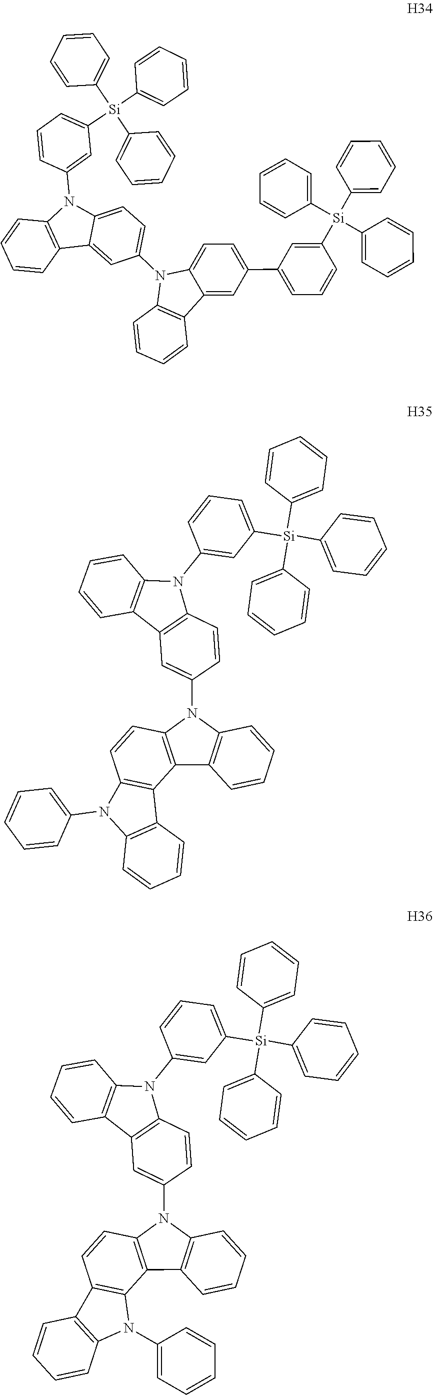 [SMILES: c1ccc([Si](c2ccccc2)(c2ccccc2)c2cccc(-c3ccc4c(c3)c3ccccc3n4-c3ccc4c(c3)c3ccccc3n4-c3cccc([Si](c4ccccc4)(c4ccccc4)c4ccccc4)c3)c2)cc1 ; c1ccc(-n2c3ccccc3c3c4c5ccccc5n(-c5ccc6c(c5)c5ccccc5n6-c5cccc([Si](c6ccccc6)(c6ccccc6)c6ccccc6)c5)c4ccc32)cc1 ; c1ccc(-n2c3ccccc3c3ccc4c(c5ccccc5n4-c4ccc5c(c4)c4ccccc4n5-c4cccc([Si](c5ccccc5)(c5ccccc5)c5ccccc5)c4)c32)cc1]

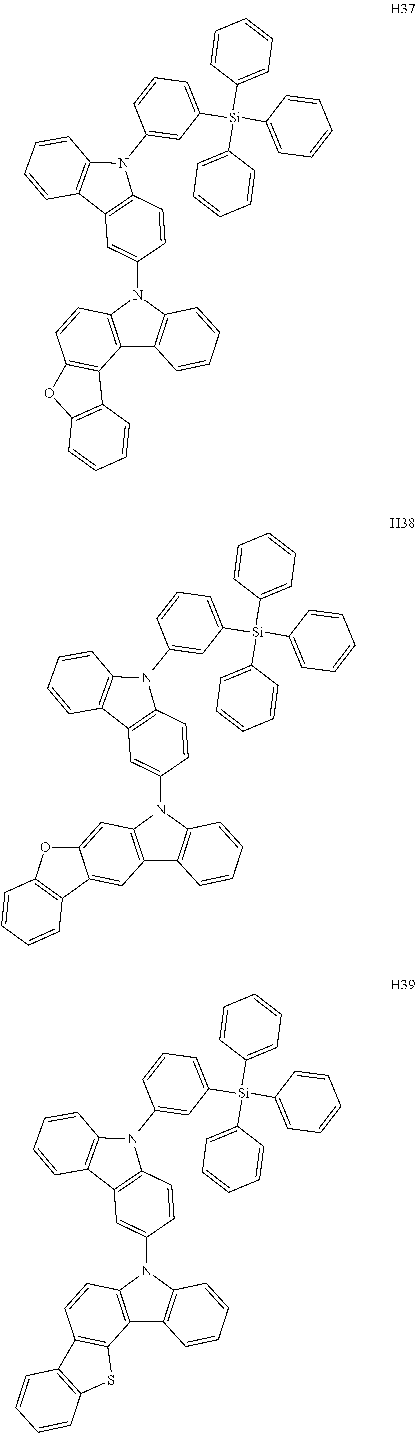 [SMILES: c1ccc([Si](c2ccccc2)(c2ccccc2)c2cccc(-n3c4ccccc4c4cc(-n5c6ccccc6c6c7c(ccc65)oc5ccccc57)ccc43)c2)cc1 ; c1ccc([Si](c2ccccc2)(c2ccccc2)c2cccc(-n3c4ccccc4c4cc(-n5c6ccccc6c6cc7c(cc65)oc5ccccc57)ccc43)c2)cc1 ; c1ccc([Si](c2ccccc2)(c2ccccc2)c2cccc(-n3c4ccccc4c4cc(-n5c6ccccc6c6c7sc8ccccc8c7ccc65)ccc43)c2)cc1]

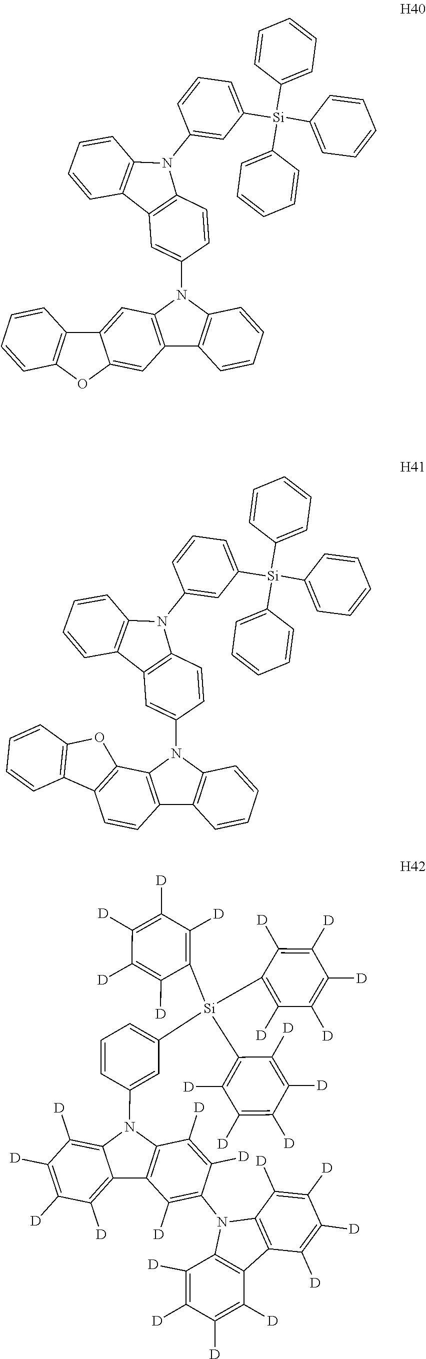 [SMILES: c1ccc([Si](c2ccccc2)(c2ccccc2)c2cccc(-n3c4ccccc4c4cc(-n5c6ccccc6c6cc7oc8ccccc8c7cc65)ccc43)c2)cc1 ; c1ccc([Si](c2ccccc2)(c2ccccc2)c2cccc(-n3c4ccccc4c4cc(-n5c6ccccc6c6ccc7c8ccccc8oc7c65)ccc43)c2)cc1 ; [2H]c1c([2H])c([2H])c([Si](c2cccc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2)(c2c([2H])c([2H])c([2H])c([2H])c2[2H])c2c([2H])c([2H])c([2H])c([2H])c2[2H])c([2H])c1[2H]]

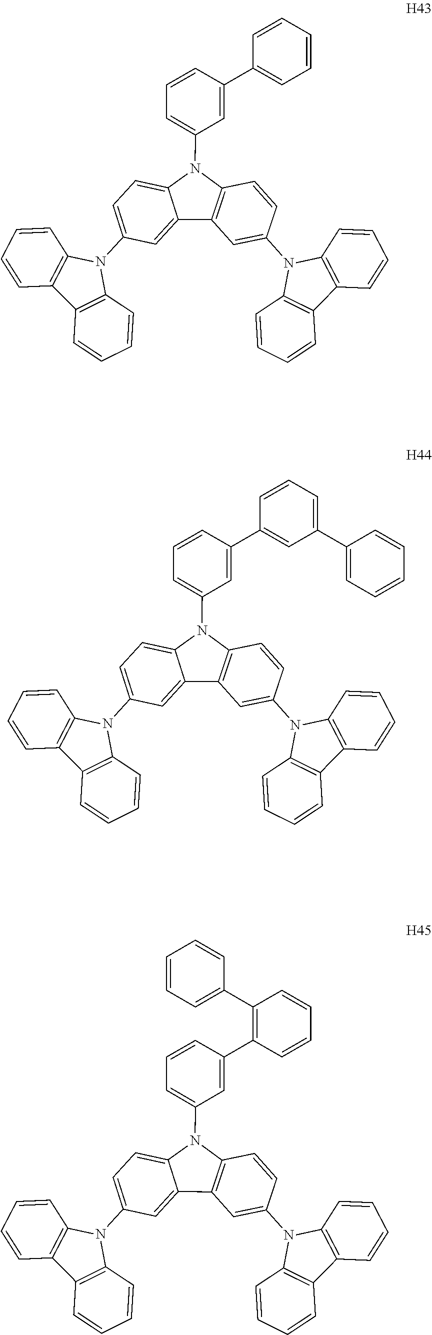 [SMILES: c1ccc(-c2cccc(-n3c4ccc(-n5c6ccccc6c6ccccc65)cc4c4cc(-n5c6ccccc6c6ccccc65)ccc43)c2)cc1 ; c1ccc(-c2cccc(-c3cccc(-n4c5ccc(-n6c7ccccc7c7ccccc76)cc5c5cc(-n6c7ccccc7c7ccccc76)ccc54)c3)c2)cc1 ; c1ccc(-c2ccccc2-c2cccc(-n3c4ccc(-n5c6ccccc6c6ccccc65)cc4c4cc(-n5c6ccccc6c6ccccc65)ccc43)c2)cc1]

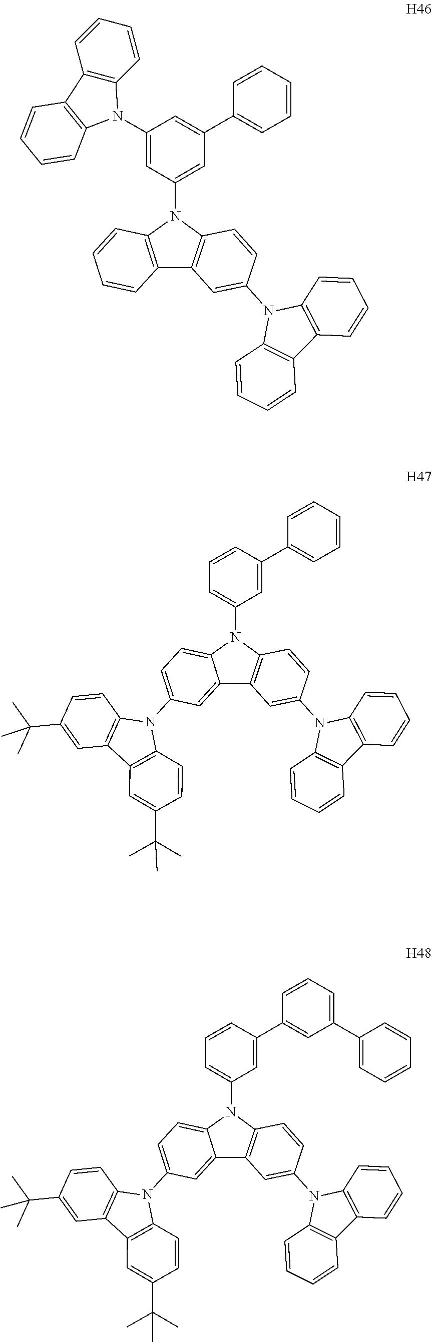 [SMILES: c1ccc(-c2cc(-n3c4ccccc4c4ccccc43)cc(-n3c4ccccc4c4cc(-n5c6ccccc6c6ccccc65)ccc43)c2)cc1 ; CC(C)(C)c1ccc2c(c1)c1cc(C(C)(C)C)ccc1n2-c1ccc2c(c1)c1cc(-n3c4ccccc4c4ccccc43)ccc1n2-c1cccc(-c2ccccc2)c1 ; CC(C)(C)c1ccc2c(c1)c1cc(C(C)(C)C)ccc1n2-c1ccc2c(c1)c1cc(-n3c4ccccc4c4ccccc43)ccc1n2-c1cccc(-c2cccc(-c3ccccc3)c2)c1]

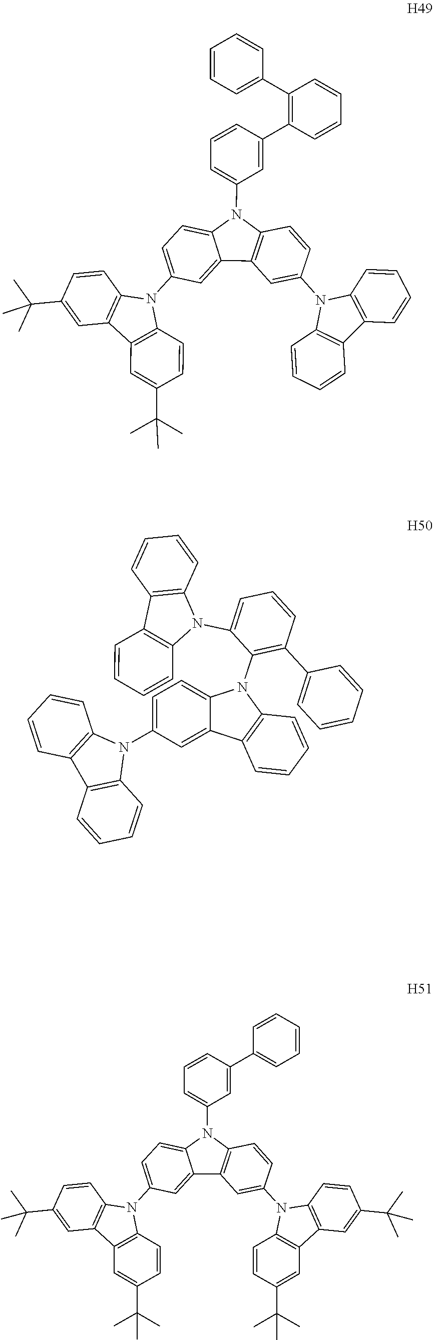 [SMILES: CC(C)(C)c1ccc2c(c1)c1cc(C(C)(C)C)ccc1n2-c1ccc2c(c1)c1cc(-n3c4ccccc4c4ccccc43)ccc1n2-c1cccc(-c2ccccc2-c2ccccc2)c1 ; c1ccc(-c2cccc(-n3c4ccccc4c4ccccc43)c2-n2c3ccccc3c3cc(-n4c5ccccc5c5ccccc54)ccc32)cc1 ; CC(C)(C)c1ccc2c(c1)c1cc(C(C)(C)C)ccc1n2-c1ccc2c(c1)c1cc(-n3c4ccc(C(C)(C)C)cc4c4cc(C(C)(C)C)ccc43)ccc1n2-c1cccc(-c2ccccc2)c1]

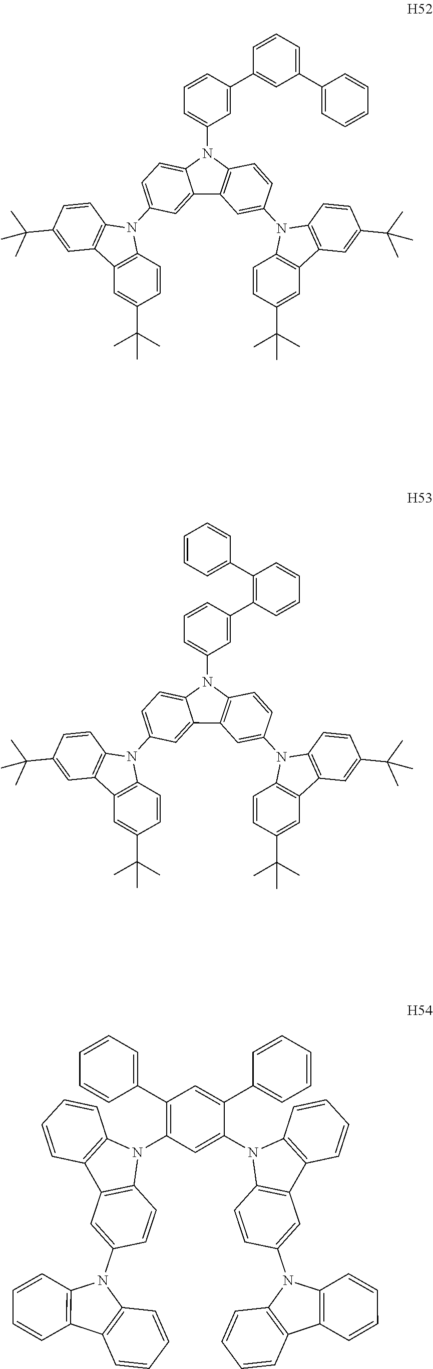

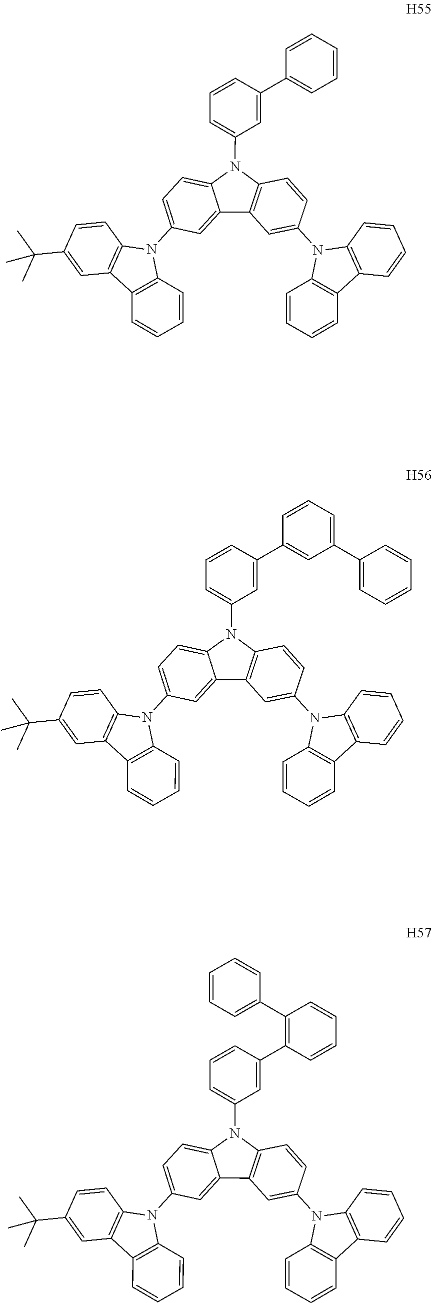 [SMILES: CC(C)(C)c1ccc2c(c1)c1ccccc1n2-c1ccc2c(c1)c1cc(-n3c4ccccc4c4ccccc43)ccc1n2-c1cccc(-c2ccccc2)c1 ; CC(C)(C)c1ccc2c(c1)c1ccccc1n2-c1ccc2c(c1)c1cc(-n3c4ccccc4c4ccccc43)ccc1n2-c1cccc(-c2cccc(-c3ccccc3)c2)c1 ; CC(C)(C)c1ccc2c(c1)c1ccccc1n2-c1ccc2c(c1)c1cc(-n3c4ccccc4c4ccccc43)ccc1n2-c1cccc(-c2ccccc2-c2ccccc2)c1]

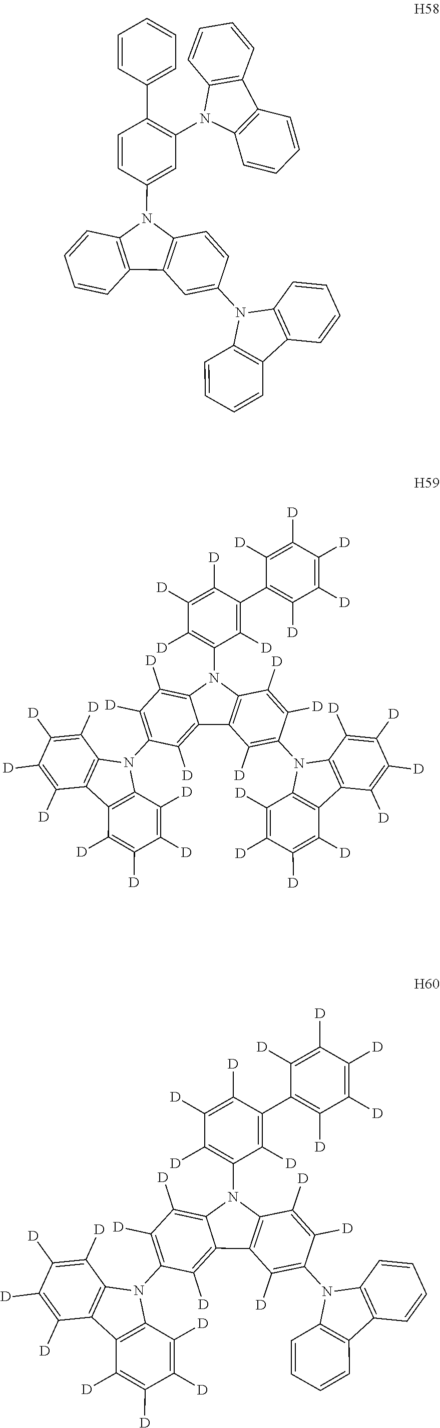

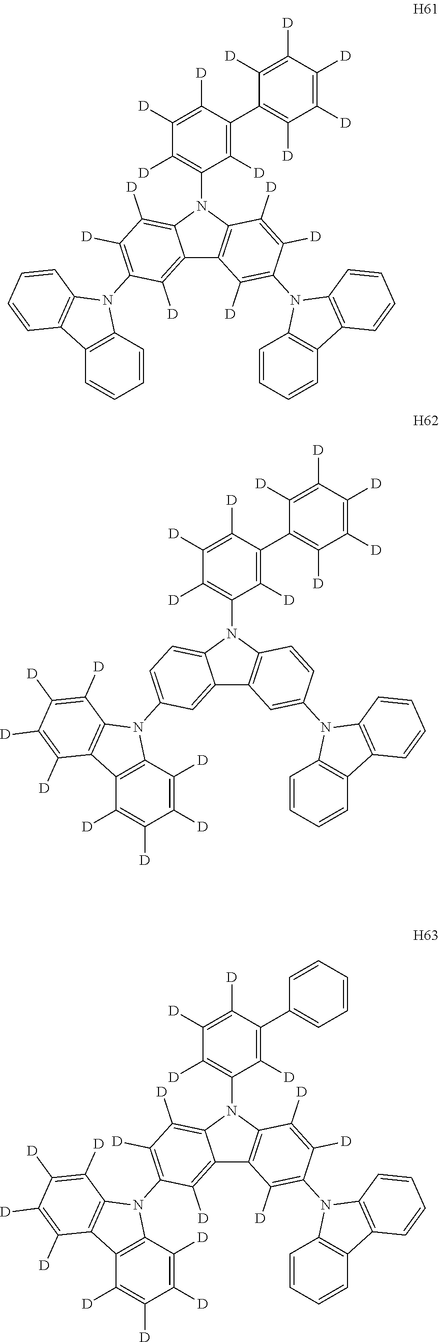

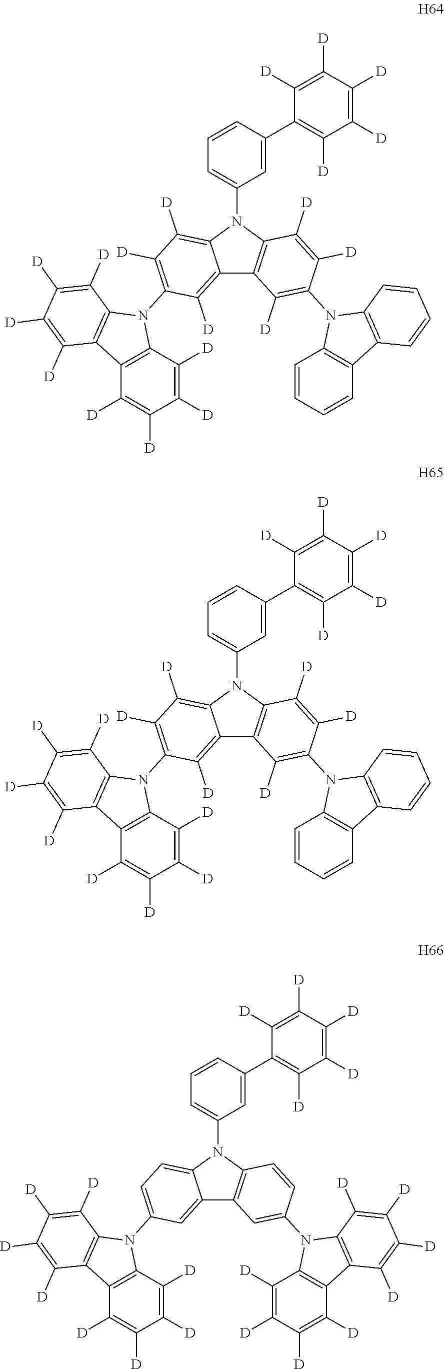

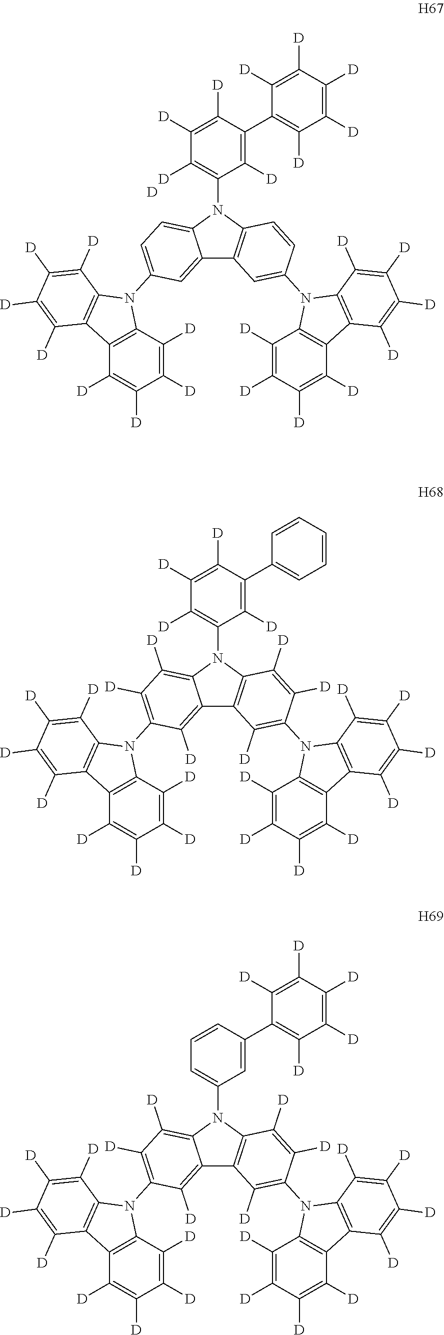

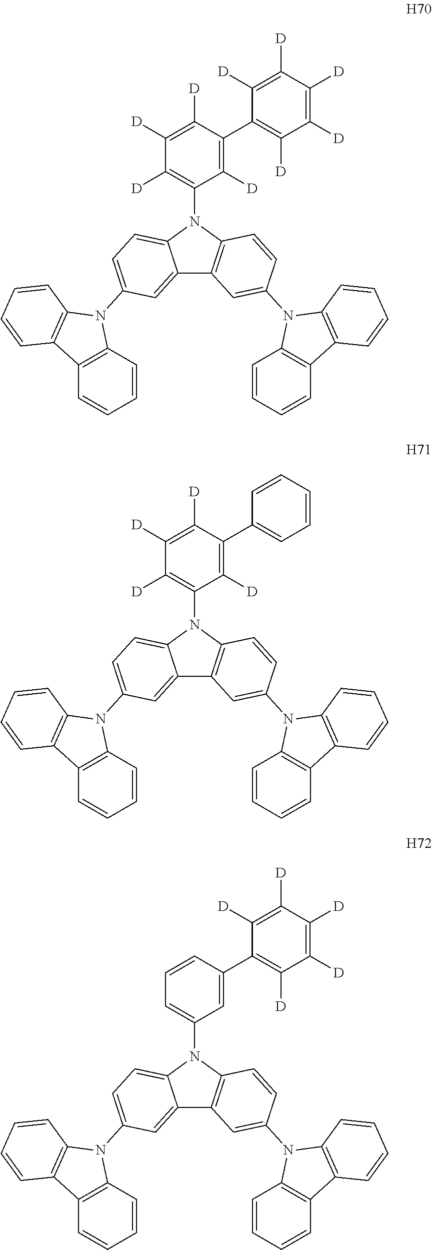 [SMILES: [2H]c1c([2H])c([2H])c(-c2c([2H])c([2H])c([2H])c(-n3c4ccc(-n5c6ccccc6c6ccccc65)cc4c4cc(-n5c6ccccc6c6ccccc65)ccc43)c2[2H])c([2H])c1[2H] ; [2H]c1c([2H])c(-c2ccccc2)c([2H])c(-n2c3ccc(-n4c5ccccc5c5ccccc54)cc3c3cc(-n4c5ccccc5c5ccccc54)ccc32)c1[2H] ; [2H]c1c([2H])c([2H])c(-c2cccc(-n3c4ccc(-n5c6ccccc6c6ccccc65)cc4c4cc(-n5c6ccccc6c6ccccc65)ccc43)c2)c([2H])c1[2H]]

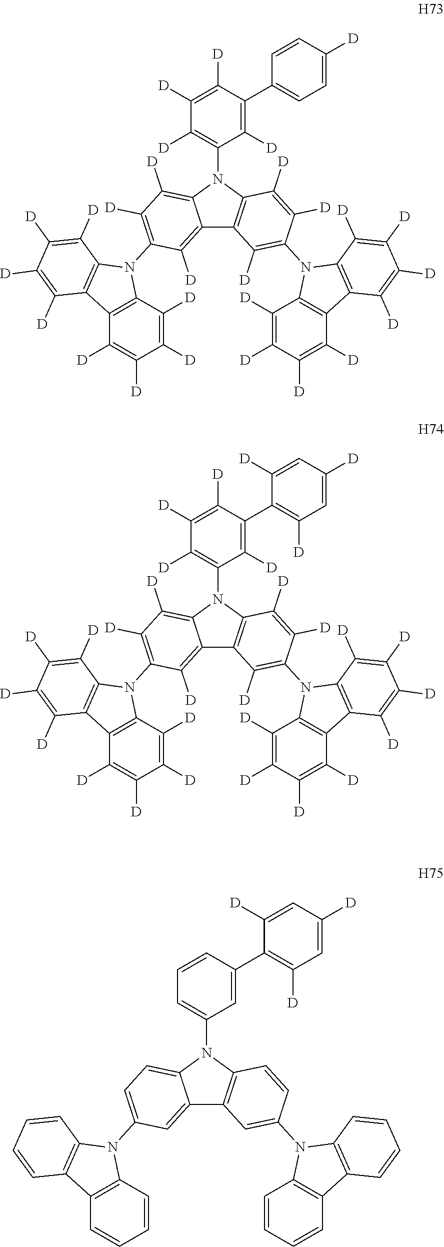

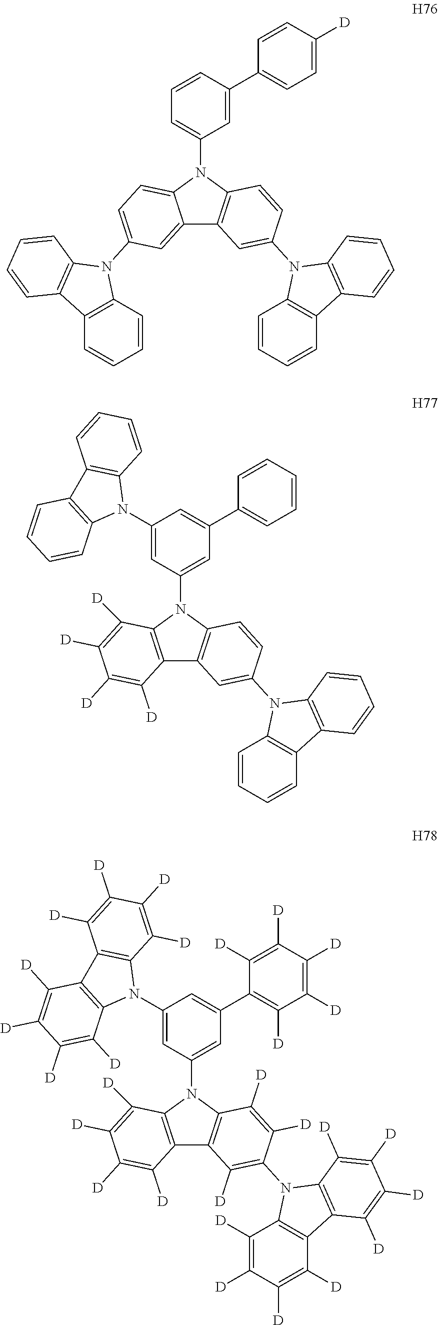 [SMILES: [2H]c1ccc(-c2cccc(-n3c4ccc(-n5c6ccccc6c6ccccc65)cc4c4cc(-n5c6ccccc6c6ccccc65)ccc43)c2)cc1 ; [2H]c1c([2H])c([2H])c2c(c1[2H])c1cc(-n3c4ccccc4c4ccccc43)ccc1n2-c1cc(-c2ccccc2)cc(-n2c3ccccc3c3ccccc32)c1 ; [2H]c1c([2H])c([2H])c(-c2cc(-n3c4c([2H])c([2H])c([2H])c([2H])c4c4c([2H])c([2H])c([2H])c([2H])c43)cc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2)c([2H])c1[2H]]

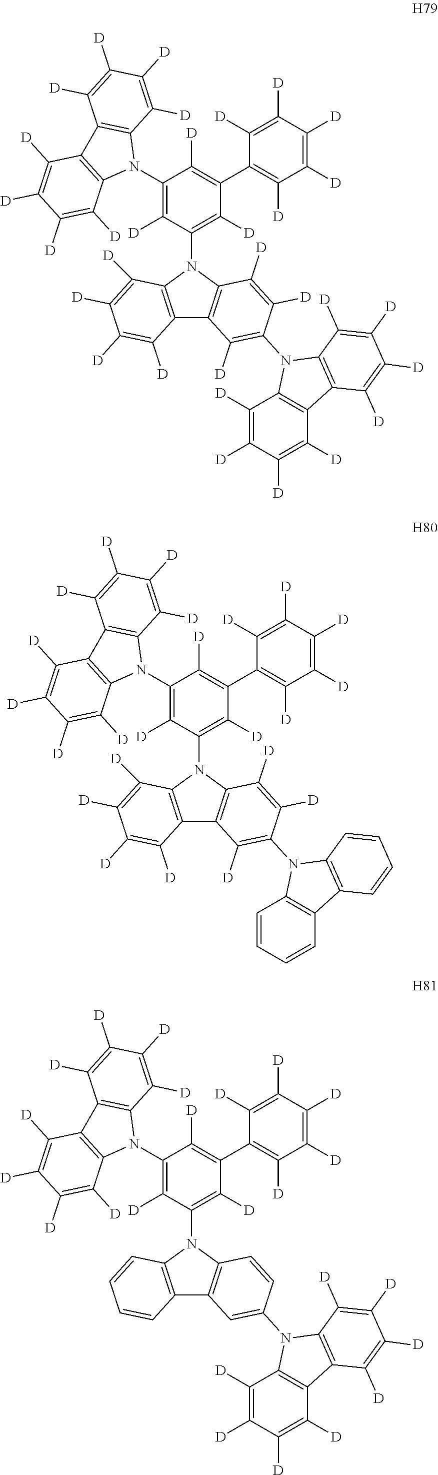

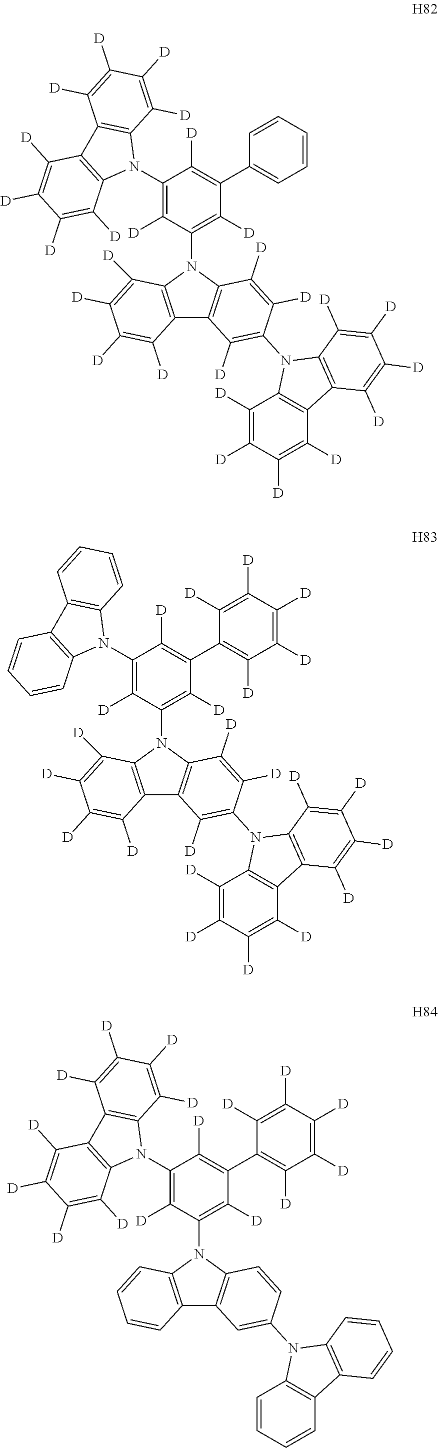

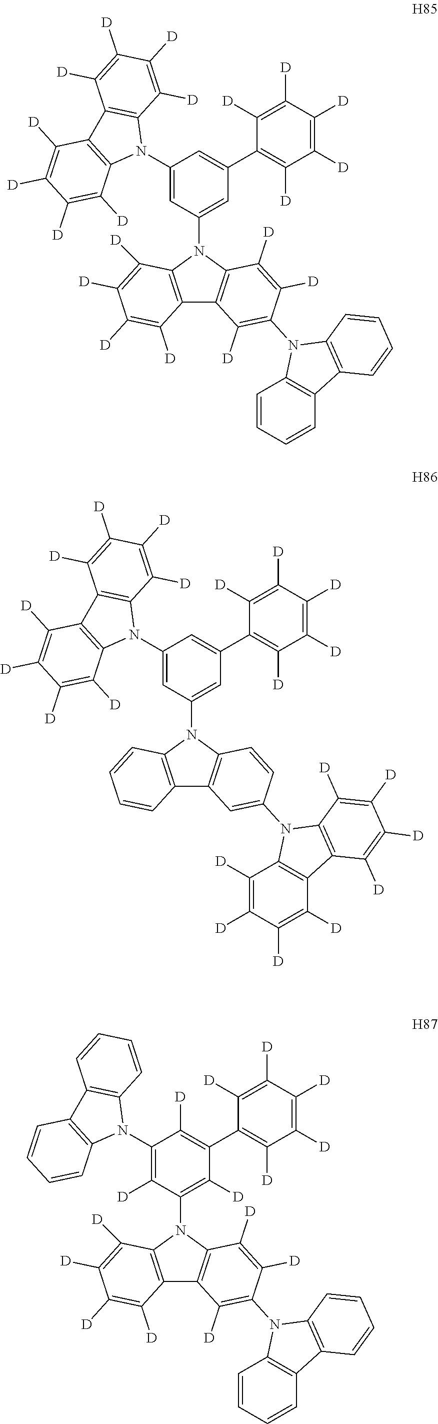

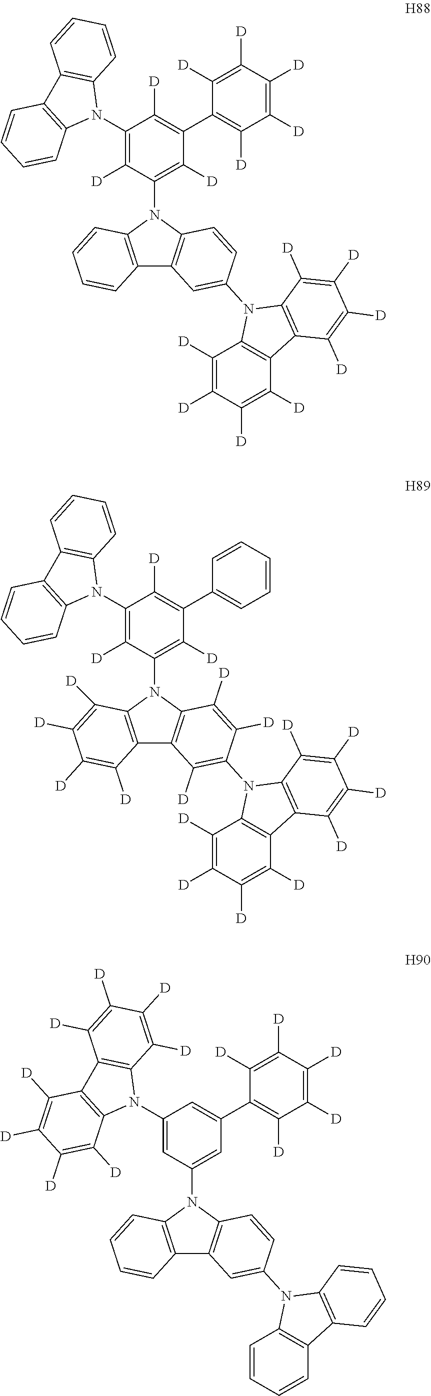

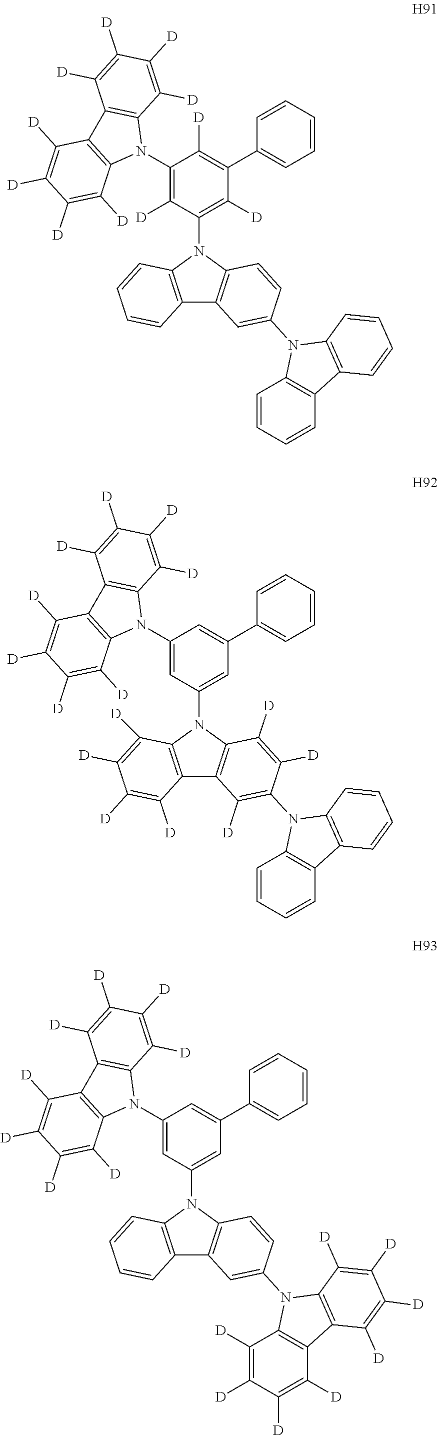

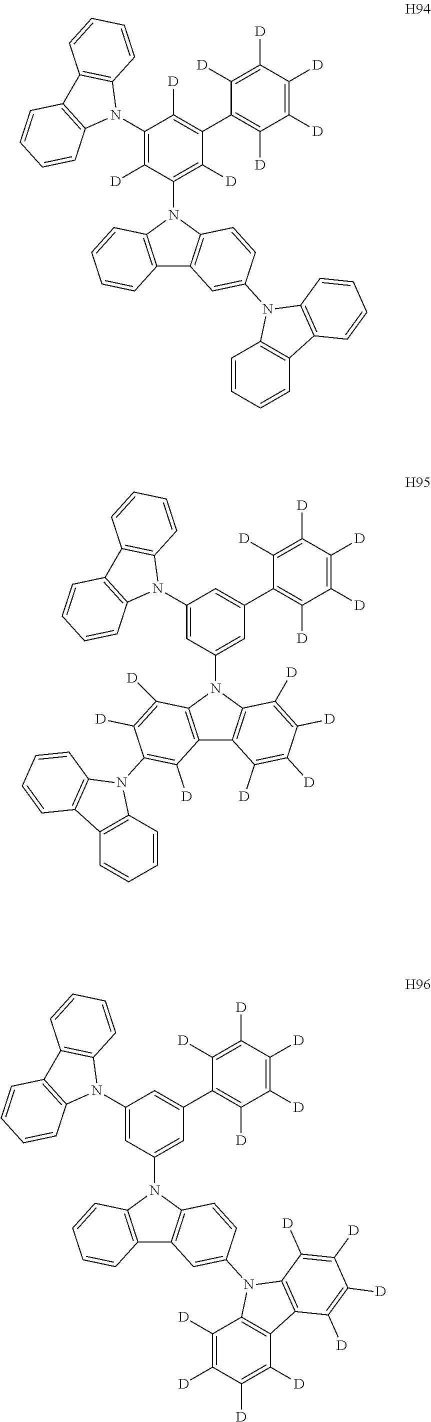 [SMILES: [2H]c1c([2H])c([2H])c(-c2c([2H])c(-n3c4ccccc4c4ccccc43)c([2H])c(-n3c4ccccc4c4cc(-n5c6ccccc6c6ccccc65)ccc43)c2[2H])c([2H])c1[2H] ; [2H]c1c([2H])c([2H])c(-c2cc(-n3c4ccccc4c4ccccc43)cc(-n3c4c([2H])c([2H])c([2H])c([2H])c4c4c([2H])c(-n5c6ccccc6c6ccccc65)c([2H])c([2H])c43)c2)c([2H])c1[2H] ; [2H]c1c([2H])c([2H])c(-c2cc(-n3c4ccccc4c4ccccc43)cc(-n3c4ccccc4c4cc(-n5c6c([2H])c([2H])c([2H])c([2H])c6c6c([2H])c([2H])c([2H])c([2H])c65)ccc43)c2)c([2H])c1[2H]]

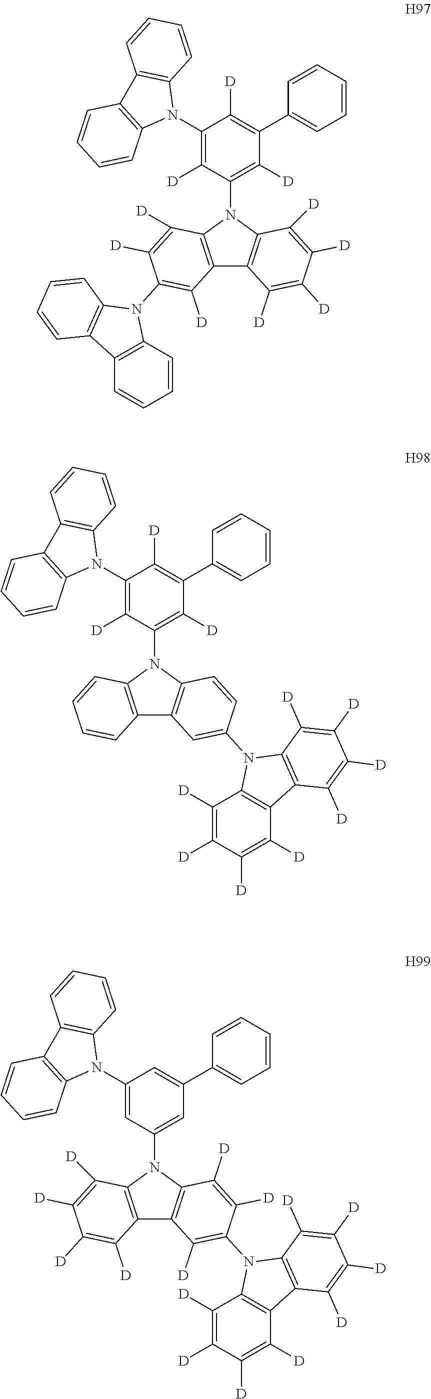 [SMILES: [2H]c1c(-c2ccccc2)c([2H])c(-n2c3c([2H])c([2H])c([2H])c([2H])c3c3c([2H])c(-n4c5ccccc5c5ccccc54)c([2H])c([2H])c32)c([2H])c1-n1c2ccccc2c2ccccc21 ; [2H]c1c(-c2ccccc2)c([2H])c(-n2c3ccccc3c3cc(-n4c5c([2H])c([2H])c([2H])c([2H])c5c5c([2H])c([2H])c([2H])c([2H])c54)ccc32)c([2H])c1-n1c2ccccc2c2ccccc21 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cc(-c2ccccc2)cc(-n2c3ccccc3c3ccccc32)c1]

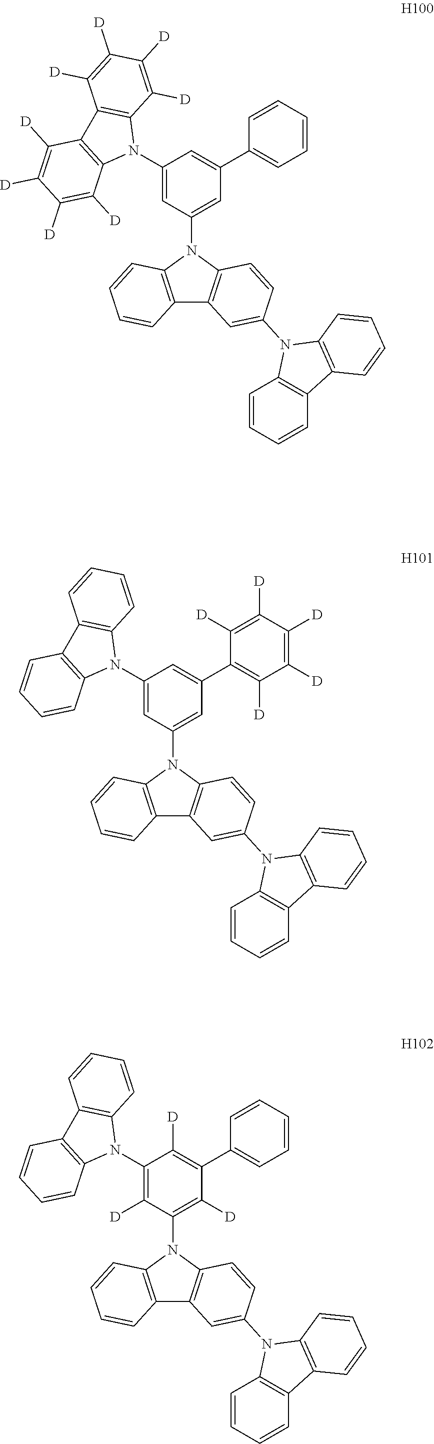 [SMILES: [2H]c1c([2H])c([2H])c2c(c1[2H])c1c([2H])c([2H])c([2H])c([2H])c1n2-c1cc(-c2ccccc2)cc(-n2c3ccccc3c3cc(-n4c5ccccc5c5ccccc54)ccc32)c1 ; [2H]c1c([2H])c([2H])c(-c2cc(-n3c4ccccc4c4ccccc43)cc(-n3c4ccccc4c4cc(-n5c6ccccc6c6ccccc65)ccc43)c2)c([2H])c1[2H] ; [2H]c1c(-c2ccccc2)c([2H])c(-n2c3ccccc3c3cc(-n4c5ccccc5c5ccccc54)ccc32)c([2H])c1-n1c2ccccc2c2ccccc21]

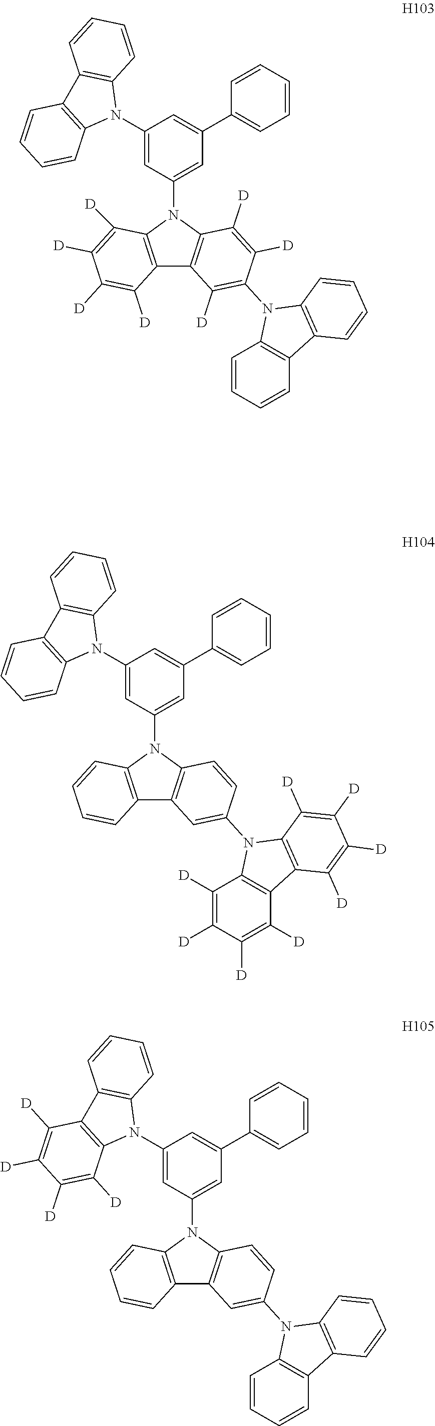 [SMILES: [2H]c1c([2H])c([2H])c2c(c1[2H])c1c([2H])c(-n3c4ccccc4c4ccccc43)c([2H])c([2H])c1n2-c1cc(-c2ccccc2)cc(-n2c3ccccc3c3ccccc32)c1 ; [2H]c1c([2H])c([2H])c2c(c1[2H])c1c([2H])c([2H])c([2H])c([2H])c1n2-c1ccc2c(c1)c1ccccc1n2-c1cc(-c2ccccc2)cc(-n2c3ccccc3c3ccccc32)c1 ; [2H]c1c([2H])c([2H])c2c(c1[2H])c1ccccc1n2-c1cc(-c2ccccc2)cc(-n2c3ccccc3c3cc(-n4c5ccccc5c5ccccc54)ccc32)c1]

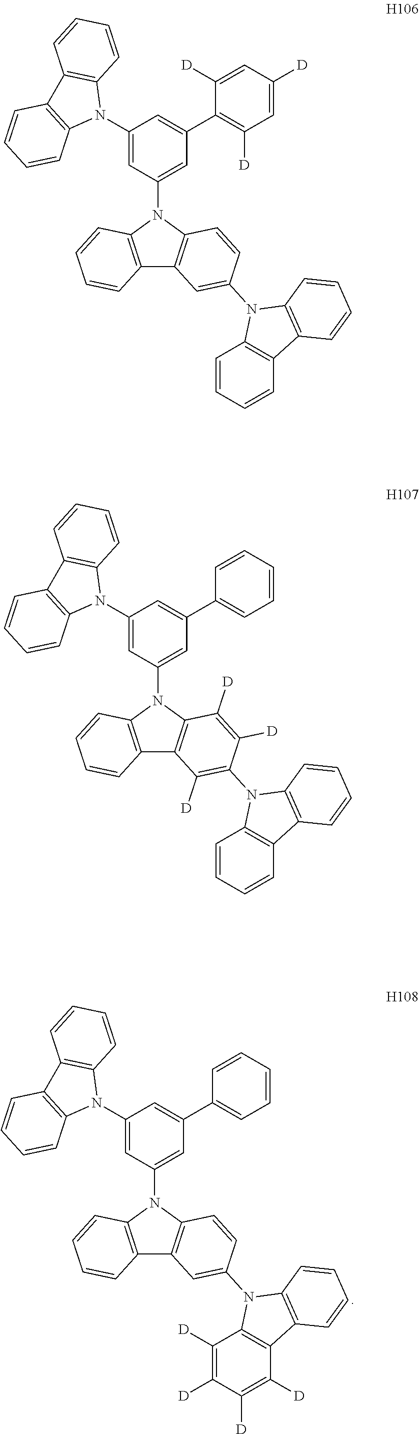 [SMILES: [2H]c1cc([2H])c(-c2cc(-n3c4ccccc4c4ccccc43)cc(-n3c4ccccc4c4cc(-n5c6ccccc6c6ccccc65)ccc43)c2)c([2H])c1 ; [2H]c1c(-n2c3ccccc3c3ccccc32)c([2H])c2c3ccccc3n(-c3cc(-c4ccccc4)cc(-n4c5ccccc5c5ccccc54)c3)c2c1[2H] ; [2H]c1c([2H])c([2H])c2c(c1[2H])c1ccccc1n2-c1ccc2c(c1)c1ccccc1n2-c1cc(-c2ccccc2)cc(-n2c3ccccc3c3ccccc32)c1]

### Third Compound

In an embodiment, the interlayer may further include a third compound including a polycyclic group in which at least 3 single rings are condensed. The emission layer may include the third compound. That is, the third compound may be present in the emission layer. The third compound may be a thermally activated delayed fluorescence material. The third compound may include at least one of boron (B) and nitrogen (N). For example, the third compound may include a polycyclic group including boron and/or nitrogen as ring-forming atoms.

The third compound may emit blue light. An energy difference (ΔE_{ST}) between a lowest singlet excited state (S₁) and a lowest triplet excited state (T₁) of the third compound may be less than 0.3 eV. For example, ΔE_{ST} of the third compound may be greater than 0 eV and less than 0.3 eV, about 0.05 eV to about 0.25 eV, or about 0.1 eV to about 0.2 eV.

In an embodiment, the third compound may include a group represented by Formula 50-1 or 50-2:

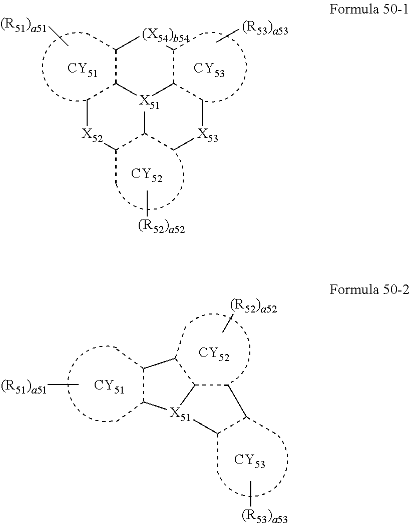

wherein, in Formulae 50-1 and 50-2,
X₅₁ may be boron (B) or nitrogen (N),
X₅₂ may be a single bond, *—N(R₅₄)—*′, *—B(R₅₄)—*′, *—P(R₅₄)—*′, *—C(R₅₄)(R₅₅)—*′, *—Si(R₅₄)(R₅₅)—*′, *—Ge(R₅₄)(R₅₅)—*′, *—O—*′, *—S—*′, *—Se—*′, *—C(═O)—*′, or *—S(═O)₂—*′,
X₅₃ may be a single bond, *—N(R₅₆)—*′, *—B(R₅₆)—*′, *—P(R₅₆)—*′, *—C(R₅₆)(R₅₇)—*′, *—Si(R₅₆)(R₅₇)—*′, *—Ge(R₅₆)(R₅₇)—*′, *—O—*′, *—S—*′, *—Se—*′, *—C(═O)—*′, or *—S(═O)₂—*′,
X₅₄ may be a single bond, *—N(R₅₈)—*′, *—B(R₅₈)—*′, *—P(R₅₈)—*′, *—C(R₅₈)(R₅₉)—*′, *—Si(R₅₈)(R₅₉)—*′, *—Ge(R₅₈)(R₅₉)—*′, *—O—*′, *—S—*′, *—Se—*′, *—C(═O)—*′, or *—S(═O)₂—*′, b₅₄ may be 0 or 1,
when b₅₄ is 0, (X₅₄)_{b54} may not be present,
R₅₁ to R₅₉ may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ heteroaryl alkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
a51 to a53 may each independently be an integer from 0 to 20,
two or more of R₅₁ in the number of a51 may optionally be bonded to each other to form a C₅-C₃₀ carbocyclic group unsubstituted or substituted with at least one R_{10b} or a C₁-C₆₀ heterocyclic group unsubstituted or substituted with at least one R_{10b},
two or more of R₅₂ in the number of a52 may optionally be bonded to each other to form a C₅-C₃₀ carbocyclic group unsubstituted or substituted with at least one R_{10b} or a C₁-C₆₀ heterocyclic group unsubstituted or substituted with at least one R_{10b},
two or more of R₅₃ in the number of a53 may optionally be bonded to each other to form a C₅-C₃₀ carbocyclic group unsubstituted or substituted with at least one R_{10b} or a C₁-C₆₀ heterocyclic group unsubstituted or substituted with at least one R_{10b}, two or more of R₅₁ to R₅₉ may optionally be bonded to each other to form a C₅-C₃₀ carbocyclic group unsubstituted or substituted with at least one R_{10b} or a C₁-C₃₀ heterocyclic group unsubstituted or substituted with at least one R_{10b},
R_{10b} is the same as described in connection with R₅₁,
* and *′ each indicate a binding site to a neighboring atom,
a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ heteroaryl alkyl group, the substituted monovalent non-aromatic condensed polycyclic group, and the substituted monovalent non-aromatic condensed heteropolycyclic group may be
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
any combination thereof, and
Q₁ to Q₉, Q₁₁ to Q₁₉, Q₂₁ to Q₂₉, and Q₃₁ to Q₃₉ may each independently be: hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

In an embodiment, the third compound may be a compound represented by any one of Formulae 50-1(1), 50-1(2), 50-2(1), 50-2(2), 50-2(3), and 50-2(4):

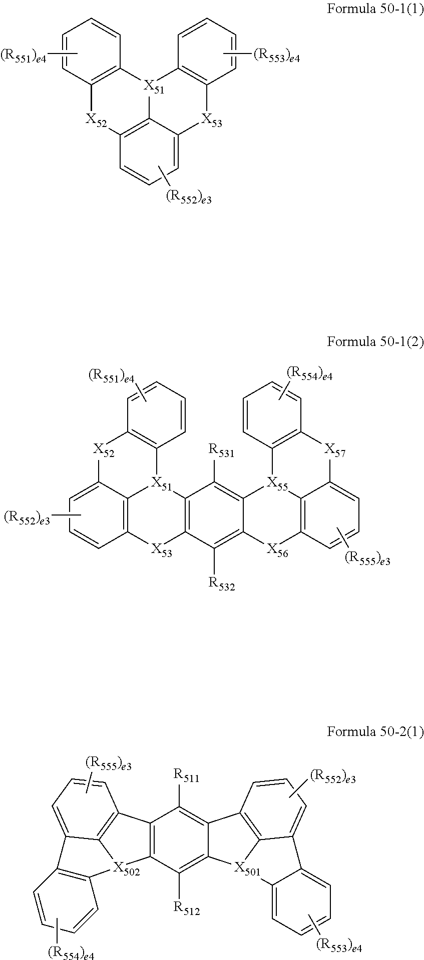

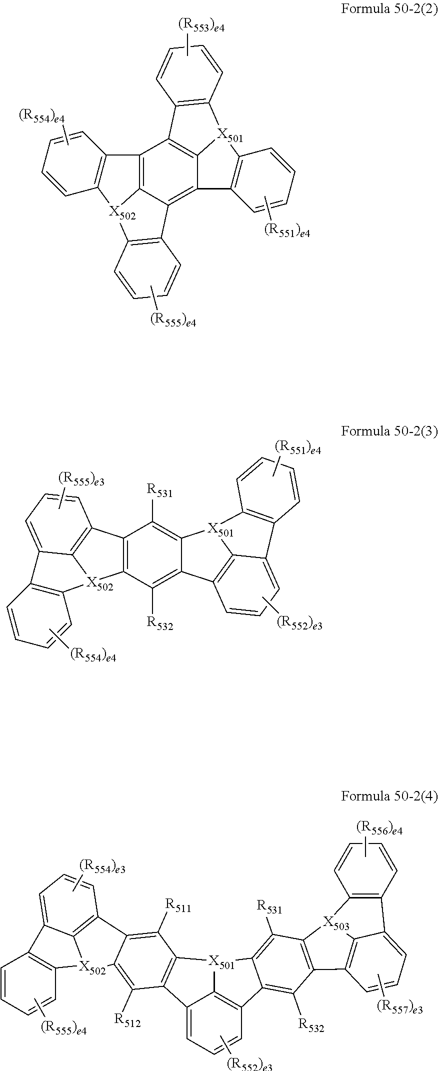

wherein, in Formulae 50-1(1), 50-1(2), 50-2(1), 50-2(2), 50-2(3), and 50-2(4),
X₅₁, X₅₅, X₅₀₁, X₅₀₂, and X₅₀₃ may each be B or N,
X₅₂ and X₅₃ are each the same as described herein,
X₅₆ and X₅₇ are each the same as described herein in connection with X₅₂ and X₅₃,
R₅₅₁, R₅₁₁, R₅₁₂, and R₅₅₄ are each the same as described herein in connection with R₅₁, R₅₅₂ and R₅₅₅ are each the same as described herein in connection with R₅₂, and R₅₅₃, R₅₃₁, and R₅₃₂ are each the same as described herein in connection with R₅₃,
e3 may be an integer from 0 to 3, and
e4 may be an integer from 0 to 4.

### Specific Examples of the Third Compound

In an embodiment, the third compound may be selected from Compounds D1 to D30:

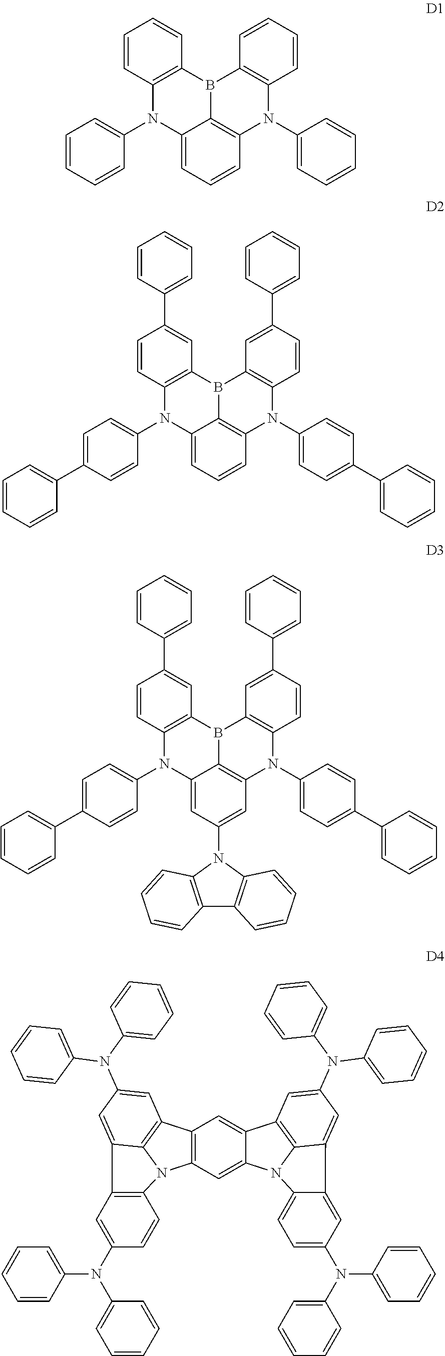 [SMILES: c1ccc(N2c3ccccc3B3c4ccccc4N(c4ccccc4)c4cccc2c43)cc1 ; c1ccc(-c2ccc(N3c4ccc(-c5ccccc5)cc4B4c5cc(-c6ccccc6)ccc5N(c5ccc(-c6ccccc6)cc5)c5cccc3c54)cc2)cc1 ; c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1 ; c1ccc(N(c2ccccc2)c2ccc3c(c2)c2cc(N(c4ccccc4)c4ccccc4)cc4c5cc6c7cc(N(c8ccccc8)c8ccccc8)cc8c9cc(N(c%10ccccc%10)c%10ccccc%10)ccc9n(c6cc5n3c24)c87)cc1]

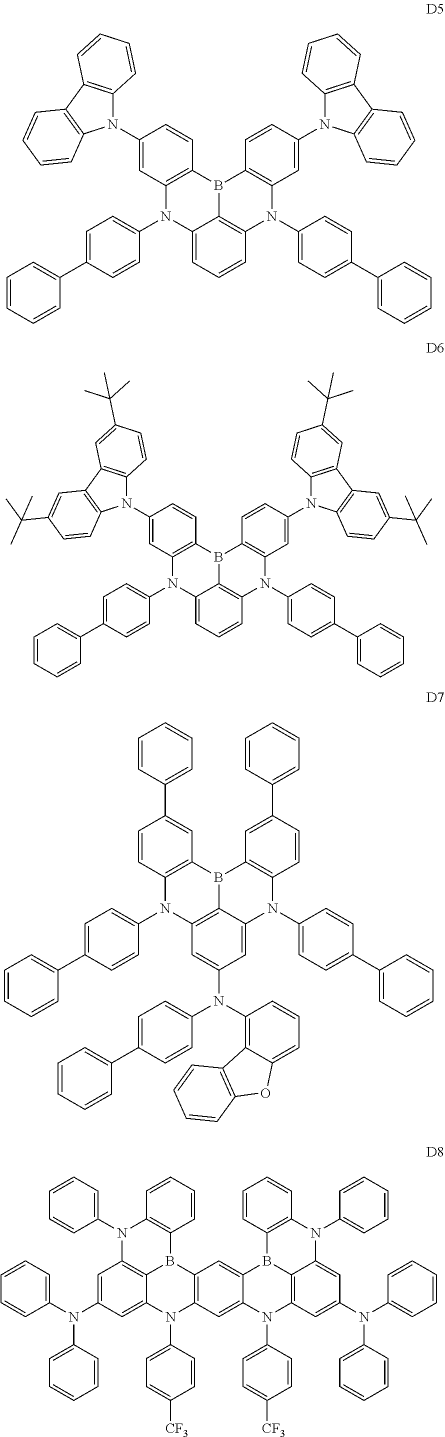

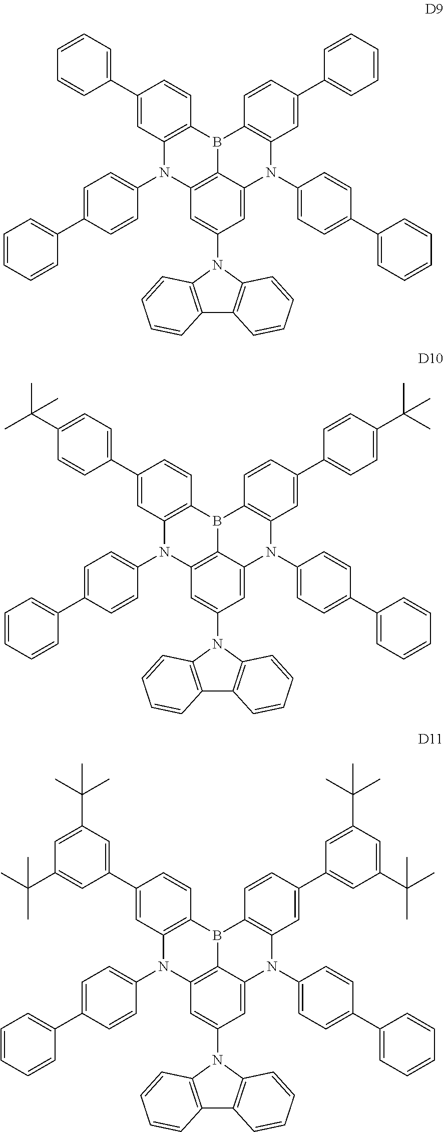 [SMILES: c1ccc(-c2ccc(N3c4cc(-c5ccccc5)ccc4B4c5ccc(-c6ccccc6)cc5N(c5ccc(-c6ccccc6)cc5)c5cc(-n6c7ccccc7c7ccccc76)cc3c54)cc2)cc1 ; CC(C)(C)c1ccc(-c2ccc3c(c2)N(c2ccc(-c4ccccc4)cc2)c2cc(-n4c5ccccc5c5ccccc54)cc4c2B3c2ccc(-c3ccc(C(C)(C)C)cc3)cc2N4c2ccc(-c3ccccc3)cc2)cc1 ; CC(C)(C)c1cc(-c2ccc3c(c2)N(c2ccc(-c4ccccc4)cc2)c2cc(-n4c5ccccc5c5ccccc54)cc4c2B3c2ccc(-c3cc(C(C)(C)C)cc(C(C)(C)C)c3)cc2N4c2ccc(-c3ccccc3)cc2)cc(C(C)(C)C)c1]

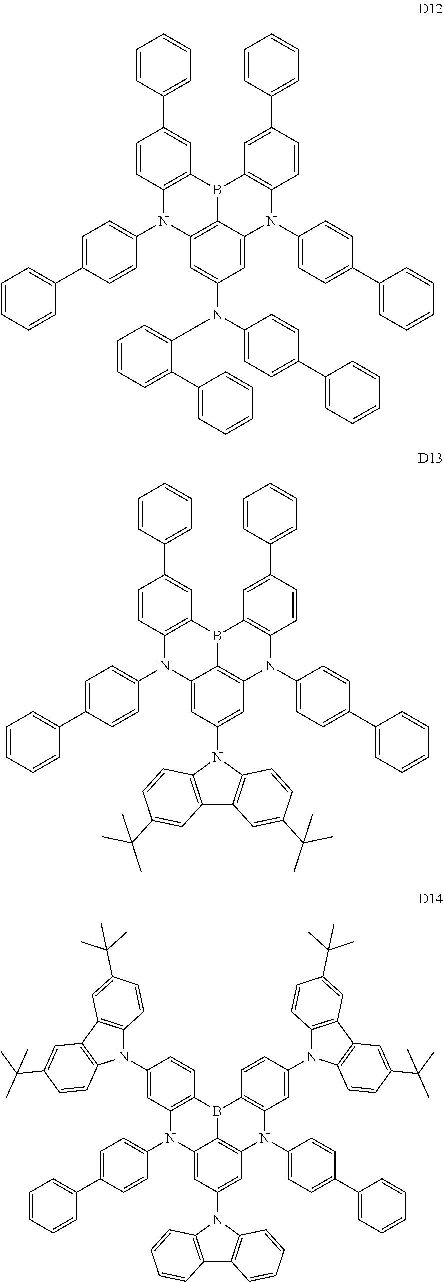 [SMILES: c1ccc(-c2ccc(N(c3cc4c5c(c3)N(c3ccc(-c6ccccc6)cc3)c3ccc(-c6ccccc6)cc3B5c3cc(-c5ccccc5)ccc3N4c3ccc(-c4ccccc4)cc3)c3ccccc3-c3ccccc3)cc2)cc1 ; CC(C)(C)c1ccc2c(c1)c1cc(C(C)(C)C)ccc1n2-c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; CC(C)(C)c1ccc2c(c1)c1cc(C(C)(C)C)ccc1n2-c1ccc2c(c1)N(c1ccc(-c3ccccc3)cc1)c1cc(-n3c4ccccc4c4ccccc43)cc3c1B2c1ccc(-n2c4ccc(C(C)(C)C)cc4c4cc(C(C)(C)C)ccc42)cc1N3c1ccc(-c2ccccc2)cc1]

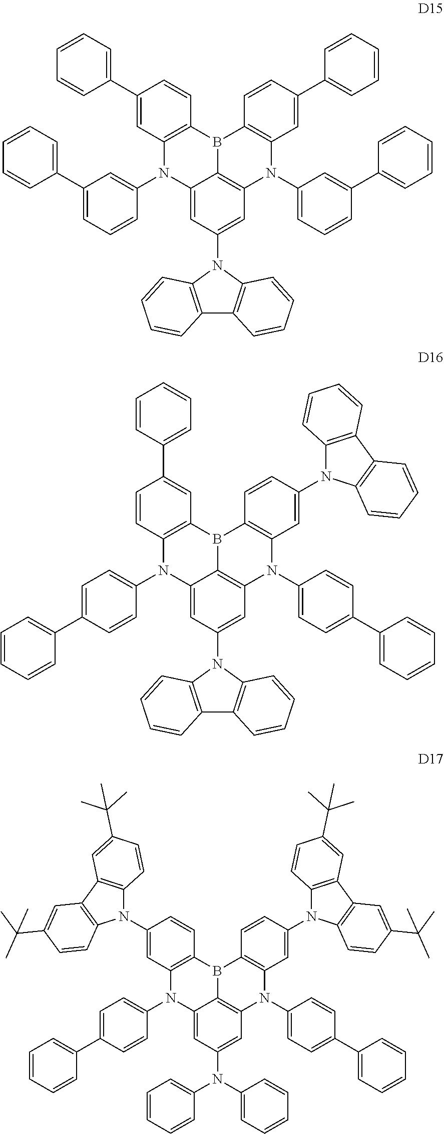 [SMILES: c1ccc(-c2cccc(N3c4cc(-c5ccccc5)ccc4B4c5ccc(-c6ccccc6)cc5N(c5cccc(-c6ccccc6)c5)c5cc(-n6c7ccccc7c7ccccc76)cc3c54)c2)cc1 ; c1ccc(-c2ccc(N3c4ccc(-c5ccccc5)cc4B4c5ccc(-n6c7ccccc7c7ccccc76)cc5N(c5ccc(-c6ccccc6)cc5)c5cc(-n6c7ccccc7c7ccccc76)cc3c54)cc2)cc1 ; CC(C)(C)c1ccc2c(c1)c1cc(C(C)(C)C)ccc1n2-c1ccc2c(c1)N(c1ccc(-c3ccccc3)cc1)c1cc(N(c3ccccc3)c3ccccc3)cc3c1B2c1ccc(-n2c4ccc(C(C)(C)C)cc4c4cc(C(C)(C)C)ccc42)cc1N3c1ccc(-c2ccccc2)cc1]

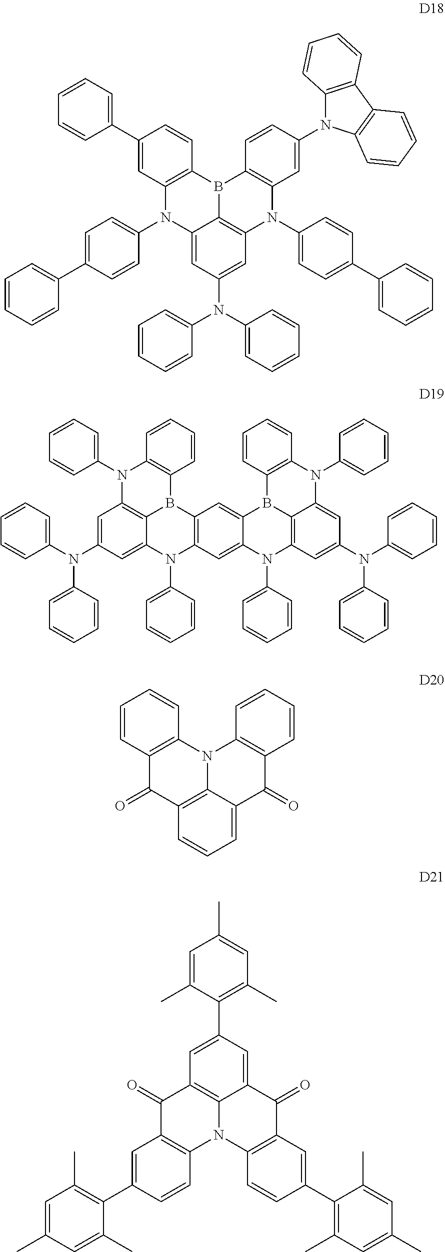

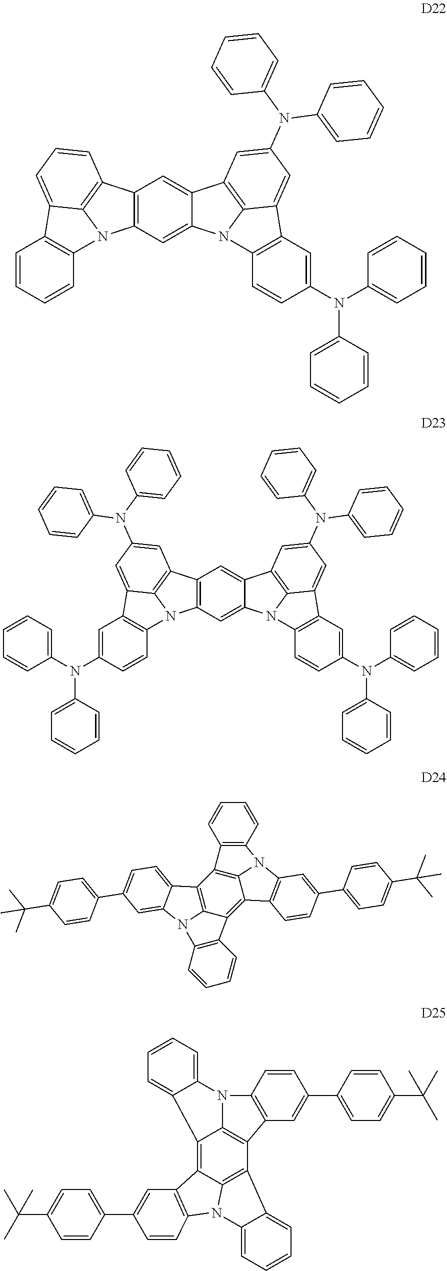

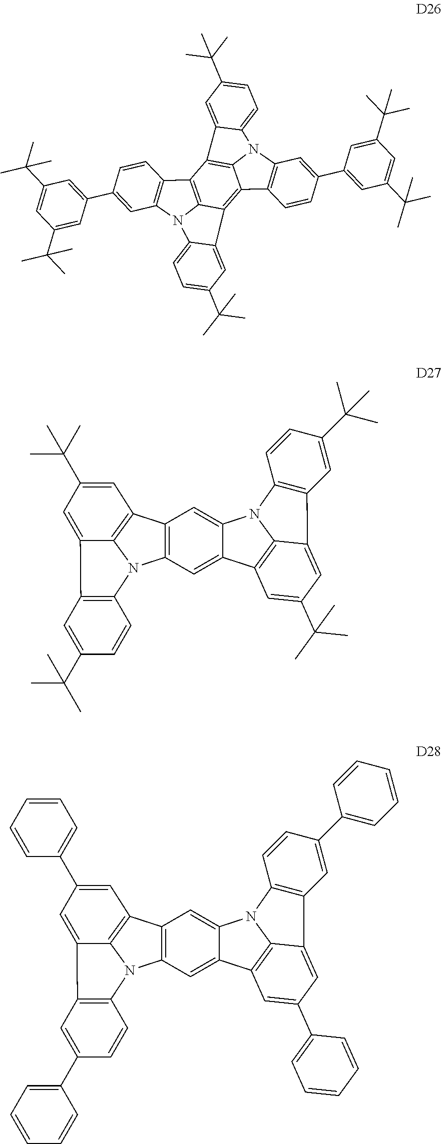

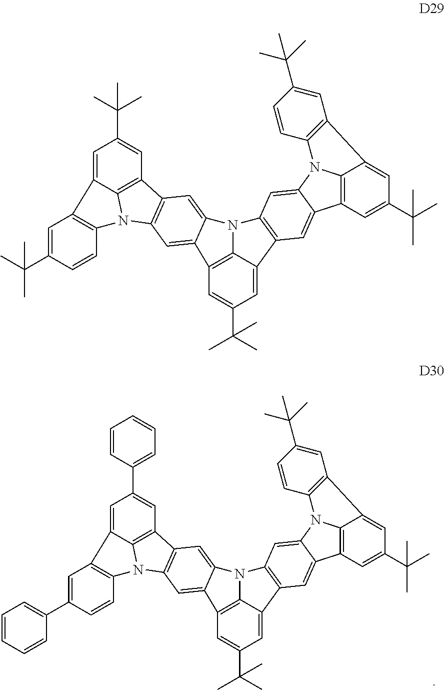 [SMILES: CC(C)(C)c1ccc2c(c1)c1cc(C(C)(C)C)cc3c4cc5c(cc4n2c13)c1cc(C(C)(C)C)cc2c3cc4c6cc(C(C)(C)C)cc7c8cc(C(C)(C)C)ccc8n(c4cc3n5c12)c76 ; CC(C)(C)c1ccc2c(c1)c1cc(C(C)(C)C)cc3c4cc5c6cc(C(C)(C)C)cc7c8cc9c(cc8n(c5cc4n2c13)c76)c1cc(-c2ccccc2)cc2c3cc(-c4ccccc4)ccc3n9c21]

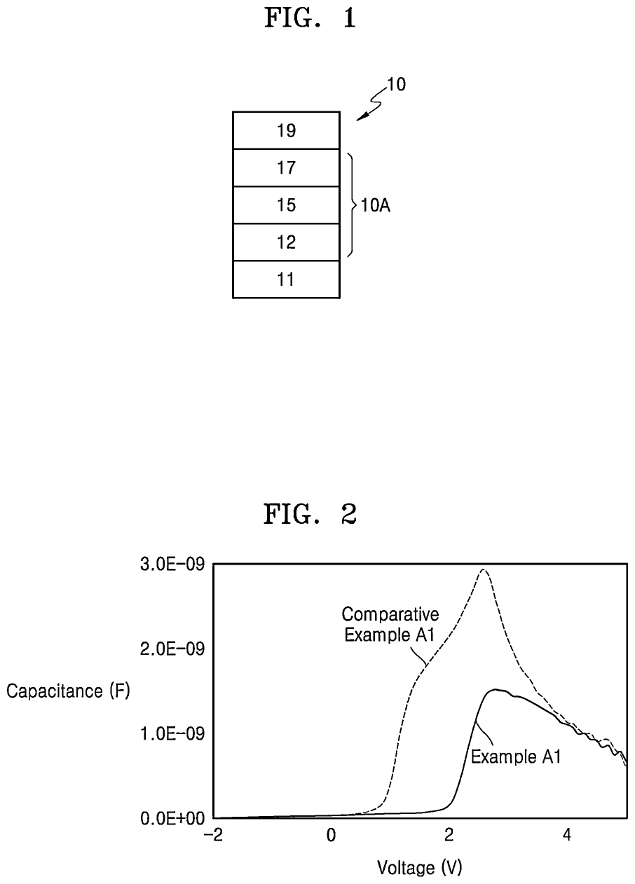

Description of FIG. 1

FIG. 1 is a cross-sectional view of an embodiment of an organic light-emitting device 10. Hereinafter, a structure and a manufacturing method of a light-emitting device according to an embodiment will be described in connection with FIG. 1.

The light-emitting device 10 of FIG. 1 may include a first electrode 11, a second electrode 19 facing the first electrode 11, and an interlayer 10A arranged between the first electrode 11 and the second electrode 19.

The interlayer 10A may include: an emission layer 15; a hole transport region 12 between the first electrode 11 and the emission layer 15; and an electron transport region 17 between the emission layer 15 and the second electrode 19.

A substrate may be further arranged under the first electrode 11 or on the second electrode 19. The substrate may be a substrate commonly used in organic light-emitting devices, e.g., a glass substrate or a transparent plastic substrate, which have excellent mechanical strength, thermal stability, transparency, surface smoothness, ease of handling, and water repellency.

### First Electrode 11

The first electrode 11 may be formed by depositing or sputtering a material for forming the first electrode 11 on the substrate. The first electrode 11 may be an anode. The material for forming the first electrode 11 may include materials with a high work function to facilitate hole injection.

The first electrode 11 may be a reflective electrode, a transreflective electrode, or a transmissive electrode. In an embodiment, when the first electrode 11 is a transmissive electrode, the material for forming the first electrode 11 may include indium tin oxide (ITO), indium zinc oxide (IZO), tin oxide (SnO₂), zinc oxide (ZnO), or any combination thereof.

When the first electrode 11 is a semi-transmissive electrode or a reflective electrode, the material for forming the first electrode 11 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 11 may have a single-layered structure or a multi-layered structure including two or more layers.

### Emission Layer 15

The thickness of the emission layer 15 may be about 100 Å to about 1,000 Å, for example, about 200 Å to about 600 Å. When the thickness of the emission layer 15 is within the range, excellent luminescence characteristics may be obtained without a substantial increase in driving voltage.

In an embodiment, the emission layer 15 may include the organometallic compound described above. In addition, the emission layer 15 may further include, in addition to the organometallic compound, at least one of the first compound (electron-transporting host), the second compound (hole-transporting host), and the third compound (thermally activated delayed fluorescence material).

### Hole Transport Region 12

The hole transport region 12 may be arranged between the first electrode 11 and the emission layer 15 of the light-emitting device 10.

The hole transport region 12 may further include a hole injection layer, a hole transport layer, a hole injection layer/hole transport layer structure, a hole injection layer/first hole transport layer/second hole transport layer structure, a hole injection layer/first hole transport layer/second hole transport layer/electron blocking layer structure, a hole transport layer/interlayer structure, a hole injection layer/hole transport layer/interlayer structure, a hole transport layer/electron blocking layer structure, or a hole injection layer/hole transport layer/electron blocking layer structure.

The hole transport region 12 may include any compound having hole-transporting properties. For example, the hole transport region 12 may include an amine-based compound.

In an embodiment, the hole transport region 12 may include m-MTDATA, TDATA, 2-TNATA, NPB, β-NPB, TPD, spiro-TPD, spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor-sulfonic acid (PANI/CSA), polyaniline/poly(4-styrene sulfonate) (PANI/PSS), a compound represented by any one of Formulae 201 to 205, or any combination thereof:

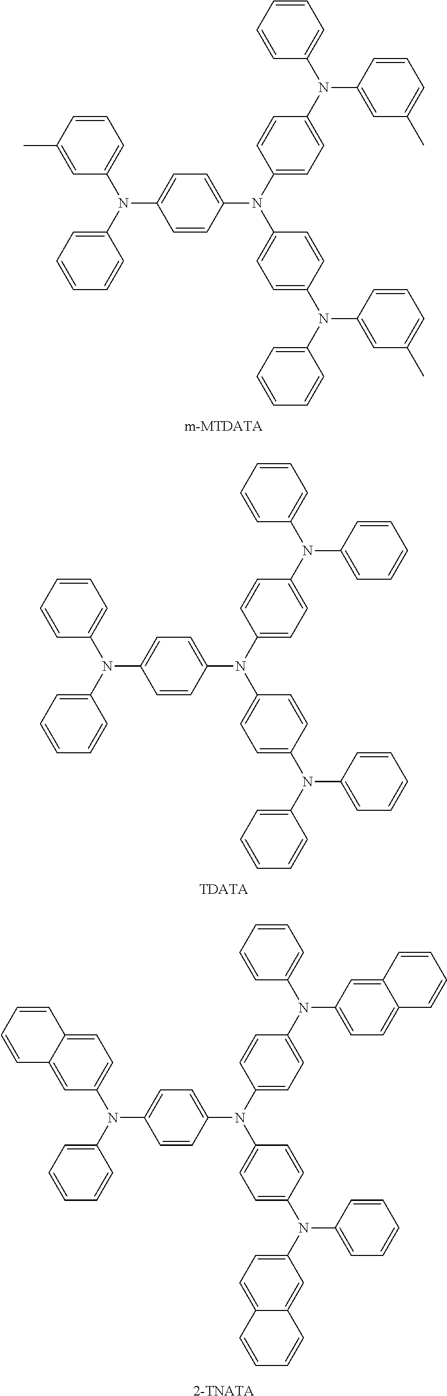

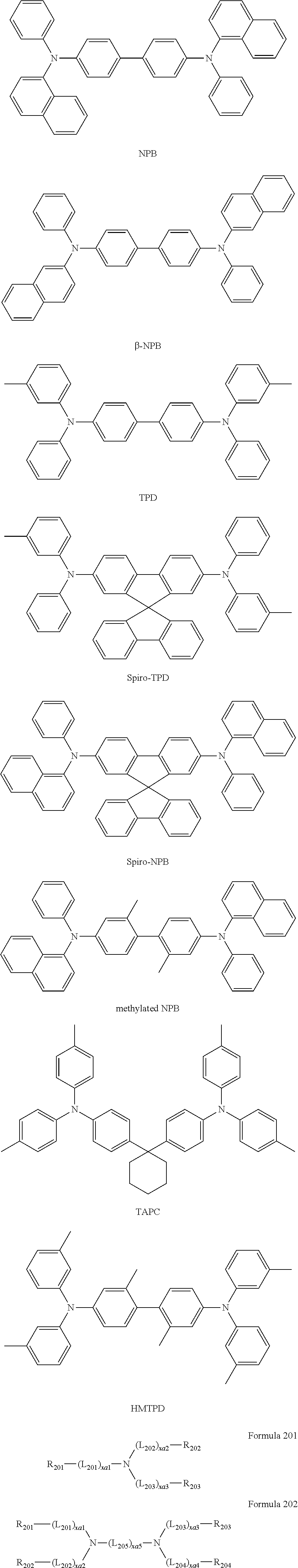

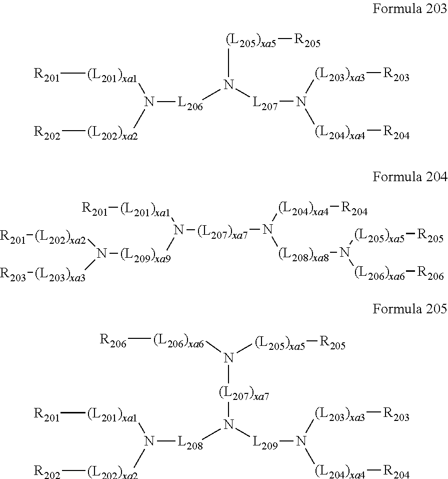

wherein, in Formulae 201 to 205,
L₂₀₁ to L₂₀₉ may each independently be *—O—*′, *—S—*′, a substituted or unsubstituted C₅-C₆₀ carbocyclic group, or a substituted or unsubstituted C₁-C₆₀ heterocyclic group,
xa1 to xa9 may each independently be an integer from 0 to 5, and
R₂₀₁ to R₂₀₆ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group, wherein neighboring two groups of R₂₀₁ to R₂₀₆ may optionally be linked to each other via a single bond, a dimethyl-methylene group, or a diphenyl-methylene group.

In an embodiment, L₂₀₁ to L₂₀₉ may be a benzene group, a heptalene group, an indene group, a naphthalene group, an azulene group, a heptalene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentacene group, a rubicene group, a corogen group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, or a triindolobenzene group, each unsubstituted or substituted with deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, —Si(Q₁₁)(Q₁₂)(Q₁₃), or any combination thereof,
xa1 to xa9 may each independently be 0, 1, or 2, and
R₂₀₁ to R₂₀₆ may each independently be a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an indeno carbazolyl group, an indolocarbazolyl group, a benzofurocarbazolyl group, or a benzothienocarbazolyl group, each unsubstituted or substituted with deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), —N(Q₃₁)(Q₃₂), or any combination thereof.

Q₁₁ to Q₁₃ and Q₃₁ to Q₃₃ may each independently be a C₁-C₁₀ alkyl group, a C₁-C₁ alkoxy group, a phenyl group, a biphenyl group, a terphenyl group, or a naphthyl group.

In an embodiment, the hole transport region 12 may include a carbazole-containing amine-based compound. The hole transport region 12 may include a carbazole-containing amine-based compound and a carbazole-free amine-based compound.

For example, the carbazole-containing amine-based compound may include compounds represented by Formula 201 i) including a carbazole group and ii) further including at least one of a dibenzofuran group, a dibenzothiophene group, a fluorene group, a spiro-bifluorene group, an indenocarbazole group, an indolocarbazole group, a benzofurocarbazole group, and a benzothienocarbazole group.

For example, the carbazole-free amine-based compound may include compounds represented by Formula 201 i) not including a carbazole group and ii) including at least one of a dibenzofuran group, a dibenzothiophene group, a fluorene group, a spiro-bifluorene group, an indenocarbazole group, an indolocarbazole group, a benzofurocarbazole group, and a benzothienocarbazole group.

In one or more embodiments, the hole transport region 12 may include a compound represented by Formula 201, a compound represented by Formula 202, or any combination thereof.

In an embodiment, the hole transport region 12 may include a compound represented by Formula 201-1, 202-1, or 201-2, or any combination thereof:

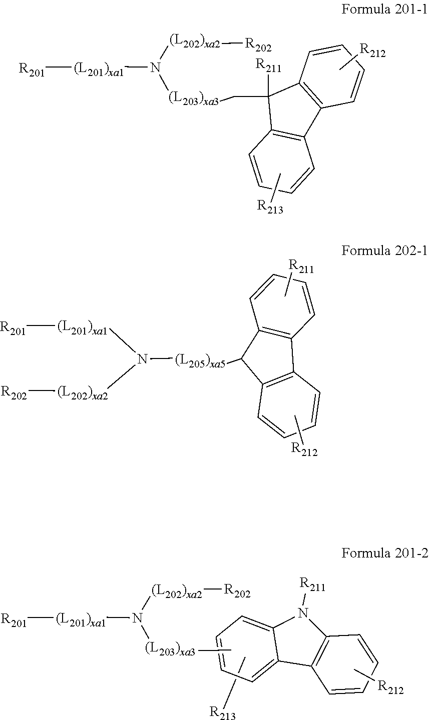

wherein, in Formulae 201-1, 202-1, and 201-2, L₂₀₁ to L₂₀₃, L₂₀₅, xa1 to xa3, xa5, R₂₀₁ and R₂₀₂ are each the same as described herein, and R₂₁₁ to R₂₁₃ may each independently be hydrogen, deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a dimethylfluorenyl group, a diphenylfluorenyl group, a triphenylenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, or a pyridinyl group.

For example, the hole transport region 12 may include one of Compounds HT1 to HT39 or any combination thereof:

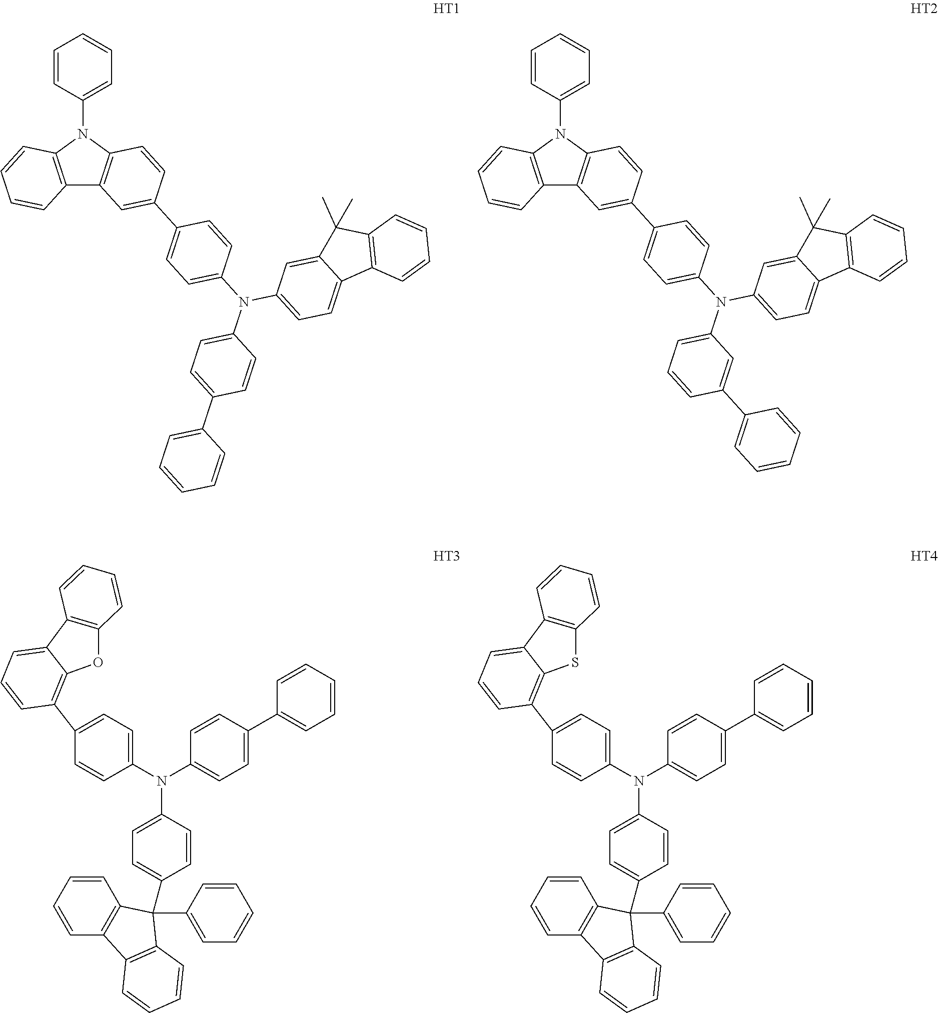 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; c1ccc(-c2ccc(N(c3ccc(-c4cccc5c4oc4ccccc45)cc3)c3ccc(C4(c5ccccc5)c5ccccc5-c5ccccc54)cc3)cc2)cc1 ; c1ccc(-c2ccc(N(c3ccc(-c4cccc5c4sc4ccccc45)cc3)c3ccc(C4(c5ccccc5)c5ccccc5-c5ccccc54)cc3)cc2)cc1]

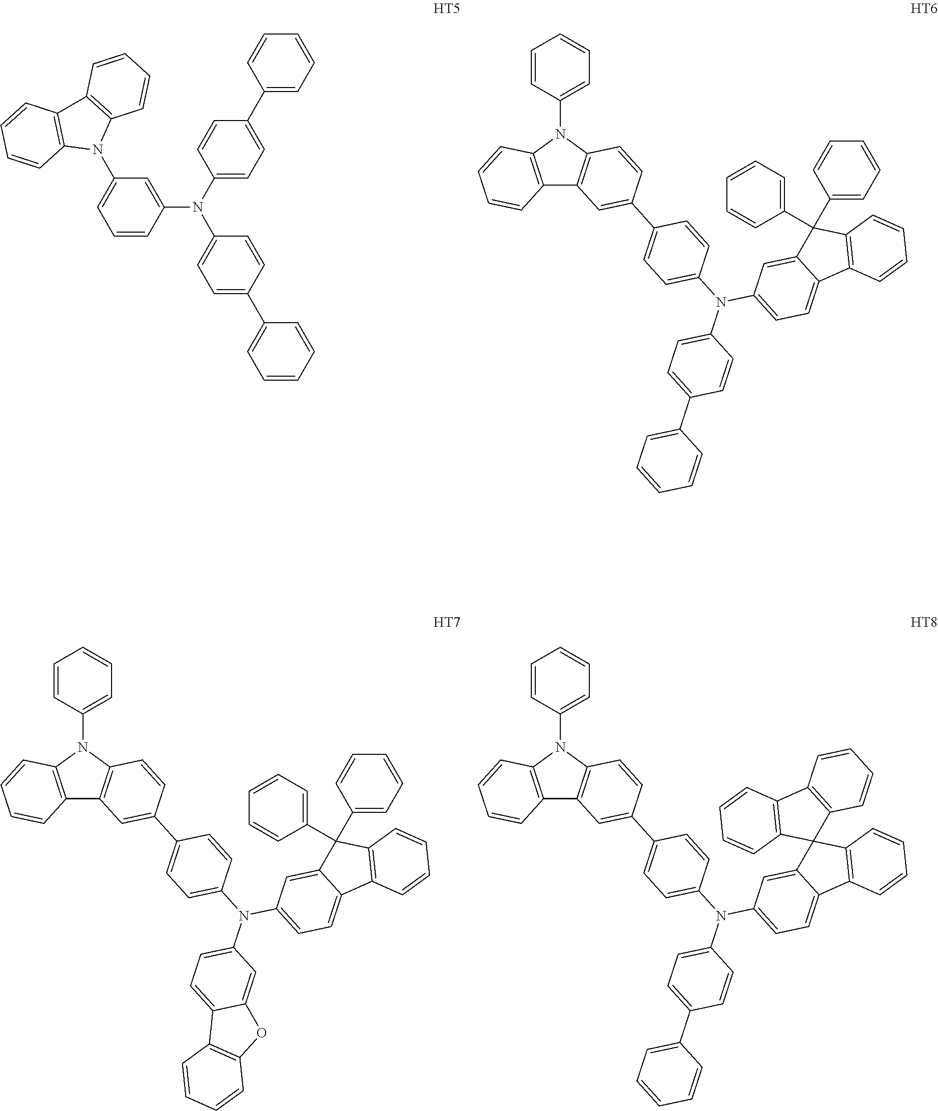 [SMILES: c1ccc(-c2ccc(N(c3ccc(-c4ccccc4)cc3)c3cccc(-n4c5ccccc5c5ccccc54)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

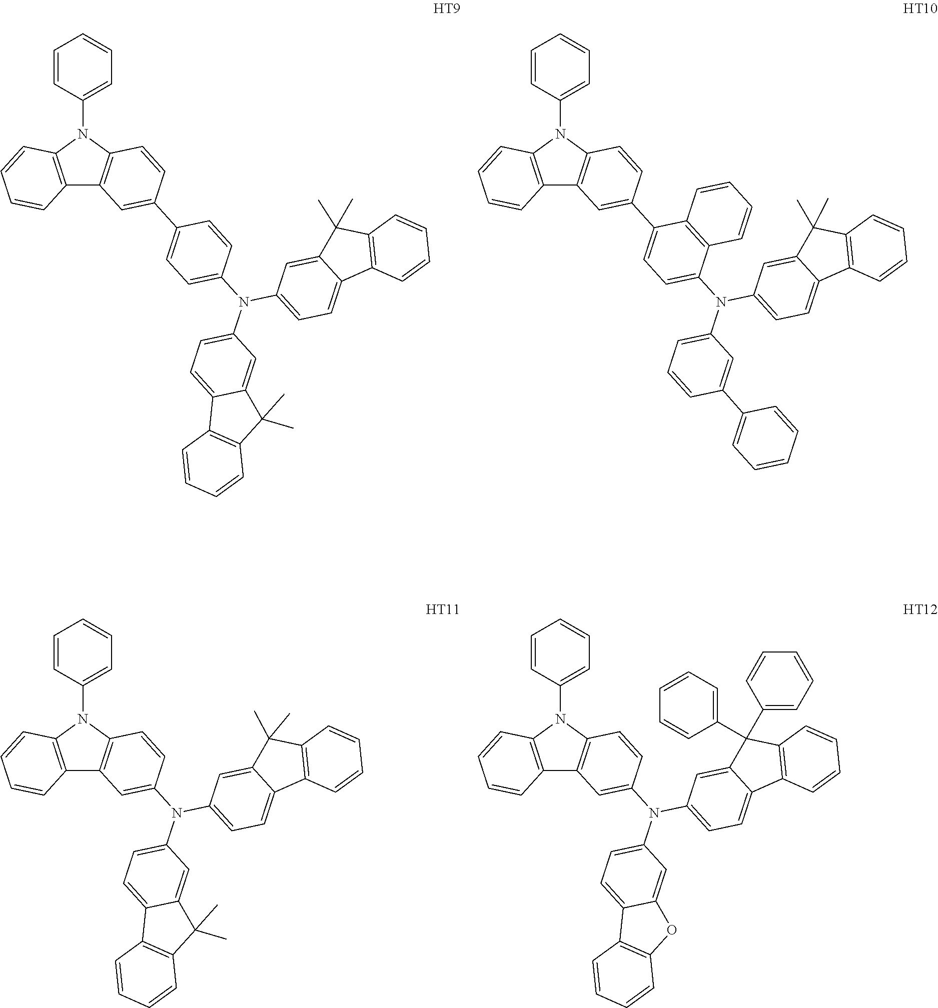 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

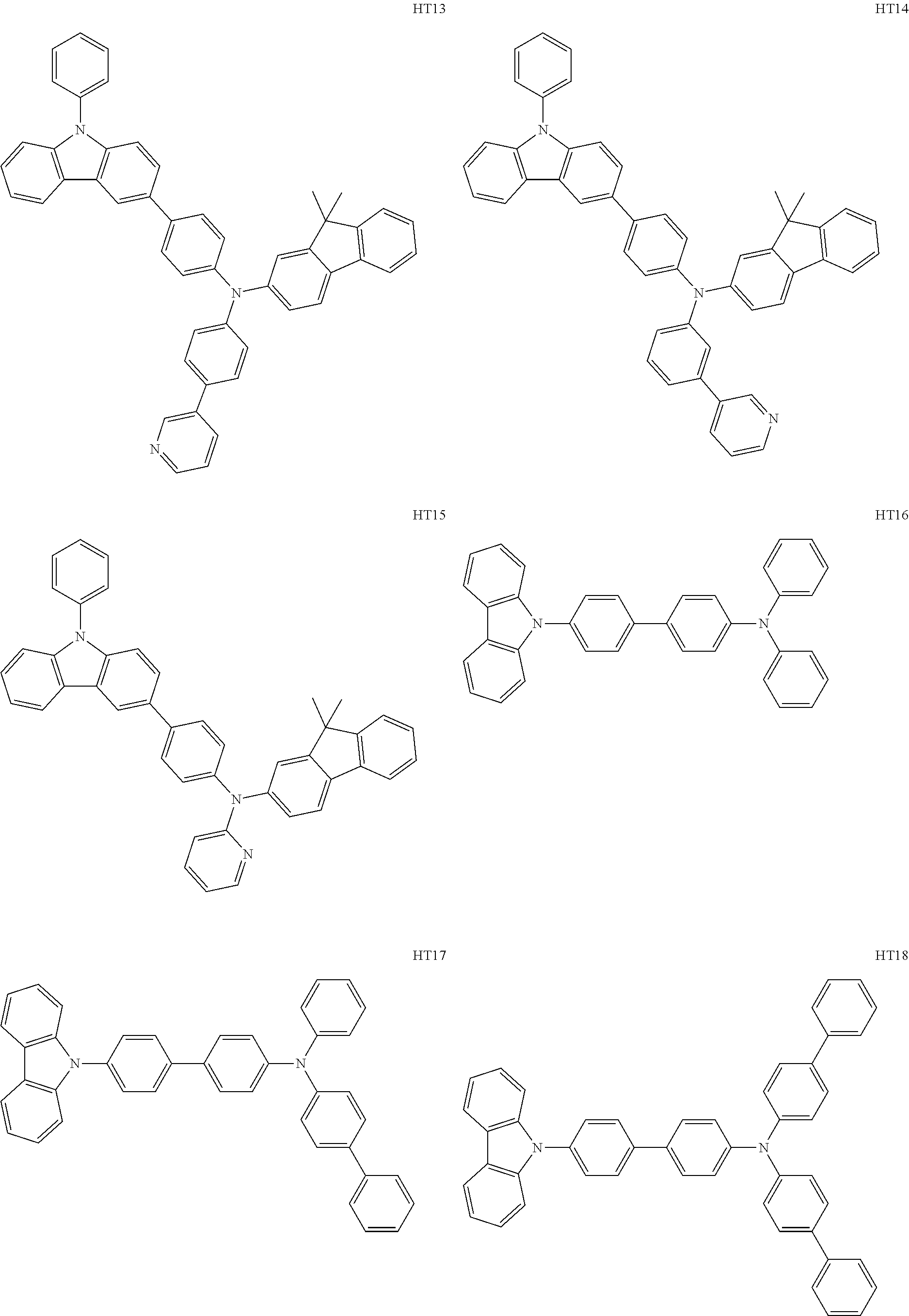 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

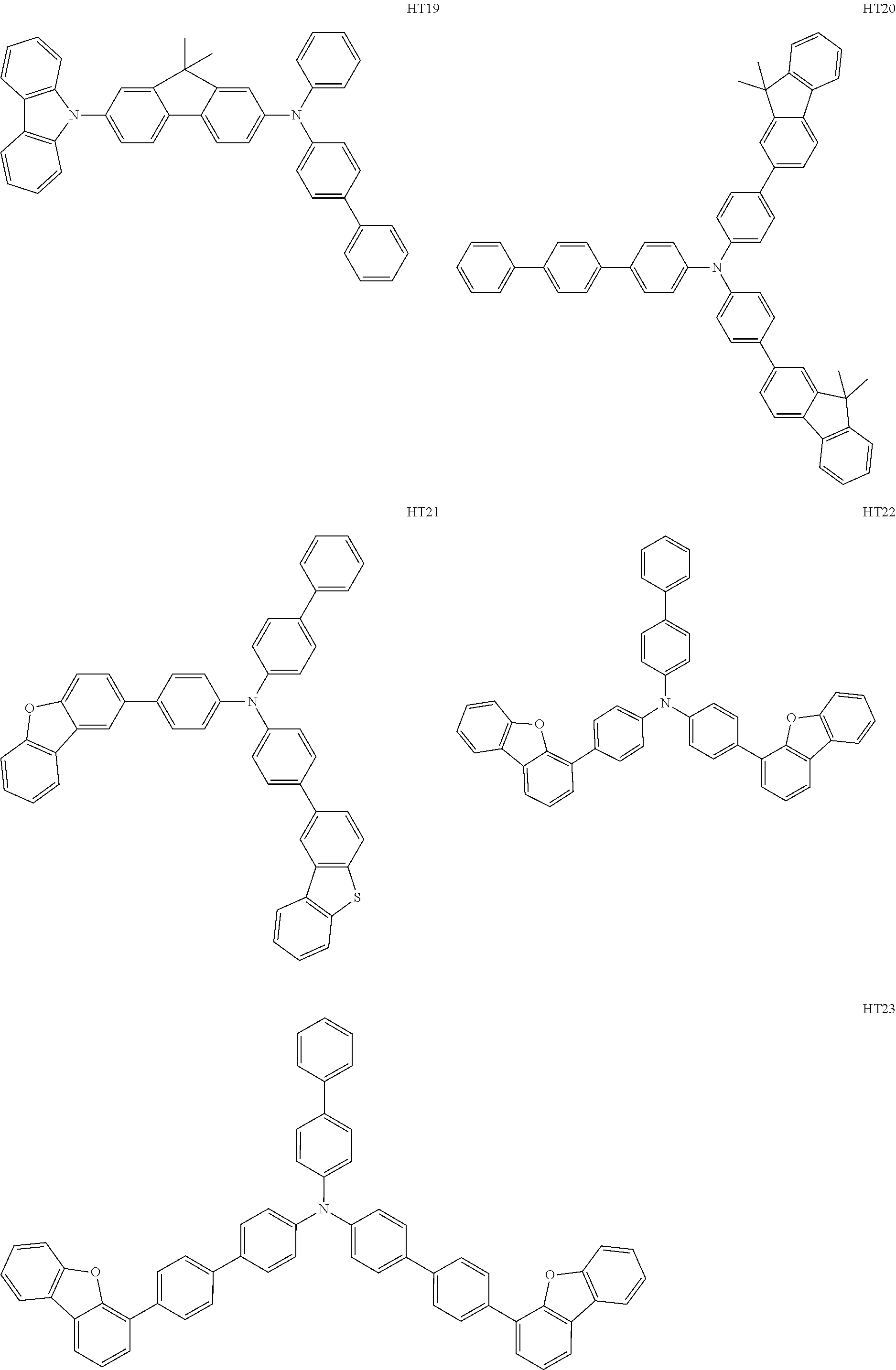 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

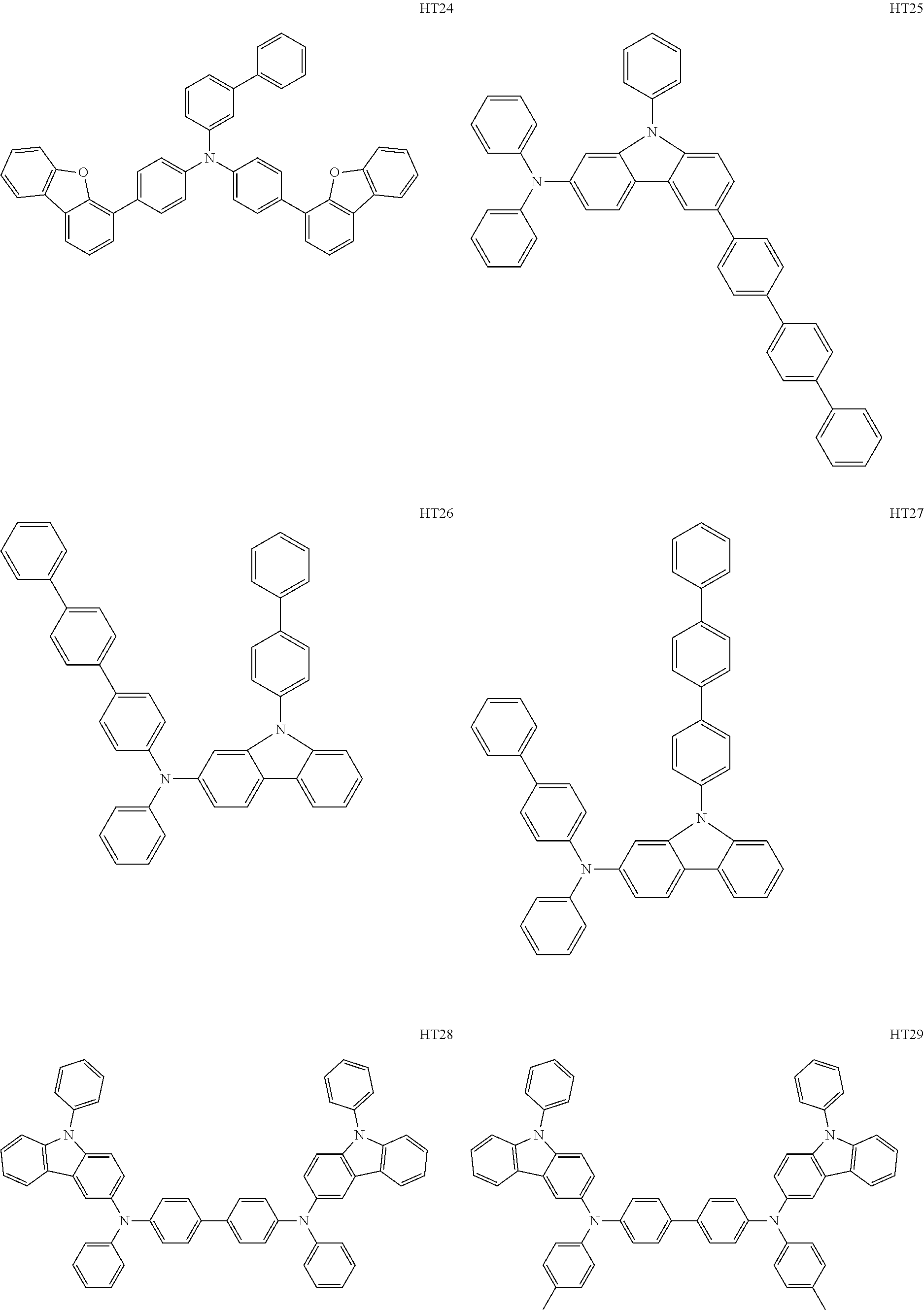

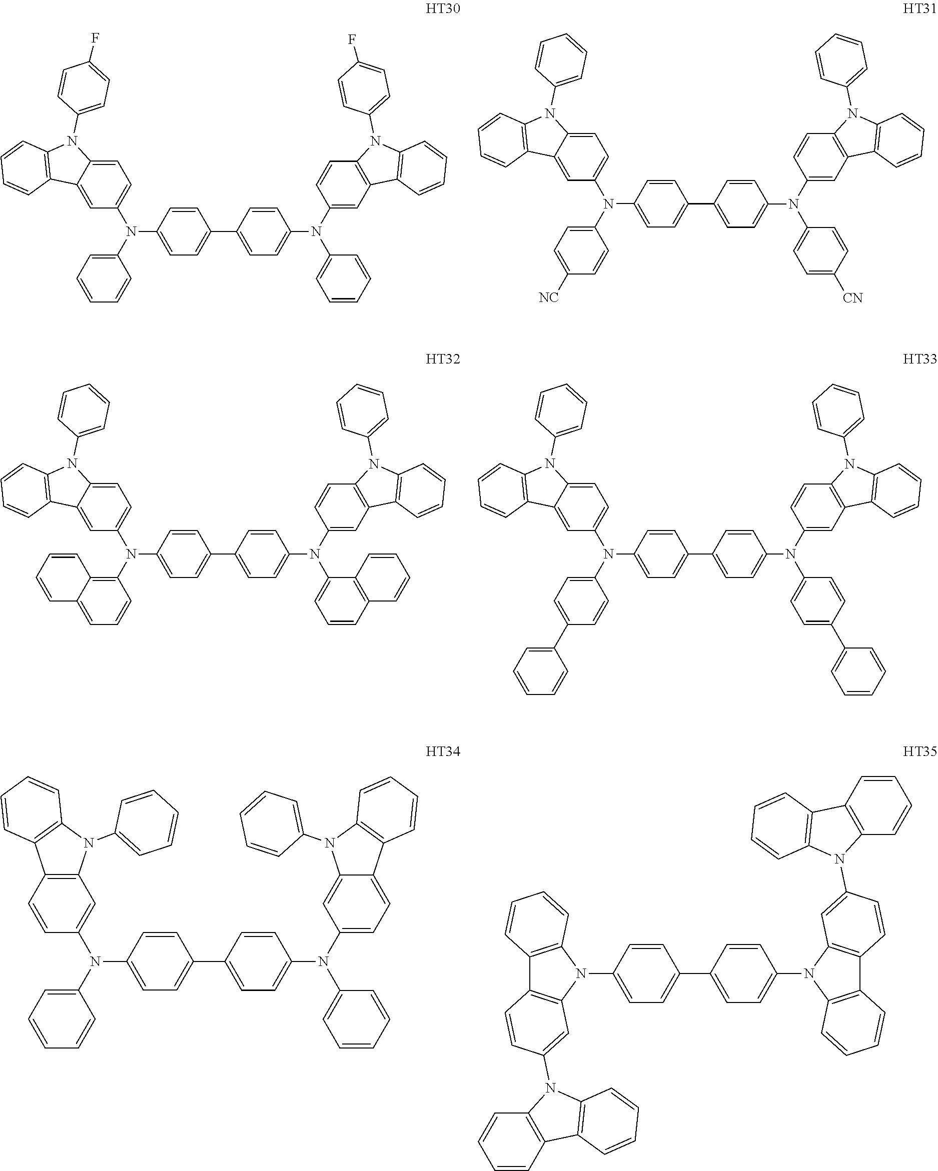

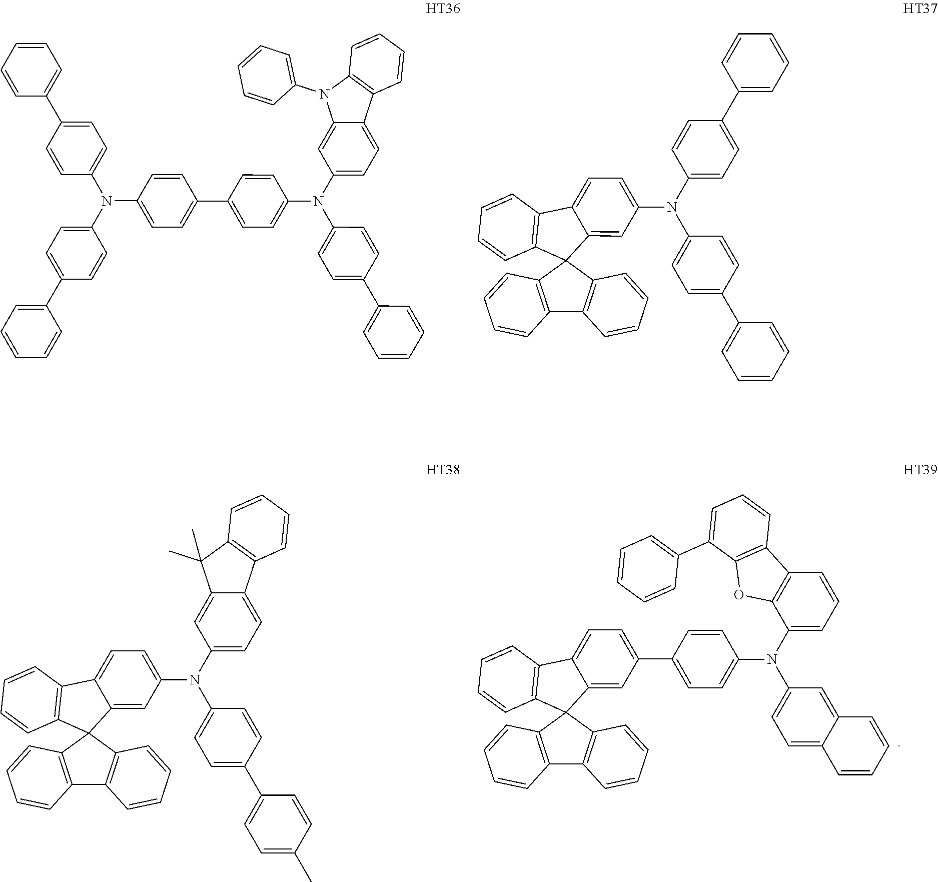 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

The hole transport region 12 of the light-emitting device 10 may further include a p-dopant. When the hole transport region 12 further includes a p-dopant, the hole transport region 12 may have a matrix (for example, at least one of compounds represented by Formulae 201 to 205) and a structure including a p-dopant included in the matrix. The p-dopant may be uniformly or non-uniformly doped in the hole transport region 12.

In an embodiment, the lowest unoccupied molecular orbital (LUMO) energy level of the p-dopant may be less than or equal to −3.5 eV.

The p-dopant may include a quinone derivative, a metal oxide, a cyano group-containing compound, or any combination thereof.

For example, the p-dopant may include:
a quinone derivative, such as tetracyanoquinodimethane (TCNQ),2,3,5,6-tetrafluoro-7,7,8,8-tetracyanoquinodimethane (F4-TCNQ), and F6-TCNNQ;
a metal oxide, such as tungsten oxide or molybdenum oxide;
1,4,5,8,9,12-hexaazatriphenylene-hexacarbonitrile (HAT-CN);
a compound represented by Formula 221; or
any combination thereof:

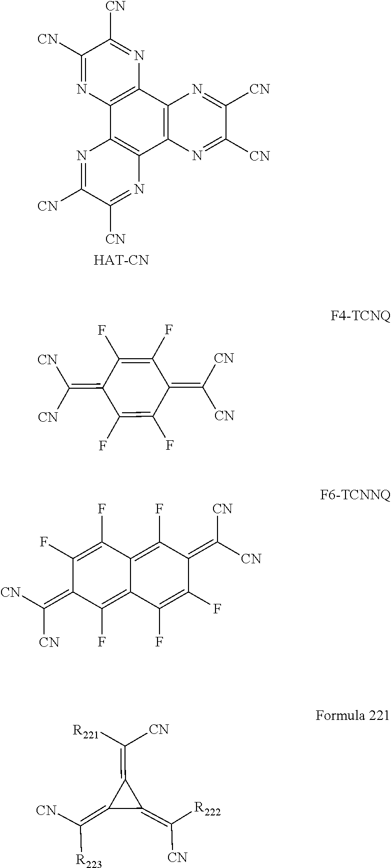

wherein, in Formula 221,
R₂₂₁ to R₂₂₃ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group, wherein at least one substituent of R₂₂₁ to R₂₂₃ may be: a cyano group; —F; —Cl; —Br; —I; a C₁-C₂₀ alkyl group substituted with —F; a C₁-C₂₀ alkyl group substituted with —Cl; a C₁-C₂₀ alkyl group substituted with —Br; a C₁-C₂₀ alkyl group substituted with —I; or any combination thereof.

The compound represented by Formula 221 may include, for example, Compound HT-D2:

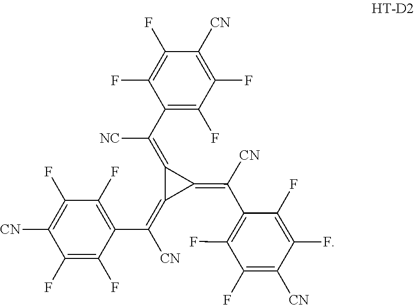

The hole transport region 12 may have a thickness in a range about 100 Å to about 10,000 Å, for example, about 400 Å to about 2,000 Å, and the emission layer 15 may have a thickness in a range of about 100 Å to about 3,000 Å, for example, about 300 Å to about 1,000 Å. When the thickness of each of the hole transport region 12 and the emission layer 15 is within these ranges, satisfactory hole transportation characteristics and/or luminescence characteristics may be obtained without a substantial increase in driving voltage.

The hole transport region 12 may further include a buffer layer.

The buffer layer may compensate for an optical resonance distance according to a wavelength of light emitted from the emission layer 15, and thus, efficiency of a formed organic light-emitting device may be improved.

The hole transport region 12 may further include an electron blocking layer. The electron blocking layer may include a known material, for example, mCP or DBFPO:

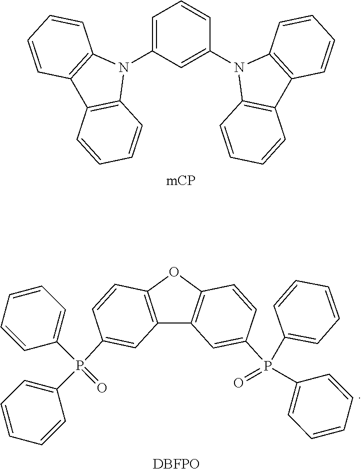

### Electron Transport Region 17

The electron transport region 17 may be arranged between the emission layer 15 and the second electrode 19 of the light-emitting device 10.

The electron transport region 17 may have a single-layer structure or a multi-layer structure.

For example, the electron transport region 17 may have an electron transport layer, an electron transport layer/electron injection layer structure, a buffer layer/electron transport layer structure, hole blocking layer/electron transport layer structure, a buffer layer/electron transport layer/electron injection layer structure, or a hole blocking layer/electron transport layer/electron injection layer structure. The electron transport region 17 may further include an electron control layer.

The electron transport region 17 may include known electron-transporting materials.

The electron transport region 17 (for example, a buffer layer, a hole blocking layer, an electron control layer, or an electron transport layer in the electron transport region) may include a metal-free compound containing at least one π electron-deficient nitrogen-containing C₁-C₆₀ cyclic group. The π electron-deficient nitrogen-containing C₁-C₆₀ cyclic group is the same as described herein.

For example, the electron transport region 17 may include a compound represented by Formula 601:

[Ar₆₀₁]ₓₑ₁₁-[(L₆₀₁)ₓₑ₁-R₆₀₁]ₓₑ₂₁ Formula 601
wherein, in Formula 601,
Ar₆₀₁ and L₆₀₁ may each independently be a C₅-C₆₀ carbocyclic group unsubstituted or substituted with at least one R₆₀₁ₐ or a C₁-C₆₀ heterocyclic group unsubstituted or substituted with at least one R₆₀₁ₐ,
xe11 may be 1, 2, or 3,
xe1 may be an integer from 0 to 5,
R₆₀₁ₐ and R₆₀₁ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂), Q₆₀₁ to Q₆₀₃ may each independently be a C₁-C₁₀ alkyl group, a C₁-C₁₀ alkoxy group, a phenyl group, a biphenyl group, a terphenyl group, or a naphthyl group, and
xe21 may be an integer from 1 to 5.

In an embodiment, at least one of Ar₆₀₁ in the number of xe11 and R₆₀₁ in the number of xe21 may include the π electron-deficient nitrogen-containing C₁-C₆₀ cyclic group.

In an embodiment, Ar₆₀₁ and L₆₀₁ in Formula 601 may each independently be a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, or an azacarbazole group, each unsubstituted or substituted with deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, —Si(Q₃₁)(Q₃₂)(Q₃₃), —S(═O)₂(Q₃₁), —P(═O)(Q₃₁)(Q₃₂), or any combination thereof, and Q₃₁ to Q₃₃ may each independently be a C₁-C₁₀ alkyl group, a C₁-C₁₀ alkoxy group, a phenyl group, a biphenyl group, a terphenyl group, or a naphthyl group.

When xe11 in Formula 601 is 2 or more, two or more of Ar₆₀₁ may be linked to each other via a single bond.

In one or more embodiments, Ar₆₀₁ in Formula 601 may be an anthracene group.

In one or more embodiments, the compound represented by Formula 601 may be represented by Formula 601-1:

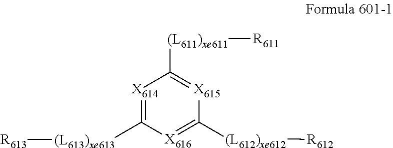

wherein, in Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ are each independently the same as described in connection with L₆₀₁,
xe611 to xe613 are each independently the same as described in connection with xe1,
R₆₁₁ to R₆₁₃ are each independently the same as described in connection with R₆₀₁, and
R₆₁₄ to R₆₁₆ may each independently be hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, or a naphthyl group.

In one or more embodiments, xe1 and xe611 to xe613 in Formulae 601 and 601-1 may each independently be 0, 1, or 2.

In one or more embodiments, R₆₀₁ and R₆₁₁ to R₆₁₃ in Formulae 601 and 601-1 may each independently be: a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, or an azacarbazolyl group, each unsubstituted or substituted with deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, an azacarbazolyl group, or any combination thereof; or
—S(═O)₂(Q₆₀₁) or —P(═O)(Q₆₀₁)(Q₆₀₂), and
Q₆₀₁ and Q₆₀₂ are each the same as described herein.

The electron transport region 17 may include one of Compounds ET1 to ET36 or any combination thereof:

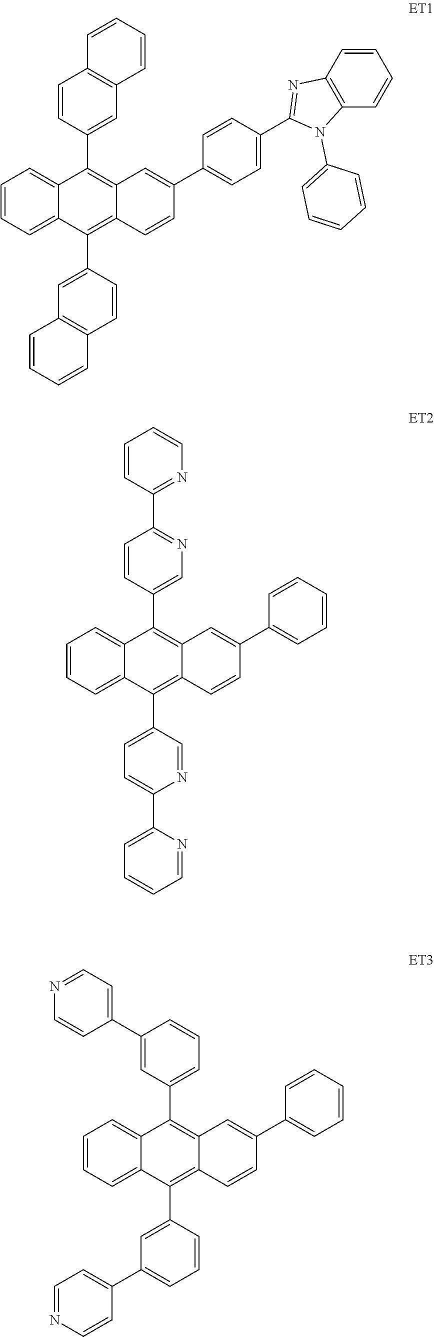

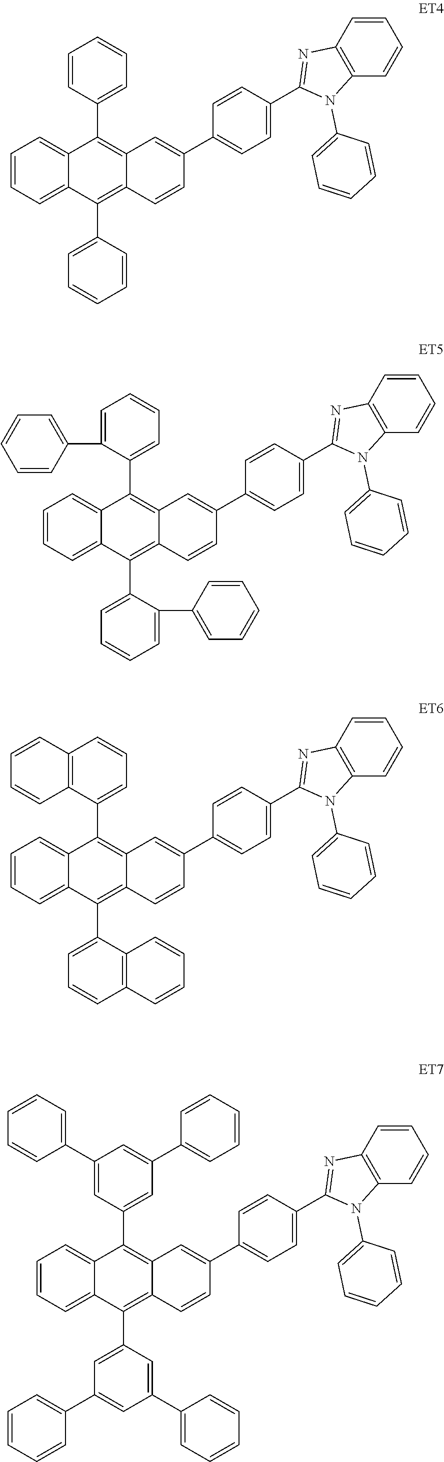 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

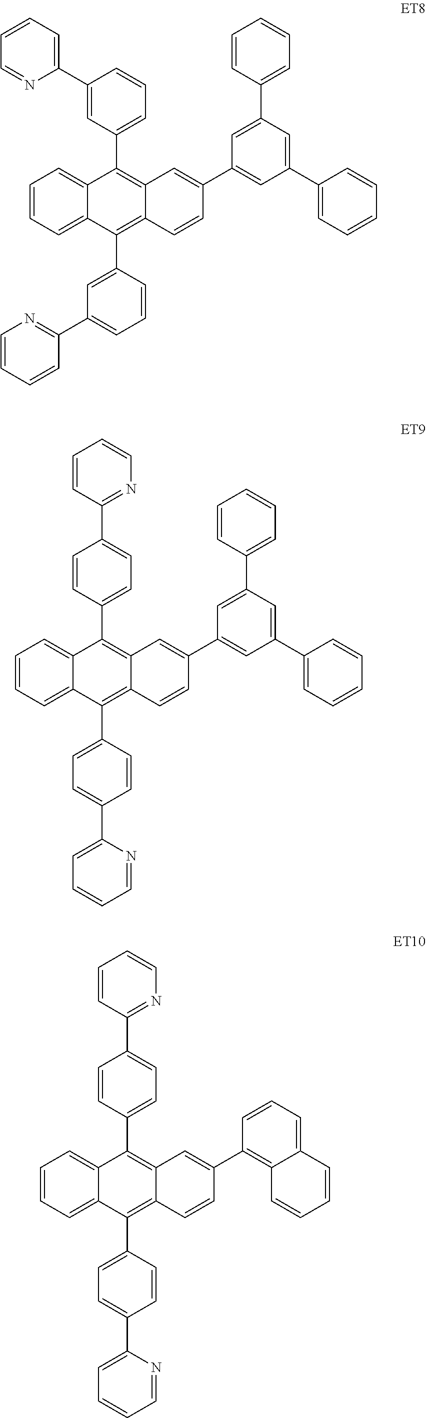 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

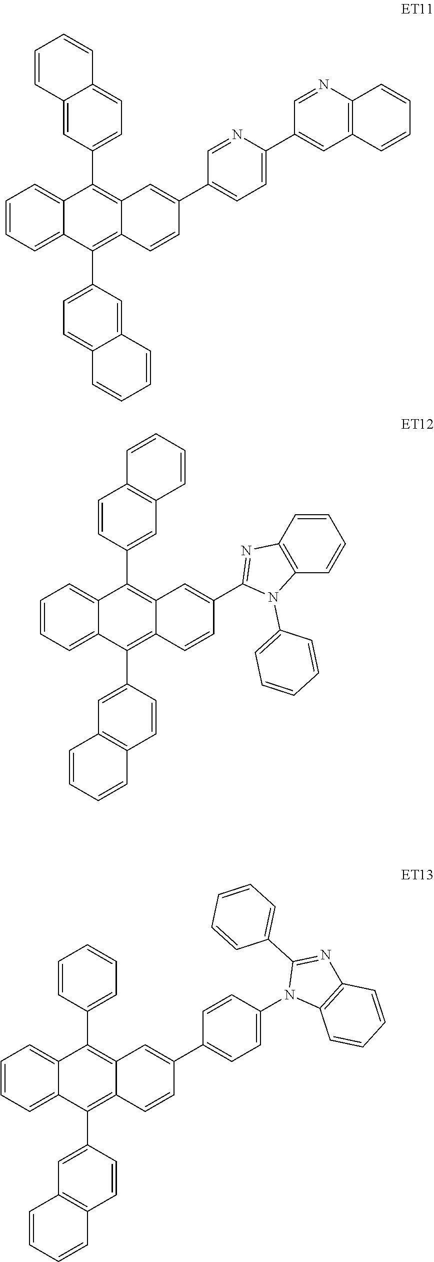 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

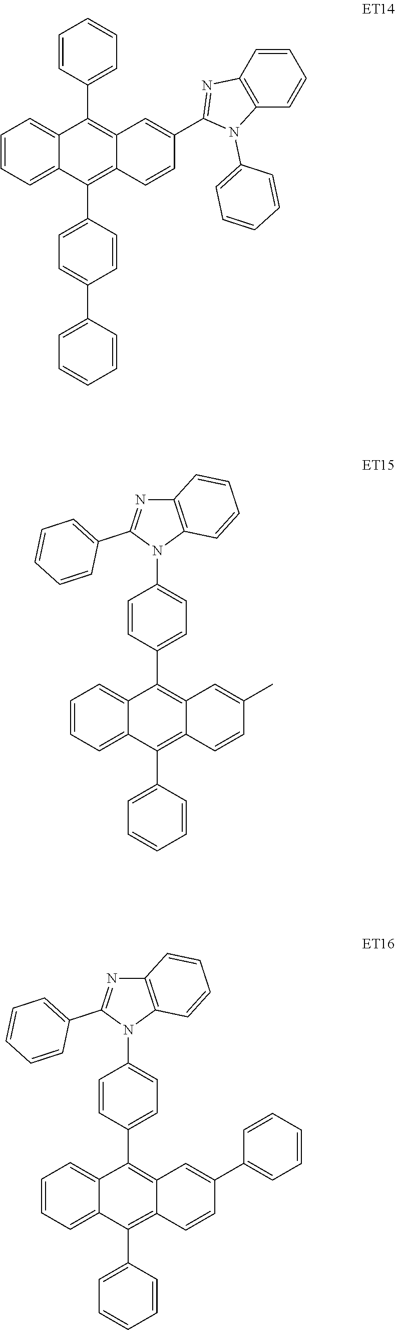 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

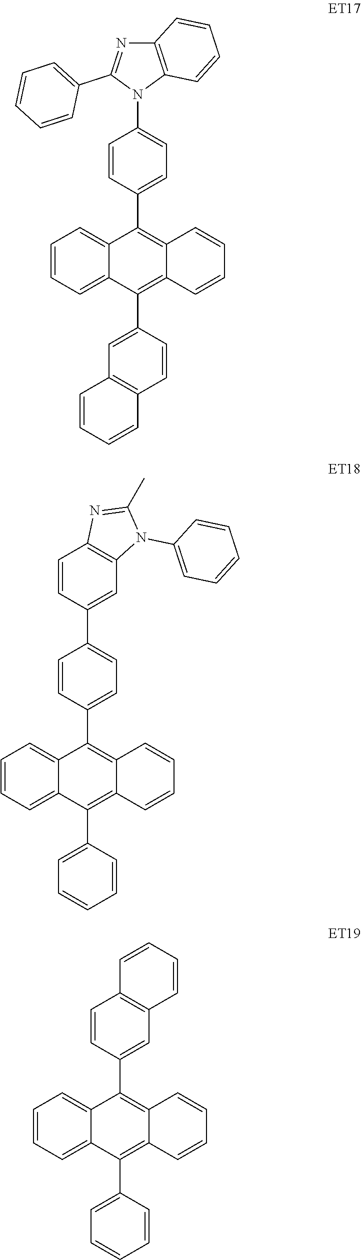

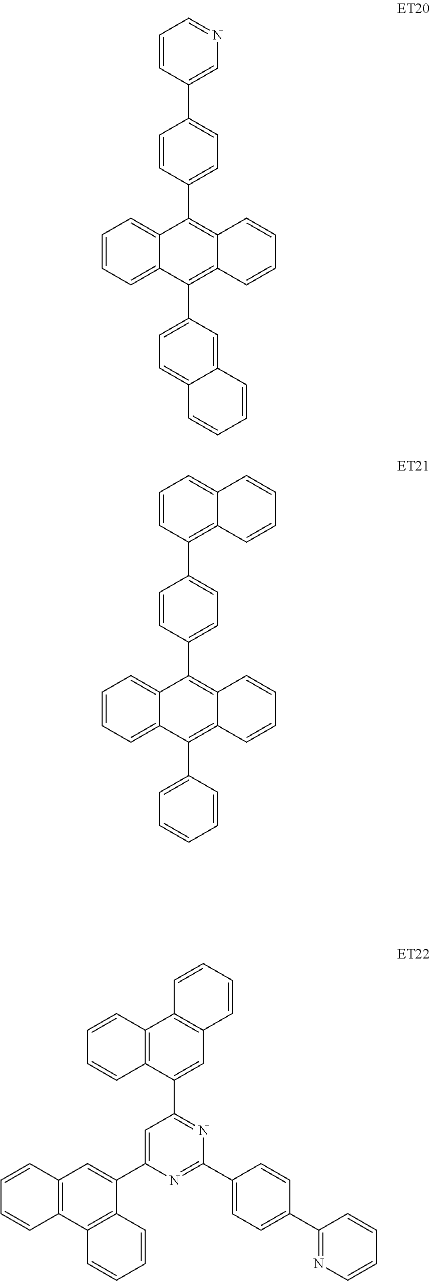

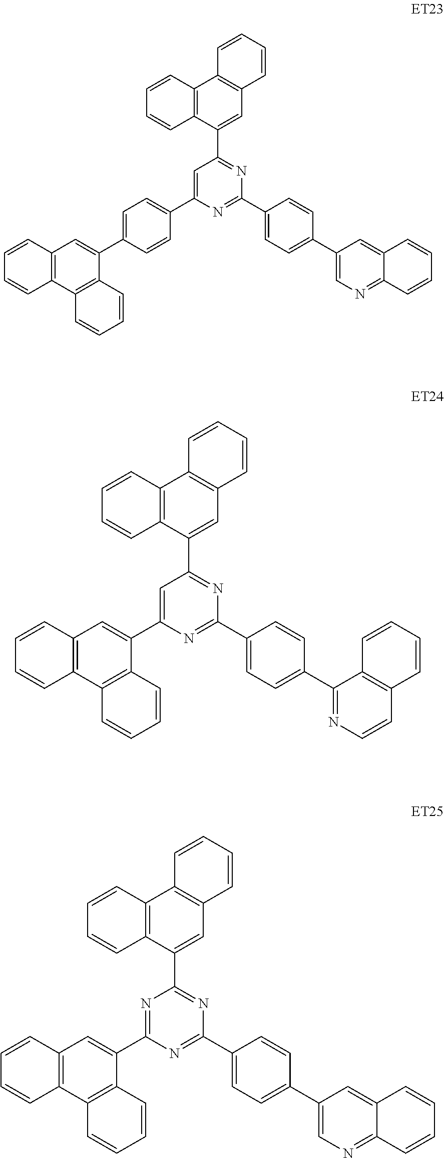 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

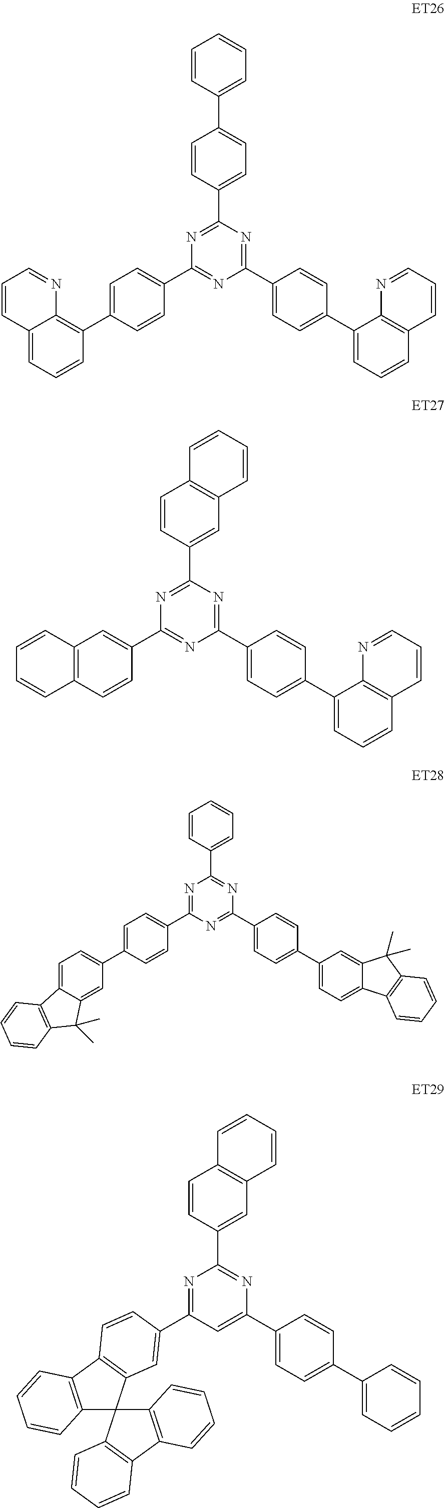 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

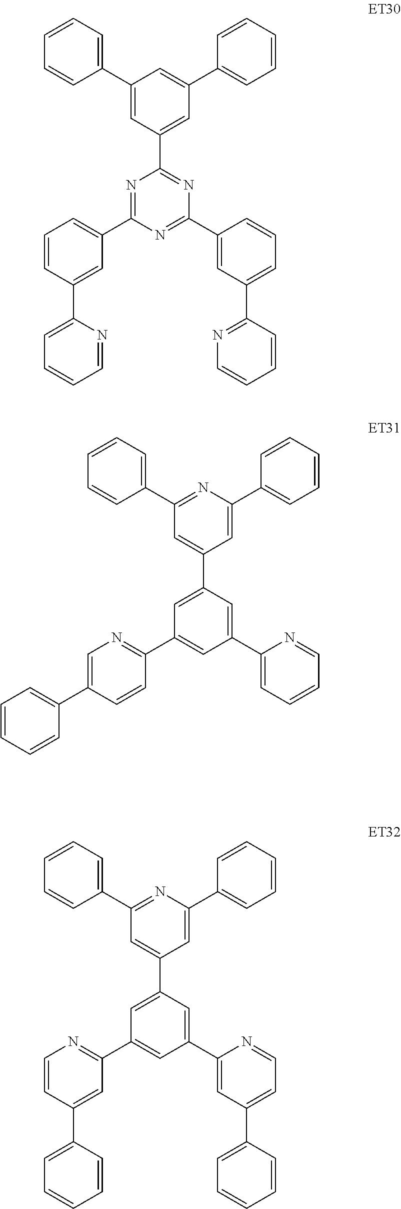 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

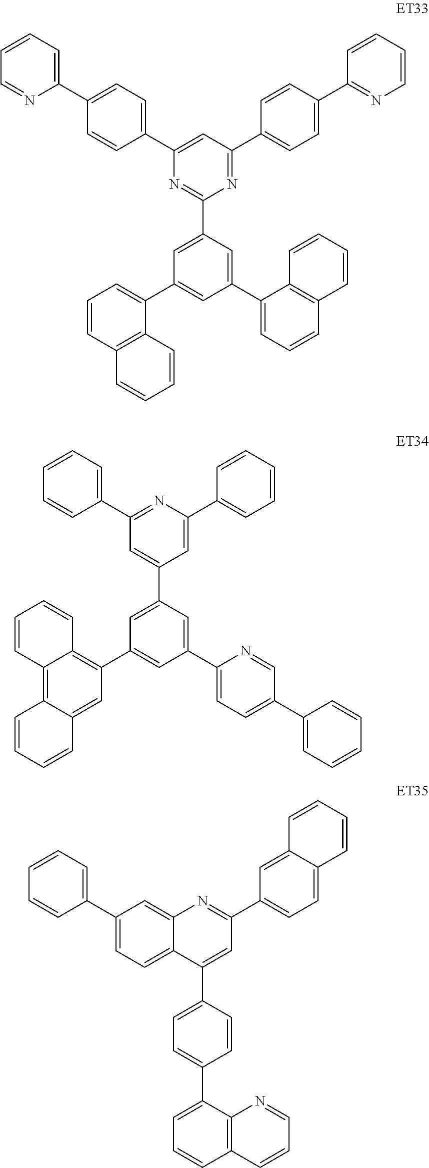

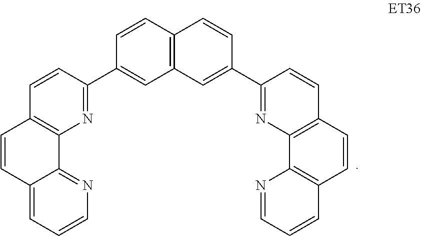 [SMILES: c1cnc2c(c1)ccc1ccc(-c3ccc4ccc(-c5ccc6ccc7cccnc7c6n5)cc4c3)nc12]

In one or more embodiments, the electron transport region 17 may include 2,9-dimethyl-4,7-diphenyl-1,10-phenanthroline (BCP), 4,7-diphenyl-1,10-phenanthroline (Bphen), Alq₃, BAlq, 3-(biphenyl-4-yl)-5-(4-tert-butylphenyl)-4-phenyl-4H-1,2,4-triazole (TAZ), NTAZ, DBFPO, or any combination thereof. For example, when the electron transport region 17 includes a hole blocking layer, the hole blocking layer may include BCP or Bphen:

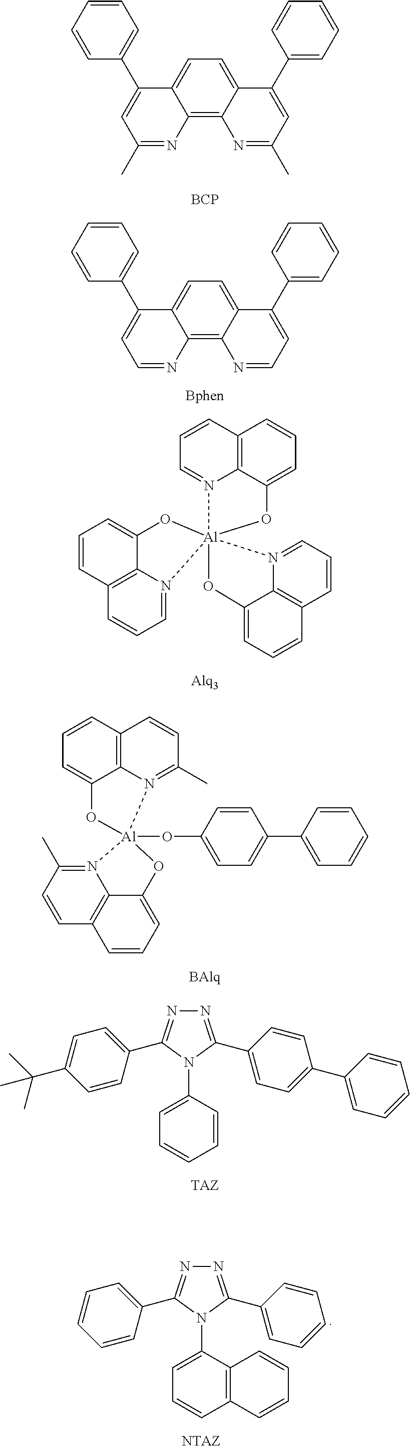

Thicknesses of the buffer layer, the hole blocking layer, and the electron control layer may each independently be about 20 Å to about 1,000 Å, for example, about 30 Å to about 300 Å. When the thicknesses of the buffer layer, the hole blocking layer, and the electron control layer are within these ranges, excellent hole blocking characteristics or excellent electron control characteristics may be obtained without a substantial increase in driving voltage.

The thickness of the electron transport layer may be about 100 Å to about 1,000 Å, for example, about 150 Å to about 500 Å. When the thickness of the electron transport layer is within these ranges, satisfactory electron-transporting characteristics may be obtained without a substantial increase in driving voltage.

The electron transport region 17 (for example, the electron transport layer in the electron transport region 17) may further include, in addition to the aforementioned materials, a metal-containing material.

The metal-containing material may include an alkali metal complex, an alkaline earth metal complex, or any combination thereof. A metal ion of the alkali metal complex may include a Li ion, a Na ion, a K ion, a Rb ion, a Cs ion, or any combination thereof, and a metal ion of the alkaline earth metal complex may include a Be ion, a Mg ion, a Ca ion, a Sr ion, a Ba ion, or any combination thereof. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxydiphenyloxadiazole, a hydroxydiphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or ET-D2:

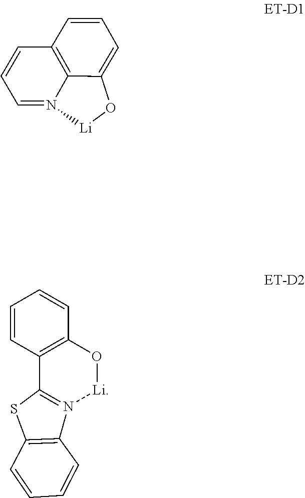

The electron transport region 17 may include an electron injection layer that facilitates the injection of electrons from the second electrode 19. The electron injection layer may directly contact the second electrode 19.

The electron injection layer may have i) a single-layer structure consisting of a single layer including a single material, ii) a single-layer structure consisting of a single layer including multiple materials that are different from each other, or iii) a multi-layer structure consisting of multiple layers including multiple materials that are different from each other.

The electron injection layer may include an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combinations thereof.

The alkali metal may include Li, Na, K, Rb, Cs, or any combination thereof. In an embodiment, the alkali metal may be Li, Na, or Cs. In one or more embodiments, the alkali metal may be Li or Cs.

The alkaline earth metal may include Mg, Ca, Sr, Ba, or any combination thereof.

The rare earth metal may include Sc, Y, Ce, Tb, Yb, Gd, or any combination thereof.

The alkali metal compound, the alkaline earth metal compound, and the rare earth metal compound may include oxides and halides (for example, fluorides, chlorides, bromides, or iodides) of the alkali metal, the alkaline earth metal, and the rare earth metal, or any combination thereof.

The alkali metal compound may include: one of alkali metal oxides such as Li₂O, Cs₂O, K₂O, and the like; one of alkali metal halides such as LiF, NaF, CsF, KF, LiI, NaI, CsI, KI, and the like; or any combination thereof. In an embodiment, the alkali metal compound may include LiF, Li₂O, NaF, LiI, NaI, CsI, KI, or any combination thereof.

The alkaline earth-metal compound may include one of alkaline earth-metal compounds, such as BaO, SrO, CaO, BaₓSr₁₋ₓO (wherein 0<x<1), or BaₓCa₁₋ₓO (wherein 0<x<1), or any combination thereof. In an embodiment, the alkaline earth metal compound may include BaO, SrO, CaO, or any combination thereof.

The rare earth metal compound may include YbF₃, ScF₃, ScO₃, Y₂O₃, Ce₂O₃, GdF₃, TbF₃, or any combination thereof. In an embodiment, the rare earth metal compound may include YbF₃, ScF₃, TbF₃, YbI₃, ScI₃, TbI₃, or any combination thereof.

The alkali metal complex, the alkaline earth metal complex, and the rare earth metal complex may include an ion of alkali metal, alkaline earth metal, and rare earth metal as described above, and a ligand coordinated with a metal ion of the alkali metal complex, the alkaline earth metal complex, or the rare earth metal complex may include hydroxy quinoline, hydroxy isoquinoline, hydroxy benzoquinoline, hydroxy acridine, hydroxy phenanthridine, hydroxy phenyloxazole, hydroxy phenylthiazole, hydroxy diphenyloxadiazole, hydroxy diphenylthiadiazole, hydroxy phenylpyridine, hydroxy phenylbenzimidazole, hydroxy phenylbenzothiazole, bipyridine, phenanthroline, cyclopentadiene, or any combination thereof.

The electron injection layer may consist of an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combinations thereof, as described above. In one or more embodiments, the electron injection layer may further include an organic material. When the electron injection layer further includes an organic material, an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combination thereof may be homogeneously or non-homogeneously dispersed in a matrix including the organic material.

The thickness of the electron injection layer may be about 1 Å to about 100 Å, and, for example, about 3 Å to about 90 Å. When the thickness of the electron injection layer is within the range as described above, satisfactory electron injection characteristics may be obtained without a substantial increase in driving voltage.

### Second Electrode 19

The second electrode 19 may be arranged on the interlayer 10A described above.

The second electrode 19 may be a cathode which is an electron injection electrode, and in this regard, a material for forming the second electrode 19 may be selected from a metal, an alloy, an electrically conductive compound, and a combination thereof, which have a relatively low work function.

The second electrode 19 may include lithium (Li), silver (Ag), magnesium (Mg), aluminum (Al), aluminum-lithium (Al—Li), calcium (Ca), magnesium-indium (Mg—In), magnesium-silver (Mg—Ag), ITO, IZO, or any combination thereof. The second electrode 19 may be a transmissive electrode, a transflective electrode, or a reflective electrode.

The second electrode 19 may have a single-layer structure or a multi-layer structure including multiple layers.

### Explanation of Terms

The term “C₁-C₆₀ alkyl group” as used herein refers to a linear or branched saturated aliphatic hydrocarbons monovalent group having 1 to 60 carbon atoms, and the term “C₁-C₆₀ alkylene group” as used here refers to a divalent group having the same structure as the C₁-C₆₀ alkyl group.

Examples of the C₁-C₆₀ alkyl group, the C₁-C₂₀ alkyl group, and/or the C₁-C₁₀ alkyl group are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or any combination thereof.

The term “C₁-C₆₀ alkoxy group” as used herein refers to a monovalent group represented by —OA₁₀₁ (wherein A₁₀₁ is the C₁-C₆₀ alkyl group), and examples thereof are a methoxy group, an ethoxy group, a propoxy group, a butoxy group, and a pentoxy group.

The term “C₂-C₆₀ alkenyl group” as used herein refers to a structure containing at least one carbon-carbon double bond in the middle or at the end of the C₂-C₆₀ alkyl group, and non-limiting examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof are an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the term “C₃-C₁₀ cycloalkylene group” as used herein refers to a divalent group having the same structure as the C₃-C₁₀ cycloalkyl group.

Examples of the C₃-C₁₀ cycloalkyl group are acyclopropyl group, a cyclobutyl group, a cyclopentyl group, a cyclohexyl group, a cycloheptyl group, a cyclooctyl group, an adamantanyl group, a norbornanyl group (a bicyclo[2.2.1]heptyl group), a bicyclo[1.1.1]pentyl group, a bicyclo[2.1.1]hexyl group, and a bicyclo[2.2.2]octyl group.

The term “C₁-C₁₀ heterocycloalkyl group” as used herein refers to a monovalent monocyclic group that includes at least one heteroatom selected from N, O, P, Si, S, Se, Ge, and B as a ring-forming atom and 1 to 10 carbon atoms, and the term “the C₁-C₁₀ heterocycloalkylene group” as used herein refers to a divalent group having the same structure as the C₁-C₁₀ heterocycloalkyl group.

Examples of the C₁-C₁₀ heterocycloalkyl group are a silolanyl group, a silinanyl group, tetrahydrofuranyl group, a tetrahydro-2H-pyranyl group, and a tetrahydrothiophenyl group.

The term “C₃-C₁₀ cycloalkenyl group” as used herein refers to a monovalent cyclic group that has 3 to 10 carbon atoms, and at least one carbon-carbon double bond in the ring thereof and has no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one hetero atom selected from N, O, P, Si, S, Se, Ge, and B as a ring-forming atom, 1 to 10 carbon atoms, and at least one carbon-carbon double bond in the ring thereof. Examples of the C₁-C₁₀ heterocycloalkenyl group are a 2,3-dihydrofuranyl group and a 2,3-dihydrothiophenyl group. The term “C₁-C₁ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group are a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused with each other.

The term “C₁-C₆₀ heteroaryl group” as used herein refers to a monovalent group that includes at least one heteroatom selected from N, O, P, Si, S, Se, Ge, and B as a ring-forming atom and a heterocyclic aromatic system having 1 to 60 carbon atoms, and the term “C₁-C₆₀ heteroarylene group” as used herein refers to a divalent group that includes at least one heteroatom selected from N, O, P, Si, S, Se, Ge, and B as a ring-forming atom and a heterocyclic aromatic system having 1 to 60 carbon atoms. Examples of the C₁-C₆₀ heteroaryl group are a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused with each other.

The term “C₆-C₆₀ aryloxy group” as used herein indicates —OA₁₀₂ (wherein A102 is the C₆-C₆₀ aryl group), and the term “C₆-C₆₀ arylthio group” as used herein indicates —SA₁₀₃ (wherein A103 is the C₆-C₆₀ aryl group).

The term “C₇-C₆₀ aryl alkyl group” as used herein indicates -A₁₀₄A₁₀₅ (wherein A₁₀₄ is the C₆-C₆₀ aryl group and A105 is the C₁-C₆₀ alkyl group). The term “C₂-C₆₀ heteroaryl alkyl group” as used herein indicates -A₁₀₆A₁₀₉ (wherein A₁₀₉ is the C₁-C₆₀ heteroaryl group and A₁₀₈ is the C₁-C₆₀ alkyl group).

The term “monovalent non-aromatic condensed polycyclic group” as used herein refers to a monovalent group in which two or more rings are condensed with each other, only carbon is used as a ring-forming atom (for example, the number of carbon atoms may be 8 to 60), and the whole molecule is a non-aromaticity group. Examples of the non-aromatic condensed polycyclic group include a fluorenyl group, etc. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed with each other, a heteroatom selected from N, O, P, Si, S, Se, Ge, and B, other than carbon atoms (for example, having 1 to 60 carbon atoms), as a ring-forming atom, and no aromaticity in the entire molecular structure thereof. Examples of the monovalent non-aromatic condensed heteropolycyclic group include a carbazolyl group or the like. The term “divalent non-aromatic condensed heteropolycyclic group” as used herein refers to a divalent group having the same structure as the monovalent non-aromatic condensed heteropolycyclic group.

The term “π electron-depleted nitrogen-containing C₁-C₆₀ cyclic group” as used herein refers to a cyclic group having 1 to 60 carbon atoms and including at least one *—N═*′ (wherein * and *′ each indicate a binding site to an adjacent atom) as a ring-forming moiety. For example, the π electron-depleted nitrogen-containing C₁-C₆₀ cyclic group may be a) a first ring, b) a condensed ring in which at least two first rings are condensed, or c) a condensed ring in which at least one first ring and at least one second ring are condensed.

The term “π electron-rich C₃-C₆₀ cyclic group” as used herein refers to a cyclic group having 3 to 60 carbon atoms and not including at least one *—N═*′ (wherein * and *′ each indicate a binding site to an adjacent atom) as a ring-forming moiety. For example, the π electron-rich C₃-C₆₀ cyclic group may be a) a second ring or b) a condensed ring in which at least two second rings are condensed.

The term “C₅-C₆₀ cyclic group” as used herein refers to a monocyclic or polycyclic group having 5 to 60 carbon atoms, and may be, for example, a) a third ring or b) a condensed ring in which two or more third rings are condensed with each other.

The term “C₁-C₆₀ heterocyclic group” as used herein refers to a monocyclic or polycyclic group that has 1 to 60 carbon atoms and includes at least one heteroatom, and may be, for example, a) a fourth ring, b) a condensed ring in which two or more fourth rings are condensed with each other, or c) a condensed ring in which at least one third ring is condensed with at least one fourth ring.

The “first ring” as used herein may be an imidazole group, a pyrazole group, a thiazole group, an isothiazole group, an oxazole group, an isoxazole group, a pyridine group, a pyrazine group, a pyridazine group, a pyrimidine group, a triazole group, a tetrazole group, an oxadiazole group, a triazine group, or a thiadiazole group.

The “second ring” as used herein may be a benzene group, a cyclopentadiene group, a pyrrole group, a furan group, a thiophene group, or a silole group.

The “third ring” as used herein may be a cyclopentane group, a cyclopentadiene group, an indene group, an adamantane group, a norbornene group, a bicyclo[1.1.1]pentane group, a bicyclo[2.1.1]hexane group, a bicyclo[2.2.1]heptane group (a norbornane group), a bicyclo[2.2.2]octane group, a cyclohexane group, a cyclohexene group, or a benzene group.

The “fourth ring” as used herein may be a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, a triazasilole group, a pyridine group, a pyrimidine group, a pyrazine group, a pyridazine group, or a triazine group.

For example, the π electron-depleted nitrogen-containing C₁-C₆₀ cyclic group may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinoline group, a phthalazine group, a naphthyridine group, a quinoxaline group, a benzoquinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azacarbazole group, an azadibenzofuran group, an azadibenzothiophene group, an azadibenzosilole group, an acridine group, or a pyridopyrazine group.

For example, the π electron-rich C₃-C₆₀ cyclic group may be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, a furan group, a thiophene group, an isoindole group, an indole group, an indene group, a benzofuran group, a benzothiophene group, a benzosilole group, a naphthopyrrole group, a naphthofuran group, a naphthothiophene group, a naphthosilole group, a benzocarbazole group, a dibenzocarbazole group, a dibenzofuran group, a dibenzothiophene group, a carbazole group, a dibenzosilole group, an indenocarbazole group, an indolocarbazole group, a benzofurocarbazole group, a benzothienocarbazole group, a benzosilolocarbazole group, a triindolobenzene group, a pyrrolophenanthrene group, a furanophenanthrene group, a thienophenanthrene group, a benzonaphthofuran group, a benzonapthothiophene group, an (indolo)phenanthrene group, a (benzofurano)phenanthrene group, or a (benzothieno)phenanthrene group.

For example, the C₅-C₆₀ carbocyclic group may be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, an indene group, a fluorene group, a 5,6,7,8-tetrahydroisoquinoline group, a 5,6,7,8-tetrahydroquinoline group, an adamantane group, a norbornane group, or a norbornene group.

For example, the C₁-C₆₀ heterocyclic group may be a thiophene group, a furan group, a pyrrole group, a cyclopentadiene group, a silole group, a borole group, a phosphole group, a selenophene group, a germole group, a benzothiophene group, a benzofuran group, an indole group, an indene group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluorene-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group.

The term “N-carbazolyl group” as used herein refers to a monovalent group in which hydrogen separated from N of a carbazole group may be bonded to other groups and may be represented by

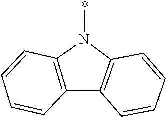 [SMILES: *n1c2ccccc2c2ccccc21]

(wherein * indicates a binding site to a neighboring atoms).

The terms “a π electron-deficient nitrogen-containing C₁-C₆₀ cyclic group, a π electron-rich C₃-C₆₀ cyclic group, a C₅-C₆₀ cyclic group, and a C₁-C₆₀ heterocyclic group” as used herein each refer to a part of a condensed ring or a monovalent, a divalent, a trivalent, a tetravalent, a pentavalent, or a hexavalent group, depending on the formula structure.

Substituents of the substituted π electron-deficient nitrogen-containing C₁-C₆₀ cyclic group, the substituted π electron-rich C₃-C₆₀ cyclic group, the substituted C₅-C₆₀ cyclic group, the substituted C₁-C₆₀ heterocyclic group, the substituted C₁-C₆₀ alkylene group, the substituted C₂-C₆₀ alkenylene group, the substituted C₂-C₆₀ alkynylene group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁ heterocycloalkyl group, the substituted C₃-C₁₀ cycloalkenyl group, the substituted C₁-C₁ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may each independently be:
deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁ cycloalkyl group, a C₁-C₁ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
any combination thereof.

Q₁ to Q₉, Q₁₁ to Q₁₉, Q₂₁ to Q₂₉, and Q₃₁ to Q₃₉ described herein may each independently be: hydrogen; deuterium; —F; —Cl; —Br; —I; a hydroxyl group; a cyano group; a nitro group; an amidino group; a hydrazine group; a hydrazone group; a carboxylic acid or a salt thereof; a sulfonic acid or a salt thereof; a phosphoric acid or a salt thereof; a C₁-C₆₀ alkyl group which is unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group which is unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

For example, Q₁ to Q₉, Q₁₁ to Q₁₉, Q₂₁ to Q₂₉, and Q₃₁ to Q₃₉ described herein may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or any combination thereof.

The term “room temperature” as used herein refers to a temperature of about 25° C.

Throughout the specification, D refers to deuterium, and Ph refers to a phenyl group.

The terms “a biphenyl group, a terphenyl group, and a tetraphenyl group” used herein respectively refer to monovalent groups in which two, three, or four phenyl groups which are linked together via a single bond.

Hereinafter, a compound and a light-emitting device according to embodiments of the disclosure are described in detail with reference to Synthesis Example and Examples.

However, the light-emitting device is not limited thereto. The wording “‘B’ was used instead of ‘A’” used in describing Synthesis Examples means that an amount of ‘A’ used was identical to an amount of ‘B’ used, in terms of a molar equivalent.

### Synthesis Example 1 (Synthesis of Compound 1)

### Synthesis of Compound 1-C

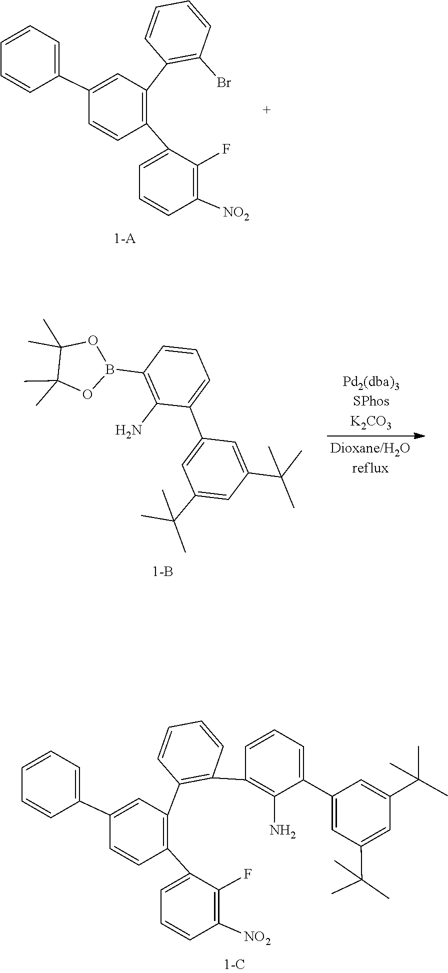 [SMILES: O=[N+]([O-])c1cccc(-c2ccc(-c3ccccc3)cc2-c2ccccc2Br)c1F ; CC(C)(C)c1cc(-c2cccc(B3OC(C)(C)C(C)(C)O3)c2N)cc(C(C)(C)C)c1 ; CC(C)(C)c1cc(-c2cccc(-c3ccccc3-c3cc(-c4ccccc4)ccc3-c3cccc([N+](=O)[O-])c3F)c2N)cc(C(C)(C)C)c1]

Compound 1-A [10.0 grams (g), 22.3 millimoles (mmol)], Compound 1-B (10.0 g, 24.5 mmol), tris(dibenzylideneacetone)dipalladium(0) (Pd₂(dba)₃, 2.04 g, 2.23 mmol), 2-dicyclohexylphosphino-2′,6′-dimethoxybiphenyl (SPhos, 1.83 g, 4.46 mmol), and potassium carbonate (K₂CO₃, 7.71 g, 55.8 mmol) were added into a round-bottom flask and mixed with 1,4-dioxane/H₂O (100 mL/25 mL). The mixture was stirred under reflux at 110° C. for 12 hours. After 12 hours, the mixture was allowed to cool to room temperature, and then, ethyl acetate and a saturated aqueous ammonium chloride solution were added to the reaction mixture. The organic layer was extracted using ethyl acetate, dried using anhydrous MgSO₄, and then filtered. The filtrate was concentrated and purified by silica gel column chromatography to provide 7.2 g (yield of 52%) of Compound 1-C.

LC-Mass (calculated: 648.32 grams per mol (g/mol), found: M⁺¹=649 g/mol).

### Synthesis of Compound 1-D

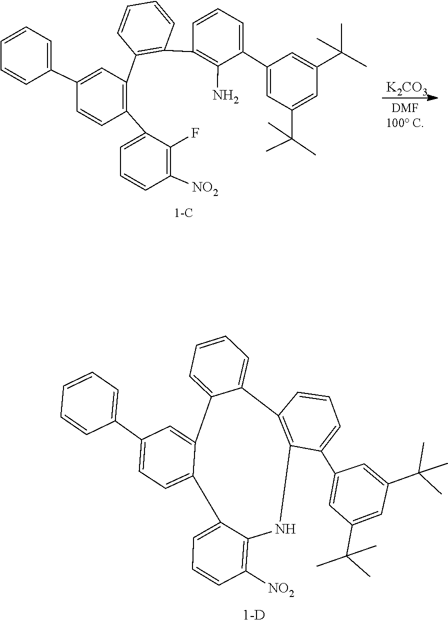

Compound 1-C (7.2 g, 11.2 mmol) and K₂CO₃ (4.62 g, 33.5 mmol) were added into a round-bottom flask and mixed with dimethylformamide (DMF, 125 mL). The mixture was stirred at 100° C. for 12 hours. After 12 hours, the mixture was allowed to cool to room temperature, and then, ethyl acetate and a saturated aqueous ammonium chloride solution were added to the reaction mixture. The solution layer was extracted using ethyl acetate, dried using anhydrous MgSO₄, and then filtered. The filtrate was concentrated and purified by silica gel column chromatography to provide 4.7 g (yield of 67%) of Compound 1-D.

LC-Mass (calculated: 628.31 g/mol, found: M⁺¹=629 g/mol).

### Synthesis of Compound 1-E

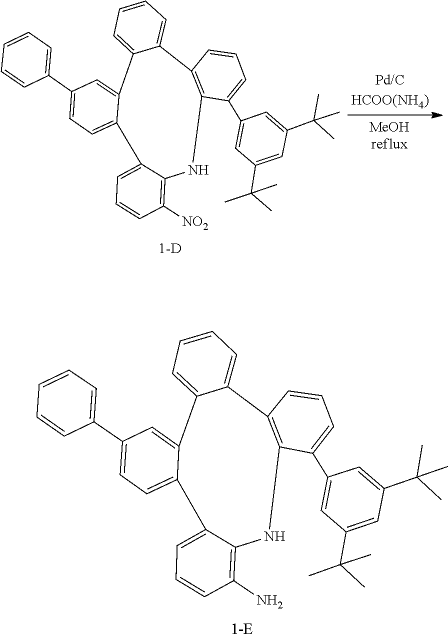 [SMILES: CC(C)(C)c1cc(-c2cccc3c2[nH]c2c([N+](=O)[O-])cccc2c2ccc(-c4ccccc4)cc2c2ccccc32)cc(C(C)(C)C)c1 ; CC(C)(C)c1cc(-c2cccc3c2[nH]c2c(N)cccc2c2ccc(-c4ccccc4)cc2c2ccccc32)cc(C(C)(C)C)c1]

Compound 1-D (4.7 g, 7.5 mmol), Pd/C (10 wt % on carbon, 0.8 g, 0.75 mmol), and ammonium formate (HCOO(NH₄), 9.5 g, 150 mmol) were added into a round-bottom flask and mixed with methanol (MeOH, 50 mL). The mixture was stirred at 80° C. for 12 hours. After 12 hours, the mixture was allowed to cool to room temperature, and then, ethyl acetate and a saturated aqueous ammonium chloride solution were added to the reaction mixture. The organic layer was extracted using ethyl acetate, dried using anhydrous MgSO₄, and then filtered. The filtrate was concentrated and purified by silica gel column chromatography to provide 4.3 g (yield of 97%) of Compound 1-E.

LC-Mass (calculated: 598.33 g/mol, found: M⁺¹=599 g/mol).

### Synthesis of Compound 1-G

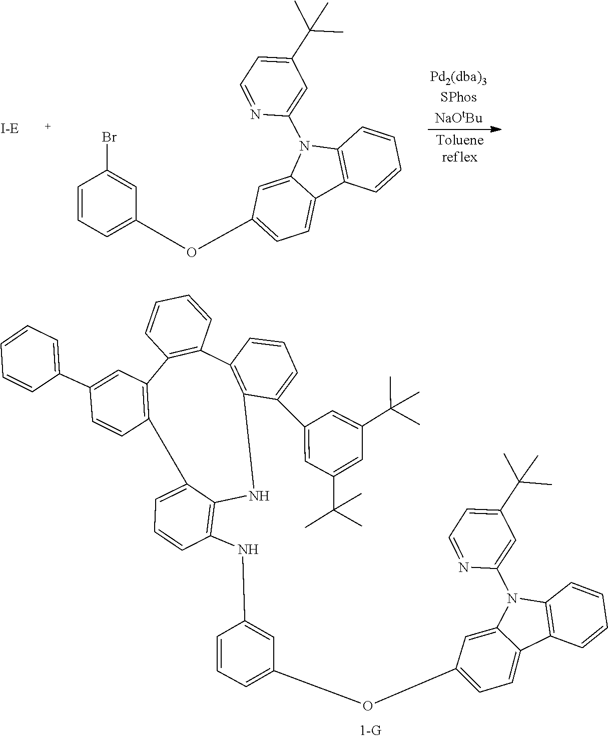

Compound 1-E (4.3 g, 7.3 mmol), Compound 1-F (3.8 g, 8.0 mmol), Pd₂(dba)₃ (0.66 g, 0.73 mmol), SPhos (0.60 g, 1.4 mmol), and sodium tert-butoxide (NaOtBu, 1.5 g, 10.9 mmol) were added into a round-bottom flask and mixed with toluene (70 mL). The mixture was stirred under reflux at 110° C. for 12 hours. After 12 hours, the mixture was allowed to cool to room temperature, and then, ethyl acetate and a saturated aqueous ammonium chloride solution were added to the reaction mixture. The organic layer was extracted using ethyl acetate, dried using anhydrous MgSO₄, and then filtered. The filtrate was concentrated and purified by silica gel column chromatography to provide 6.5 g (yield of 90%) of Compound 1-G.

LC-Mass (calculated: 988.51 g/mol, found: M⁺¹=989 g/mol).

### Synthesis of Compound 1-H

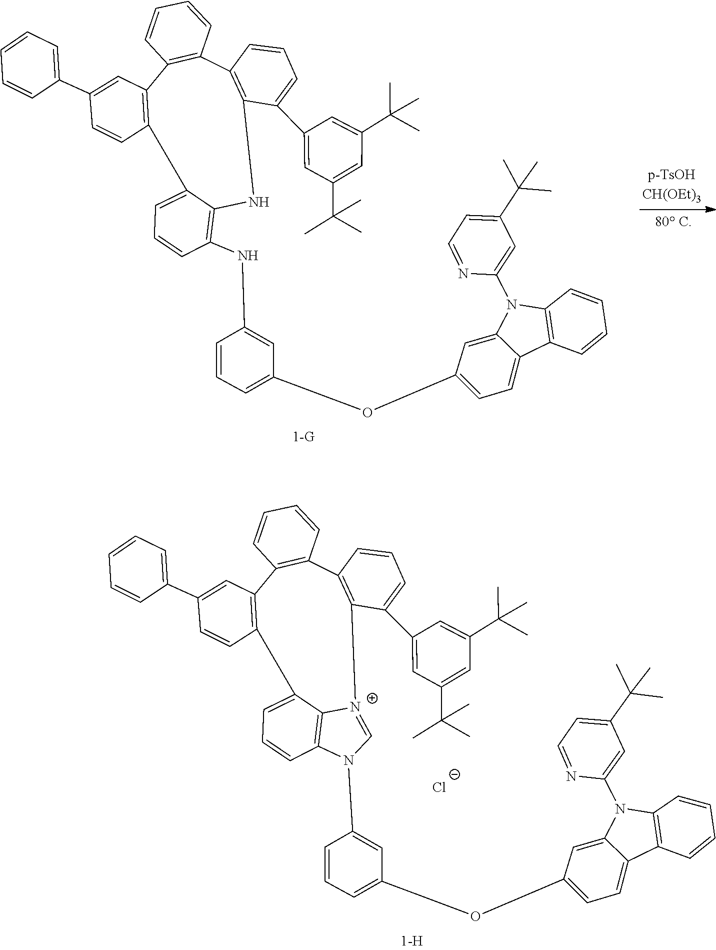 [SMILES: CC(C)(C)c1cc(-c2cccc3c2[nH]c2c(Nc4cccc(Oc5ccc6c7ccccc7n(-c7cc(C(C)(C)C)ccn7)c6c5)c4)cccc2c2ccc(-c4ccccc4)cc2c2ccccc32)cc(C(C)(C)C)c1 ; CC(C)(C)c1cc(-c2cccc3c2-[n+]2cn(-c4cccc(Oc5ccc6c7ccccc7n(-c7cc(C(C)(C)C)ccn7)c6c5)c4)c4cccc(c42)-c2ccc(-c4ccccc4)cc2-c2ccccc2-3)cc(C(C)(C)C)c1 ; [Cl-]]

Compound 1-G (6.5 g, 6.5 mmol) and p-toluenesulfonic acid (p-TsOH, 0.11 g, 0.65 mmol) were added into a round-bottom flask and mixed with triethylorthoformate (CH(OEt)₃, 45 mL). The mixture was stirred under reflux at 80° C. for 12 hours. After 12 hours, the mixture was allowed to cool to room temperature, and then, ethyl acetate and a saturated aqueous ammonium chloride solution were added to the reaction mixture. The organic layer was extracted using ethyl acetate, dried using anhydrous MgSO₄, and then filtered. The filtrate was concentrated and purified by silica gel column chromatography to provide 6.4 g (yield of 95%) of Compound 1-H.

### Synthesis of Compound 1

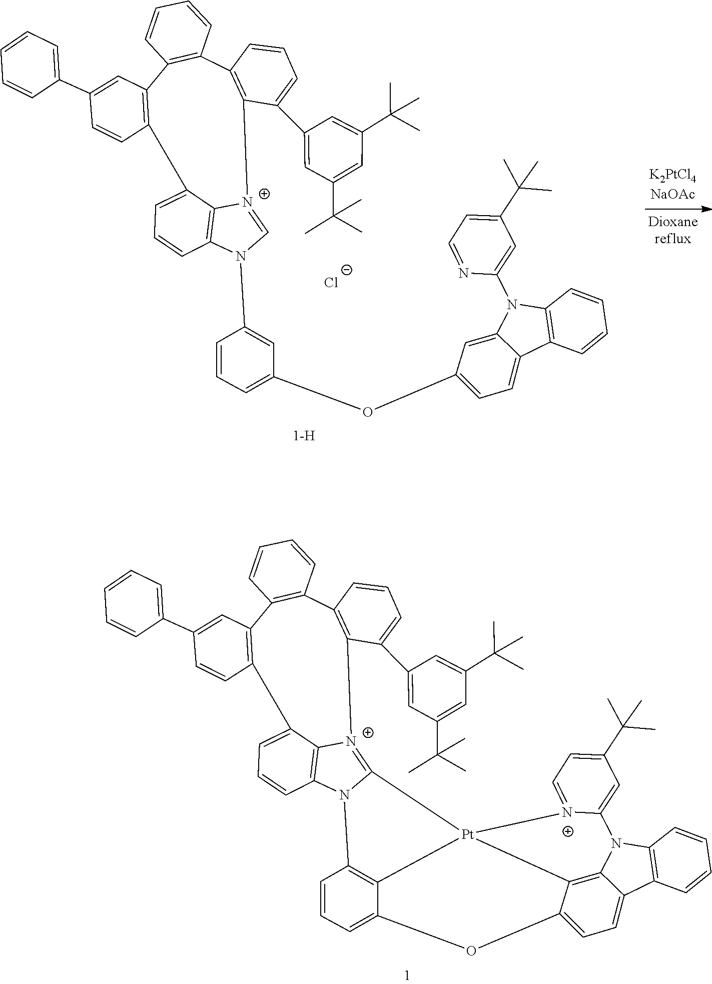

Compound 1-H (6.4 g, 6.2 mmol), potassium tetrachloroplatinate (K₂PtCl₄, 2.8 g, 6.8 mmol), and sodium acetate (NaOAc, 1.5 g, 18.6 mmol) were added into a round-bottom flask and mixed with dioxane (120 mL). The mixture was stirred at 100° C. for 12 hours. After 12 hours, the mixture was allowed to cool to room temperature, and then, ethyl acetate and a saturated aqueous ammonium chloride solution were added to the reaction mixture. The organic layer was extracted using ethyl acetate, dried using anhydrous MgSO₄, and then filtered. The filtrate was concentrated and purified by silica gel column chromatography to provide 3.2 g (yield of 43%) of Compound 1.

LC-Mass (calculated: 1191.44 g/mol, found: M⁺¹=1192 g/mol).

### Synthesis Example 2 (Synthesis of Compound 2)

### Synthesis of Compound 2-B

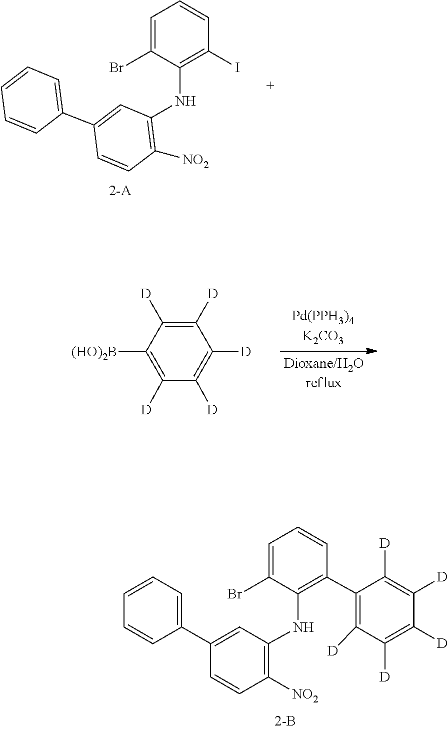 [SMILES: O=[N+]([O-])c1ccc(-c2ccccc2)cc1Nc1c(Br)cccc1I ; [2H]c1c([2H])c([2H])c(B(O)O)c([2H])c1[2H] ; [2H]c1c([2H])c([2H])c(-c2cccc(Br)c2Nc2cc(-c3ccccc3)ccc2[N+](=O)[O-])c([2H])c1[2H]]

Compound 2-A (10.0 g, 20.2 mmol), (phenyl-d5)boronic acid (2.56 g, 20.2 mmol), tetrakis(triphenylphosphine)palladium(0) (Pd(PPh₃)₄, 2.33 g, 2.02 mmol), and K₂CO₃ (8.37 g, 60.6 mmol) were added into a round-bottom flask and mixed with 1,4-dioxane/H₂O (400 mL/100 mL). The mixture was stirred under reflux at 110° C. for 12 hours. After 12 hours, the mixture was allowed to cool to room temperature, and then, ethyl acetate and a saturated aqueous ammonium chloride solution were added to the reaction mixture. The organic layer was extracted using ethyl acetate, dried using anhydrous MgSO₄, and then filtered. The filtrate was concentrated and purified by silica gel column chromatography to provide 5.1 g (yield of 56%) of Compound 2-B.

LC-Mass (calculated: 449.08 g/mol, found: M⁺¹=450 g/mol).

### Synthesis of Compound 2-C

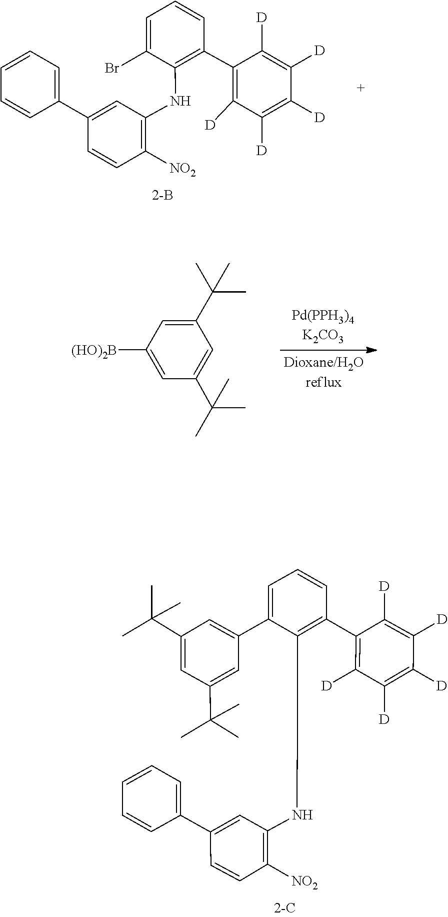 [SMILES: [2H]c1c([2H])c([2H])c(-c2cccc(Br)c2Nc2cc(-c3ccccc3)ccc2[N+](=O)[O-])c([2H])c1[2H] ; CC(C)(C)c1cc(B(O)O)cc(C(C)(C)C)c1 ; [2H]c1c([2H])c([2H])c(-c2cccc(-c3cc(C(C)(C)C)cc(C(C)(C)C)c3)c2Nc2cc(-c3ccccc3)ccc2[N+](=O)[O-])c([2H])c1[2H]]

Compound 2-B (5.1 g, 11.3 mmol), (3,5-di-tert-butylphenyl)boronic acid (3.18 g, 13.6 mmol), Pd(PPh₃)₄ (1.57 g, 1.13 mmol), and K₂CO₃ (2.34 g, 17.0 mmol) were added into a round-bottom flask and mixed with 1,4-dioxane/H₂O (100 mL/25 mL). The mixture was stirred under reflux at 110° C. for 12 hours. After 12 hours, the mixture was allowed to cool to room temperature, and then, ethyl acetate and a saturated aqueous ammonium chloride solution were added to the reaction mixture. An organic solution layer was extracted using ethyl acetate, dried using anhydrous MgSO₄, and then filtered. The filtrate was concentrated and purified by silica gel column chromatography to provide 4.5 g (yield of 71%) of Compound 2-C.

LC-Mass (calculated: 559.32 g/mol, found: M⁺¹=560 g/mol).

### Synthesis of Compound 2-D

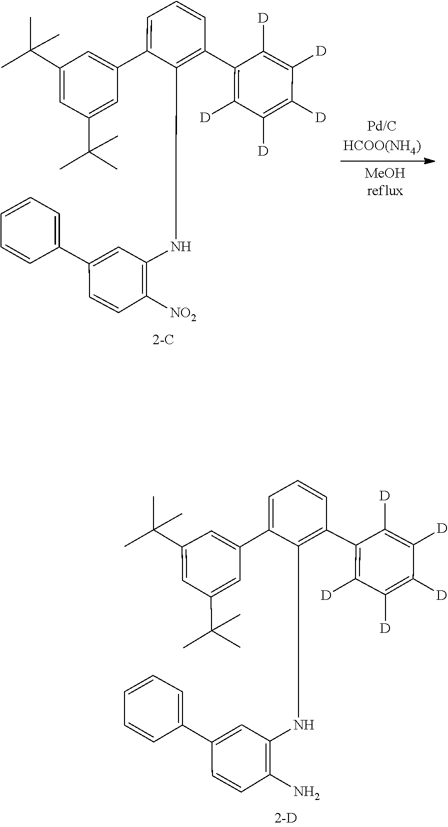 [SMILES: [2H]c1c([2H])c([2H])c(-c2cccc(-c3cc(C(C)(C)C)cc(C(C)(C)C)c3)c2Nc2cc(-c3ccccc3)ccc2[N+](=O)[O-])c([2H])c1[2H] ; [2H]c1c([2H])c([2H])c(-c2cccc(-c3cc(C(C)(C)C)cc(C(C)(C)C)c3)c2Nc2cc(-c3ccccc3)ccc2N)c([2H])c1[2H]]

Compound 2-D was obtained in the same manner as in the synthesis of Compound 1-E of Synthesis Example 1, except that Compound 2-C was used instead of Compound 1-D.

### Synthesis of Compound 2-F

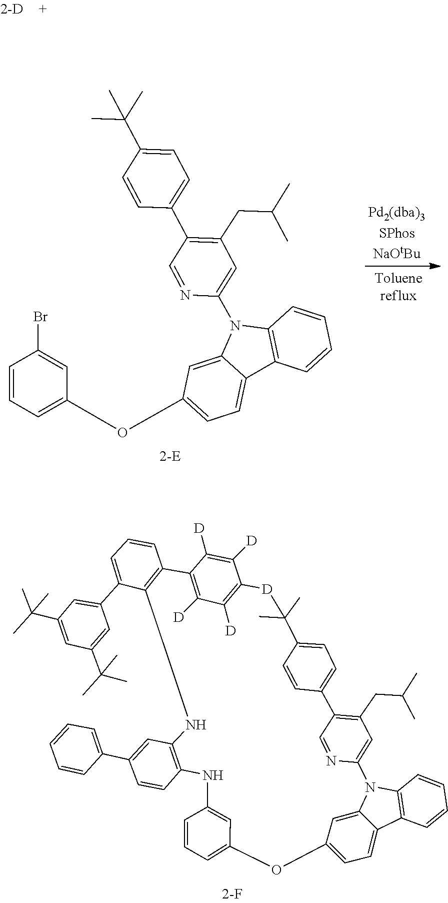

Compound 2-F was obtained in the same manner as in the synthesis of Compound 1-G of Synthesis Example 1, except that Compound 2-D was used instead of Compound 1-E and Compound 2-E was used instead of Compound 1-F.

### Synthesis of Compound 2-G

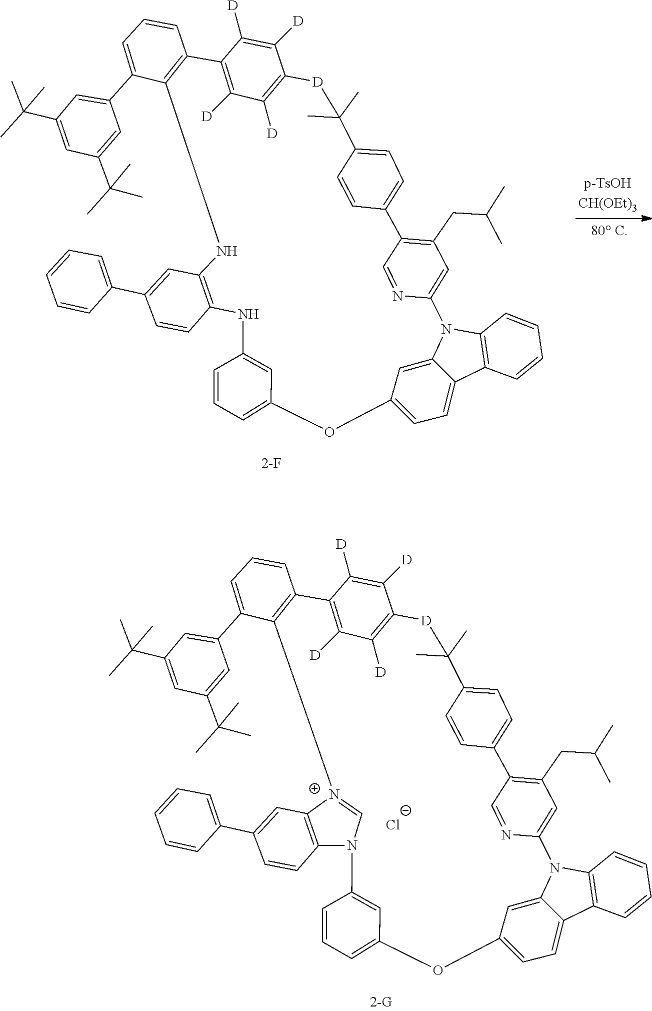

Compound 2-G was obtained in the same manner as in the synthesis of Compound 1-H of Synthesis Example 1, except that Compound 2-F was used instead of Compound 1-G.

### Synthesis of Compound 2

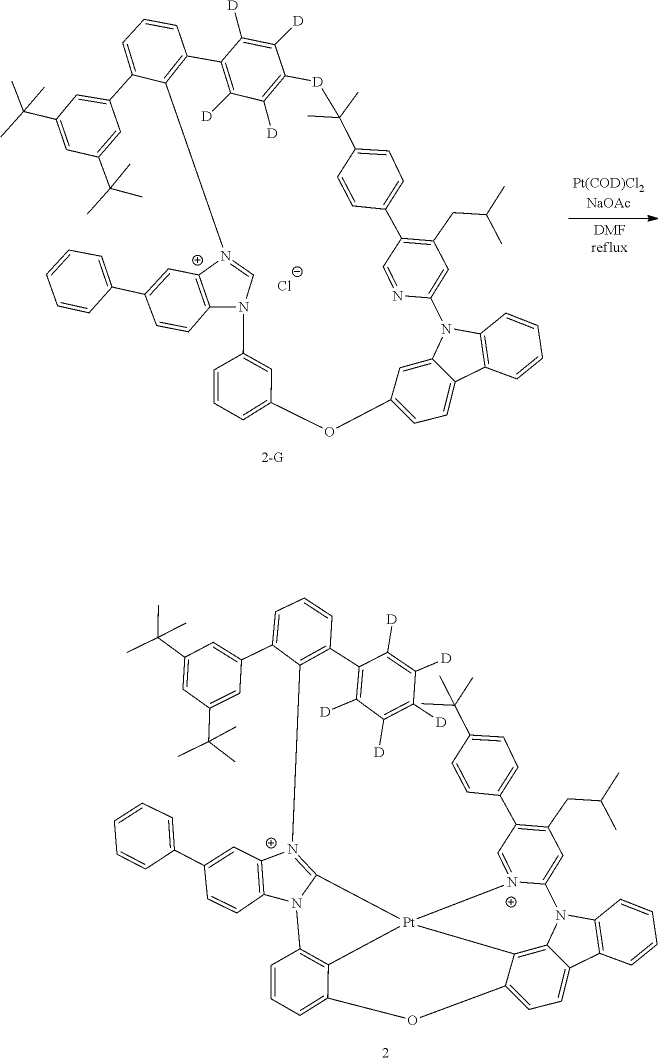

Compound 2-G (6.8 g, 6.19 mmol), (1,5-cyclooctadiene)platinum(II) dichloride (Pt(COD)Cl₂, 2.5 g, 6.81 mmol), and NaOAc (1.5 g, 18.6 mmol) were added into a round-bottom flask and mixed with DMF (150 mL). The mixture was stirred at 150° C. for 12 hours. After 12 hours, the mixture was allowed to cool to room temperature, and then, ethyl acetate and a saturated aqueous ammonium chloride solution were added to the reaction mixture. The organic layer was extracted using ethyl acetate, dried using anhydrous MgSO₄, and then filtered. The filtrate was concentrated and purified by silica gel column chromatography to provide 2.0 g (yield of 26%) of Compound 2.

LC-Mass (calculated: 1254.55 g/mol, found: M⁺¹=1255 g/mol).

### Synthesis Example 3 (Synthesis of Compound 3)

### Synthesis of Compound 3-C

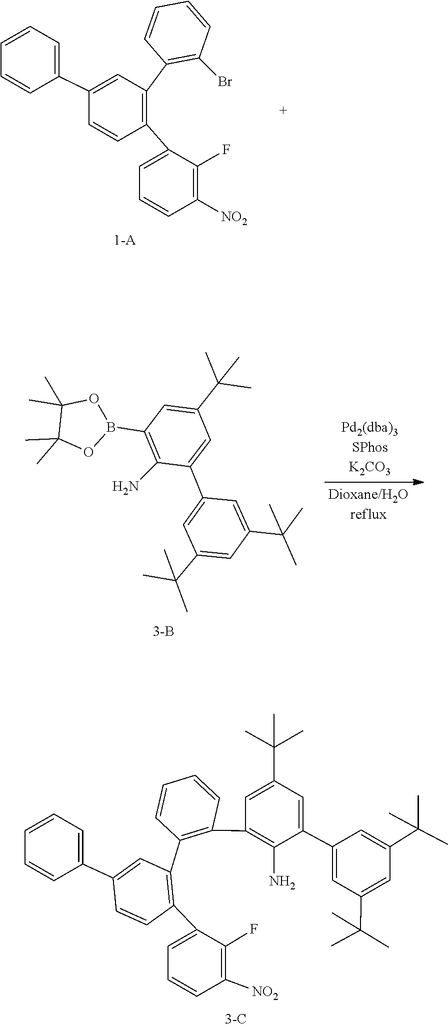 [SMILES: O=[N+]([O-])c1cccc(-c2ccc(-c3ccccc3)cc2-c2ccccc2Br)c1F ; CC(C)(C)c1cc(-c2cc(C(C)(C)C)cc(B3OC(C)(C)C(C)(C)O3)c2N)cc(C(C)(C)C)c1 ; CC(C)(C)c1cc(-c2cc(C(C)(C)C)cc(-c3ccccc3-c3cc(-c4ccccc4)ccc3-c3cccc([N+](=O)[O-])c3F)c2N)cc(C(C)(C)C)c1]

Compound 3-C was obtained in the same manner as in the synthesis of Compound 1-C of Synthesis Example 1, except that Compound 3-B was used instead of Compound 1-B.

### Synthesis of Compound 3-D

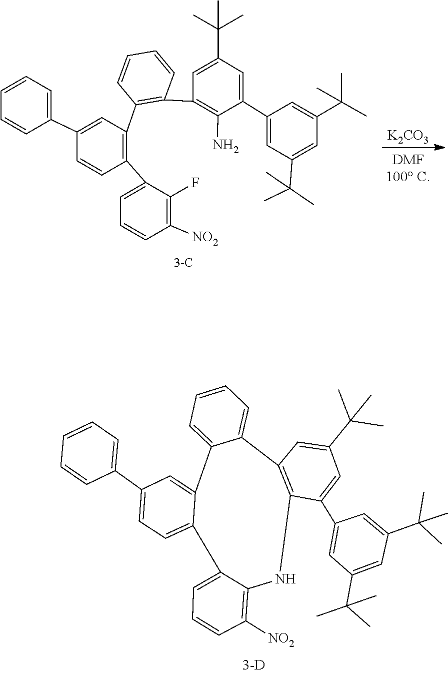

Compound 3-D was obtained in the same manner as in the synthesis of Compound 1-D of Synthesis Example 1, except that Compound 3-C was used instead of Compound 1-C.

### Synthesis of Compound 3-E

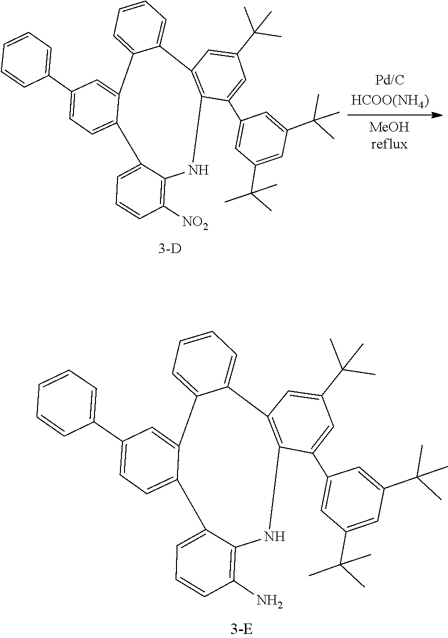 [SMILES: CC(C)(C)c1cc(-c2cc(C(C)(C)C)cc3c2[nH]c2c([N+](=O)[O-])cccc2c2ccc(-c4ccccc4)cc2c2ccccc32)cc(C(C)(C)C)c1 ; CC(C)(C)c1cc(-c2cc(C(C)(C)C)cc3c2[nH]c2c(N)cccc2c2ccc(-c4ccccc4)cc2c2ccccc32)cc(C(C)(C)C)c1]

Compound 3-E was obtained in the same manner as in the synthesis of Compound 1-E of Synthesis Example 1, except that Compound 3-D was used instead of Compound 1-D.

### Synthesis of Compound 3-G

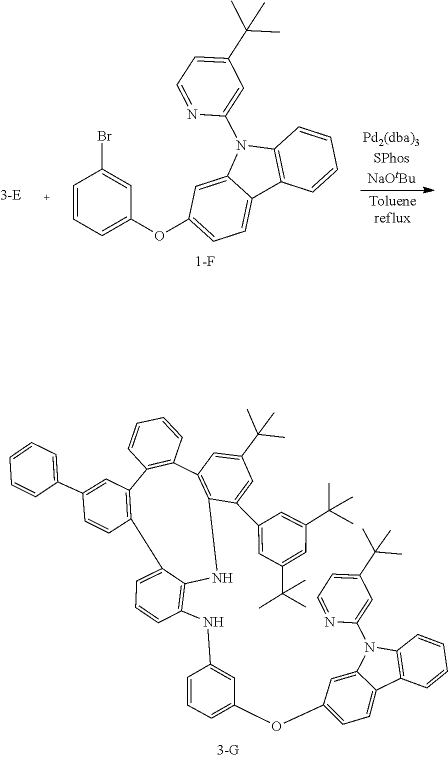 [SMILES: CC(C)(C)c1ccnc(-n2c3ccccc3c3ccc(Oc4cccc(Br)c4)cc32)c1 ; CC(C)(C)c1cc(-c2cc(C(C)(C)C)cc3c2[nH]c2c(Nc4cccc(Oc5ccc6c7ccccc7n(-c7cc(C(C)(C)C)ccn7)c6c5)c4)cccc2c2ccc(-c4ccccc4)cc2c2ccccc32)cc(C(C)(C)C)c1]

Compound 3-G was obtained in the same manner as in the synthesis of Compound 1-G of Synthesis Example 1, except that Compound 3-E was used instead of Compound 1-E.

### Synthesis of Compound 3-H

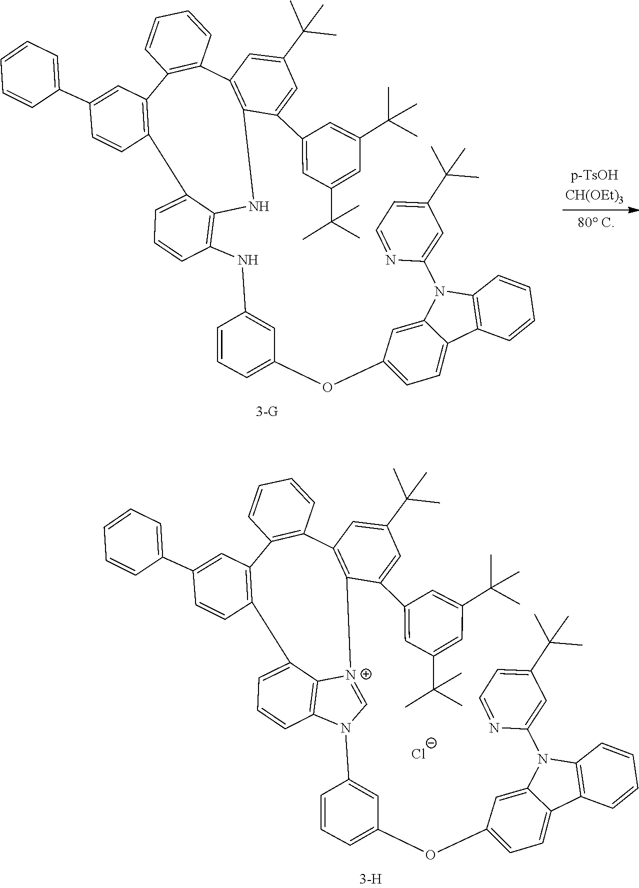 [SMILES: CC(C)(C)c1cc(-c2cc(C(C)(C)C)cc3c2[nH]c2c(Nc4cccc(Oc5ccc6c7ccccc7n(-c7cc(C(C)(C)C)ccn7)c6c5)c4)cccc2c2ccc(-c4ccccc4)cc2c2ccccc32)cc(C(C)(C)C)c1 ; CC(C)(C)c1cc(-c2cc(C(C)(C)C)cc3c2-[n+]2cn(-c4cccc(Oc5ccc6c7ccccc7n(-c7cc(C(C)(C)C)ccn7)c6c5)c4)c4cccc(c42)-c2ccc(-c4ccccc4)cc2-c2ccccc2-3)cc(C(C)(C)C)c1 ; [Cl-]]

Compound 3-H was obtained in the same manner as in the synthesis of Compound 1-H of Synthesis Example 1, except that Compound 3-G was used instead of Compound 1-G.

### Synthesis of Compound 3

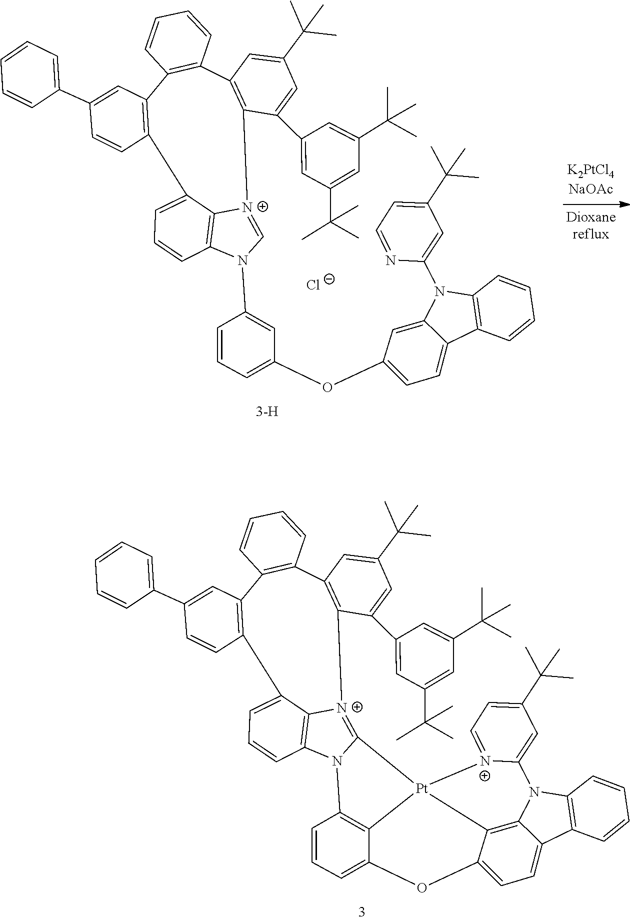

Compound 3-H (7.5 g, 6.87 mmol), K₂PtCl₄ (3.14 g, 7.56 mmol), and NaOAc (1.7 g, 20.6 mmol) were added into a round-bottom flask and mixed with dioxane (150 mL). The mixture was stirred at 100° C. for 12 hours. After 12 hours, the mixture was allowed to cool to room temperature, and then, ethyl acetate and a saturated aqueous ammonium chloride solution were added to the reaction mixture. The organic layer was extracted using ethyl acetate, dried using anhydrous MgSO₄, and then filtered. The filtrate was concentrated and purified by silica gel column chromatography to provide 2.8 g (yield of 33%) of Compound 3.

LC-Mass (calculated: 1247.50 g/mol, found: M⁺¹=1248 g/mol).

### Synthesis Example 4 (Synthesis of Compound 4)

### Synthesis of Compound 4-C

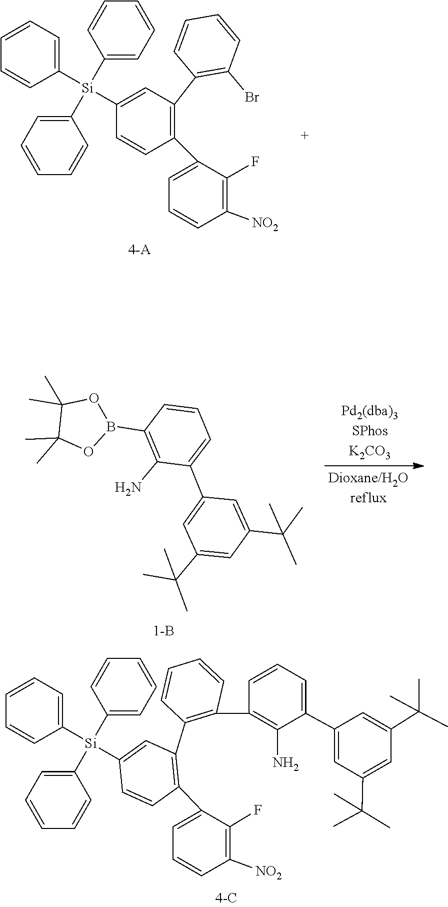

Compound 4-C was obtained in the same manner as in the synthesis of Compound 1-C of Synthesis Example 1, except that Compound 4-A was used instead of Compound 1-A.

### Synthesis of Compound 4-D

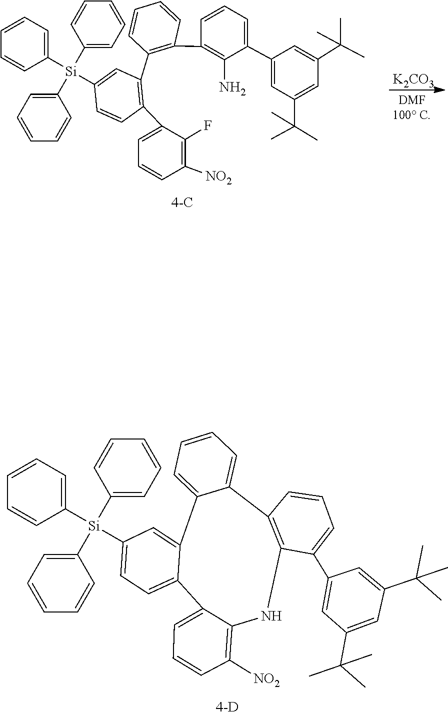

Compound 4-D was obtained in the same manner as in the synthesis of Compound 1-D of Synthesis Example 1, except that Compound 4-C was used instead of Compound 1-C.

### Synthesis of Compound 4-E

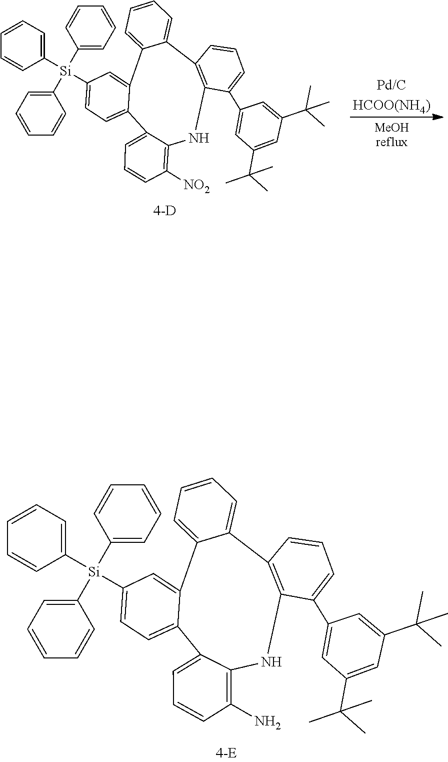 [SMILES: CC(C)(C)c1cc(-c2cccc3c2[nH]c2c([N+](=O)[O-])cccc2c2ccc([Si](c4ccccc4)(c4ccccc4)c4ccccc4)cc2c2ccccc32)cc(C(C)(C)C)c1 ; "Pd/CHCOO(NH4)" ; CC(C)(C)c1cc(-c2cccc3c2[nH]c2c(N)cccc2c2ccc([Si](c4ccccc4)(c4ccccc4)c4ccccc4)cc2c2ccccc32)cc(C(C)(C)C)c1]

Compound 4-E was obtained in the same manner as in the synthesis of Compound 1-E of Synthesis Example 1, except that Compound 4-D was used instead of Compound 1-D.

### Synthesis of Compound 4-G

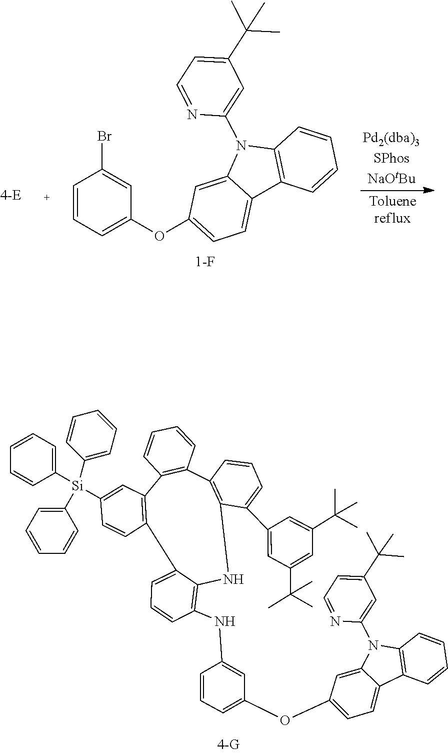 [SMILES: CC(C)(C)c1ccnc(-n2c3ccccc3c3ccc(Oc4cccc(Br)c4)cc32)c1 ; CC(C)(C)c1cc(-c2cccc3c2[nH]c2c(Nc4cccc(Oc5ccc6c7ccccc7n(-c7cc(C(C)(C)C)ccn7)c6c5)c4)cccc2c2ccc([Si](c4ccccc4)(c4ccccc4)c4ccccc4)cc2c2ccccc32)cc(C(C)(C)C)c1]

Compound 4-G was obtained in the same manner as in the synthesis of Compound 1-G of Synthesis Example 1, except that Compound 4-E was used instead of Compound 1-E.

### Synthesis of Compound 4-H

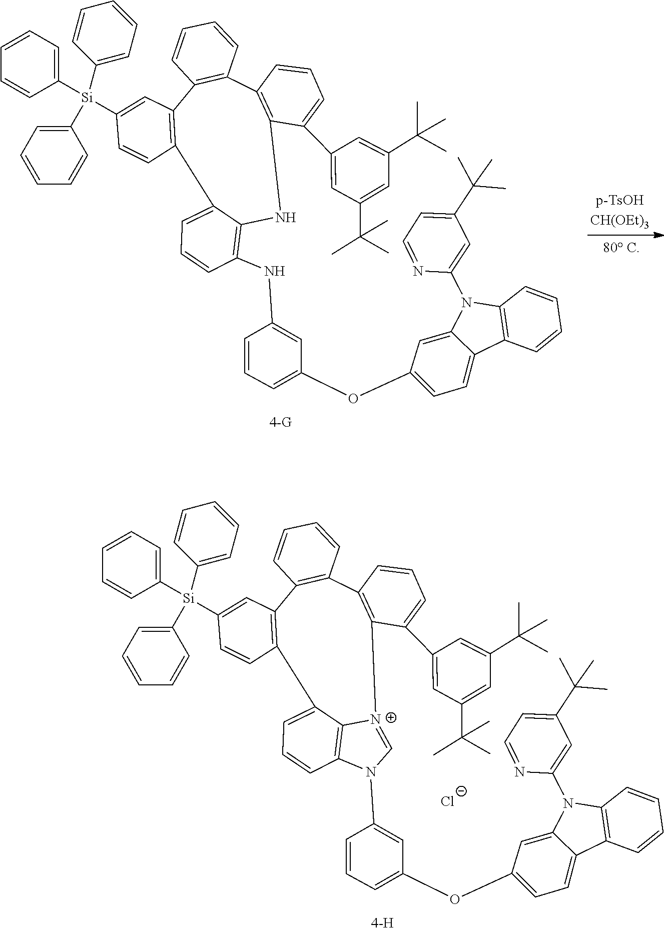 [SMILES: CC(C)(C)c1cc(-c2cccc3c2[nH]c2c(Nc4cccc(Oc5ccc6c7ccccc7n(-c7cc(C(C)(C)C)ccn7)c6c5)c4)cccc2c2ccc([Si](c4ccccc4)(c4ccccc4)c4ccccc4)cc2c2ccccc32)cc(C(C)(C)C)c1 ; CC(C)(C)c1cc(-c2cccc3c2-[n+]2cn(-c4cccc(Oc5ccc6c7ccccc7n(-c7cc(C(C)(C)C)ccn7)c6c5)c4)c4cccc(c42)-c2ccc([Si](c4ccccc4)(c4ccccc4)c4ccccc4)cc2-c2ccccc2-3)cc(C(C)(C)C)c1 ; [Cl-]]

Compound 4-H was obtained in the same manner as in the synthesis of Compound 1-H of Synthesis Example 1, except that Compound 4-G was used instead of Compound 1-G.

### Synthesis of Compound 4

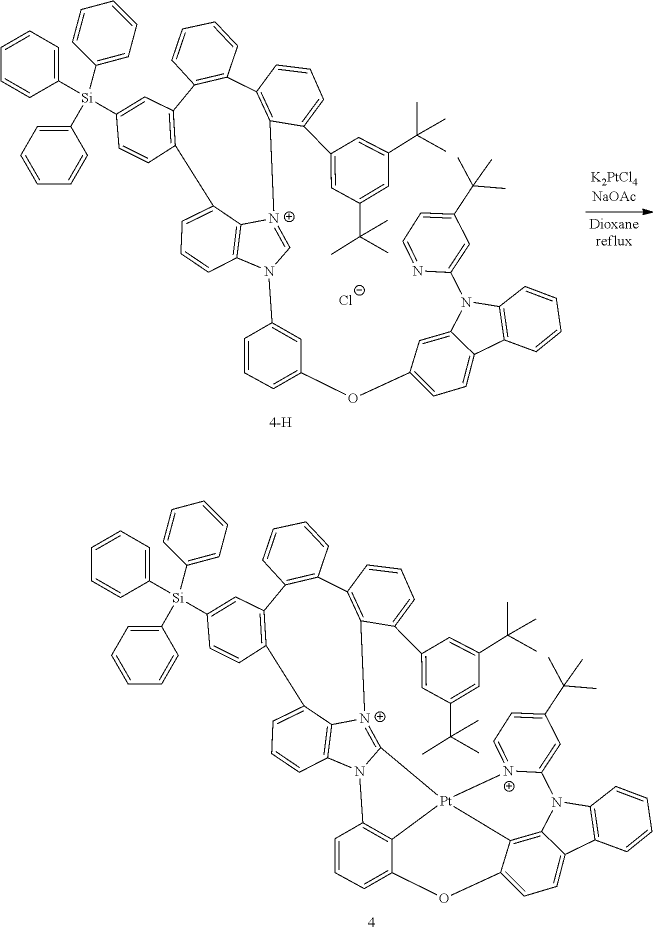

Compound 4-H (8.2 g, 6.73 mmol), K₂PtCl₄ (3.07 g, 7.41 mmol), and NaOAc (1.66 g, 20.2 mmol) were added into a round-bottom flask and mixed with dioxane (140 mL). The mixture was stirred at 100° C. for 12 hours. After 12 hours, the mixture was allowed to cool to room temperature, and then, ethyl acetate and a saturated aqueous ammonium chloride solution were added to the reaction mixture. The organic layer was extracted using ethyl acetate, dried using anhydrous MgSO₄, and then filtered. The filtrate was concentrated and purified by silica gel column chromatography to provide 1.94 g (yield of 21%) of Compound 4.

LC-Mass (calculated: 1373.50 g/mol, found: M⁺¹=1374 g/mol).

### Synthesis Example 5 (Synthesis of Compound 5)

### Synthesis of Compound 5-C

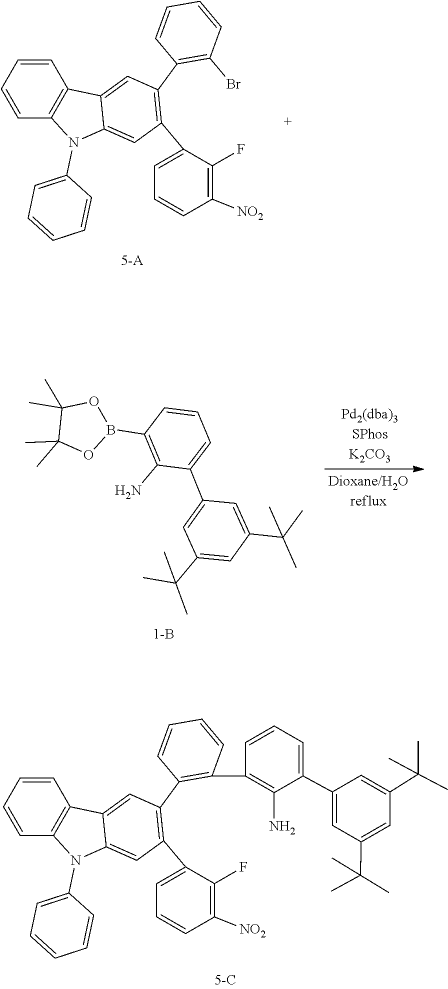 [SMILES: O=[N+]([O-])c1cccc(-c2cc3c(cc2-c2ccccc2Br)c2ccccc2n3-c2ccccc2)c1F ; CC(C)(C)c1cc(-c2cccc(B3OC(C)(C)C(C)(C)O3)c2N)cc(C(C)(C)C)c1 ; CC(C)(C)c1cc(-c2cccc(-c3ccccc3-c3cc4c5ccccc5n(-c5ccccc5)c4cc3-c3cccc([N+](=O)[O-])c3F)c2N)cc(C(C)(C)C)c1]

Compound 5-C was obtained in the same manner as in the synthesis of Compound 1-C of Synthesis Example 1, except that Compound 5-A was used instead of Compound 1-A.

### Synthesis of Compound 5-D

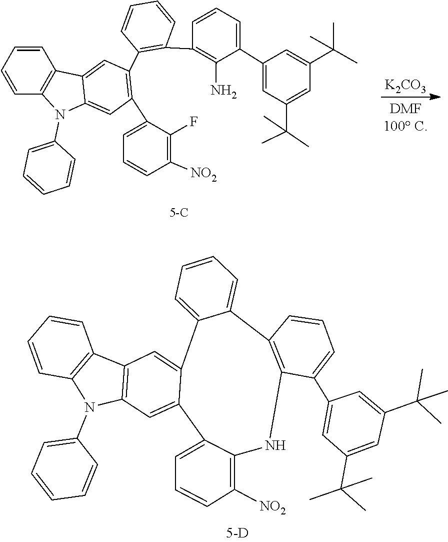

Compound 5-D was obtained in the same manner as in the synthesis of Compound 1-D of Synthesis Example 1, except that Compound 5-C was used instead of Compound 1-C.

### Synthesis of Compound 5-E

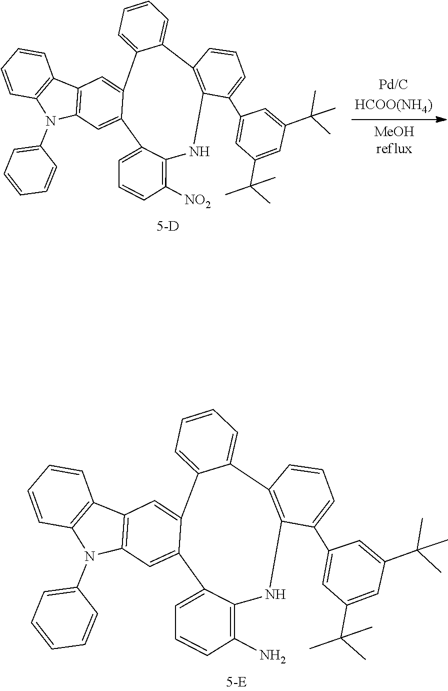 [SMILES: CC(C)(C)c1cc(-c2cccc3c2[nH]c2c([N+](=O)[O-])cccc2c2cc4c(cc2c2ccccc32)c2ccccc2n4-c2ccccc2)cc(C(C)(C)C)c1 ; CC(C)(C)c1cc(-c2cccc3c2[nH]c2c(N)cccc2c2cc4c(cc2c2ccccc32)c2ccccc2n4-c2ccccc2)cc(C(C)(C)C)c1]

Compound 5-E was obtained in the same manner as in the synthesis of Compound 1-E of Synthesis Example 1, except that Compound 5-D was used instead of Compound 1-D.

### Synthesis of Compound 5-G

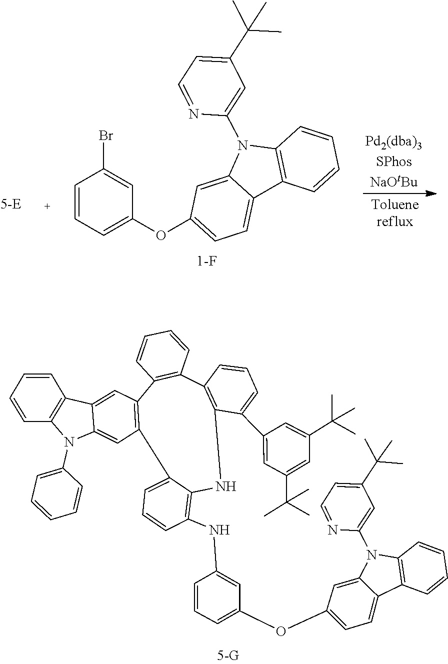 [SMILES: CC(C)(C)c1ccnc(-n2c3ccccc3c3ccc(Oc4cccc(Br)c4)cc32)c1 ; CC(C)(C)c1cc(-c2cccc3c2[nH]c2c(Nc4cccc(Oc5ccc6c7ccccc7n(-c7cc(C(C)(C)C)ccn7)c6c5)c4)cccc2c2cc4c(cc2c2ccccc32)c2ccccc2n4-c2ccccc2)cc(C(C)(C)C)c1]

Compound 5-G was obtained in the same manner as in the synthesis of Compound 1-G of Synthesis Example 1, except that Compound 5-E was used instead of Compound 1-E.

### Synthesis of Compound 5-H

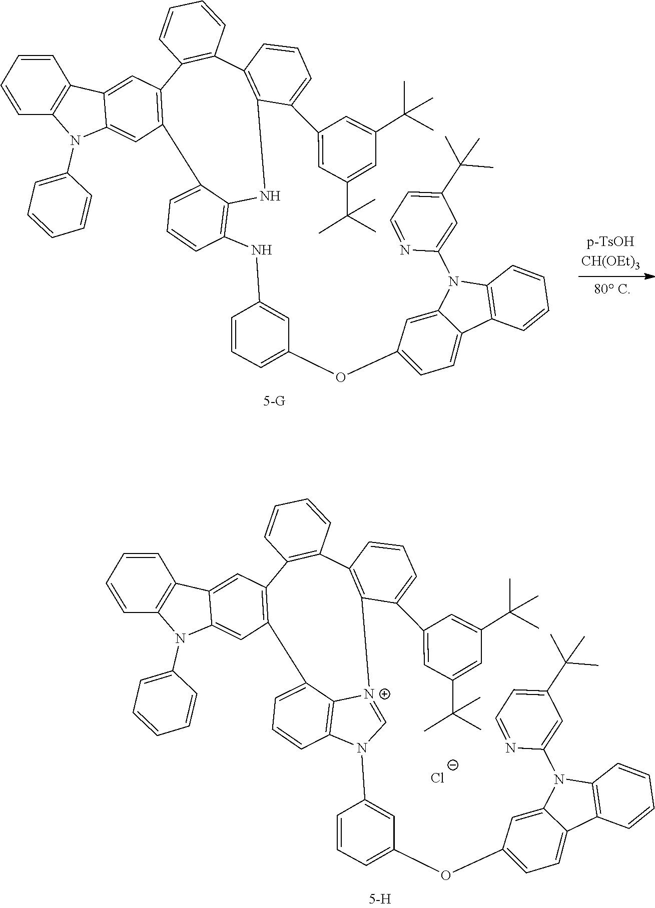 [SMILES: CC(C)(C)c1cc(-c2cccc3c2[nH]c2c(Nc4cccc(Oc5ccc6c7ccccc7n(-c7cc(C(C)(C)C)ccn7)c6c5)c4)cccc2c2cc4c(cc2c2ccccc32)c2ccccc2n4-c2ccccc2)cc(C(C)(C)C)c1 ; CC(C)(C)c1cc(-c2cccc3c2-[n+]2cn(-c4cccc(Oc5ccc6c7ccccc7n(-c7cc(C(C)(C)C)ccn7)c6c5)c4)c4cccc(c42)-c2cc4c(cc2-c2ccccc2-3)c2ccccc2n4-c2ccccc2)cc(C(C)(C)C)c1 ; [Cl-]]

Compound 5-H was obtained in the same manner as in the synthesis of Compound 1-H of Synthesis Example 1, except that Compound 5-G was used instead of Compound 1-G.

### Synthesis of Compound 5

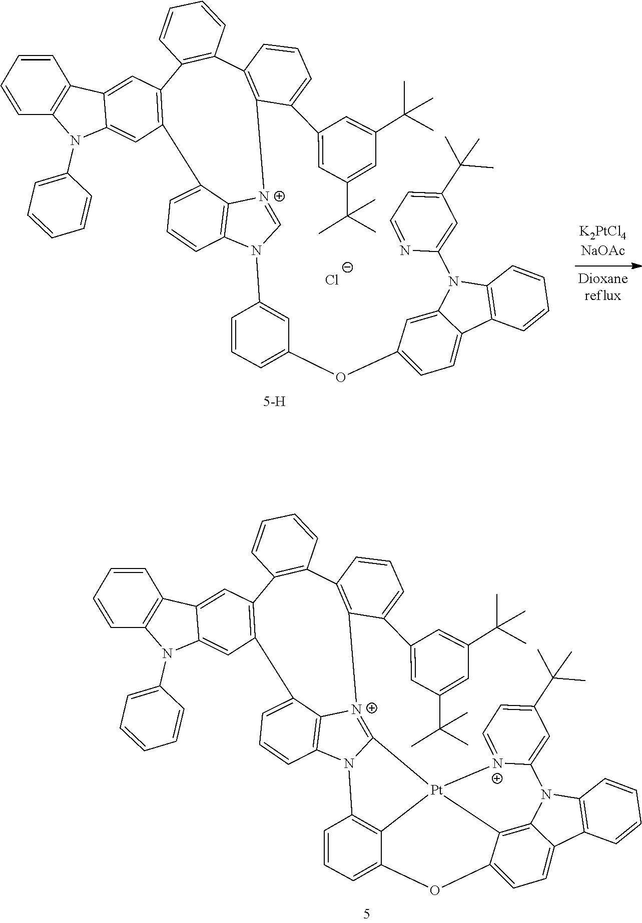

Compound 5-H (7.8 g, 6.93 mmol), K₂PtCl₄ (3.17 g, 7.63 mmol), and NaOAc (1.71 g, 20.8 mmol) were added into a round-bottom flask and mixed with dioxane (160 mL). The mixture was stirred at 100° C. for 12 hours. After 12 hours, the mixture was allowed to cool to room temperature, and then, ethyl acetate and a saturated aqueous ammonium chloride solution were added to the reaction mixture. The organic layer was extracted using ethyl acetate, dried using anhydrous MgSO₄, and then filtered. The filtrate was concentrated and purified by silica gel column chromatography to provide 2.04 g (yield of 23%) of Compound 5.

LC-Mass (calculated: 1280.47 g/mol, found: M⁺¹=1281 g/mol).

Synthesis methods of other compounds in addition to the compounds synthesized in Synthesis Examples 1 to 5 may be easily recognized by those skilled in the art by referring to the synthesis paths and source materials.

### Evaluation Example 1

With respect to the compounds synthesized in Synthesis Examples 1 to 5 and each of Comparative Compounds CE1 to CE5, as defined in Conditions 1 and 2, atoms Y₁, Y₂, and Y₃ were selected, and the results thereof are provided in the specification. Then, for the molecular structure of each of the compounds, the sizes of interior angles of an imaginary triangle including atoms Y₁, Y₂, and Y₃ as vertexes (<Y₁Y₂Y₃, <Y₂Y₃Y₁, <Y₃Y₁Y₂) and the lengths of sides (distance between Y₁ and Y₂, distance between Y₂ and Y₃, and distance between Y₃ and Y₁) were calculated by density functional theory (DFT) B3LYP, and the results thereof are shown in Table 1.

TABLE 1

| | | | | Length of sides | | | | |
|---|---|---|---|---|---|---|---|---|
| | | | | of imaginary triangle | | | Minimum | Minimum |
| | Size of interior angles | | | Distance | Distance | Distance | value of | value of |
| | of imaginary triangle | | | between | between | between | interior | side |
| | <Y₁Y₂Y₃ | <Y₂Y₃Y₁ | <Y₃Y₁Y₂ | Y₁ and Y₂ | Y₂ and Y₃ | Y₃ and Y₁ | angles | lengths |
| Compound | (°) | (°) | (°) | (Å) | (Å) | (Å) | (°) | (Å) |
| 1 | 36 | 35 | 109 | 11.3 | 18.6 | 11.6 | 35 | 11.3 |
| 2 | 61 | 33 | 86 | 8.5 | 15.5 | 13.6 | 33 | 8.5 |
| 3 | 51 | 36 | 93 | 10.9 | 18.5 | 14.4 | 36 | 10.9 |
| 4 | 31 | 29 | 120 | 11.3 | 20.2 | 12.1 | 29 | 11.3 |
| 5 | 35 | 37 | 108 | 11.3 | 18.0 | 10.9 | 35 | 10.9 |
| CE1 | 40 | 78 | 62 | 12.6 | 11.5 | 8.2 | 40 | 8.2 |
| CE2 | 44 | 39 | 97 | 10.7 | 17.0 | 11.9 | 39 | 10.7 |
| CE3 | 55 | 42 | 83 | 10.6 | 15.8 | 13.0 | 42 | 10.6 |
| CE4 | 39 | 80 | 61 | 12.7 | 11.4 | 8.2 | 39 | 8.2 |
| CE5 | 47 | 40 | 93 | 9.9 | 15.4 | 11.3 | 40 | 9.9 |

As shown in Table 1, Compounds 1 to 5 according to Synthesis Examples 1 to 5 satisfy Conditions 1 and 2, and Comparative Compounds 1 to 5 satisfy Condition 2 but do not satisfy Condition 1.

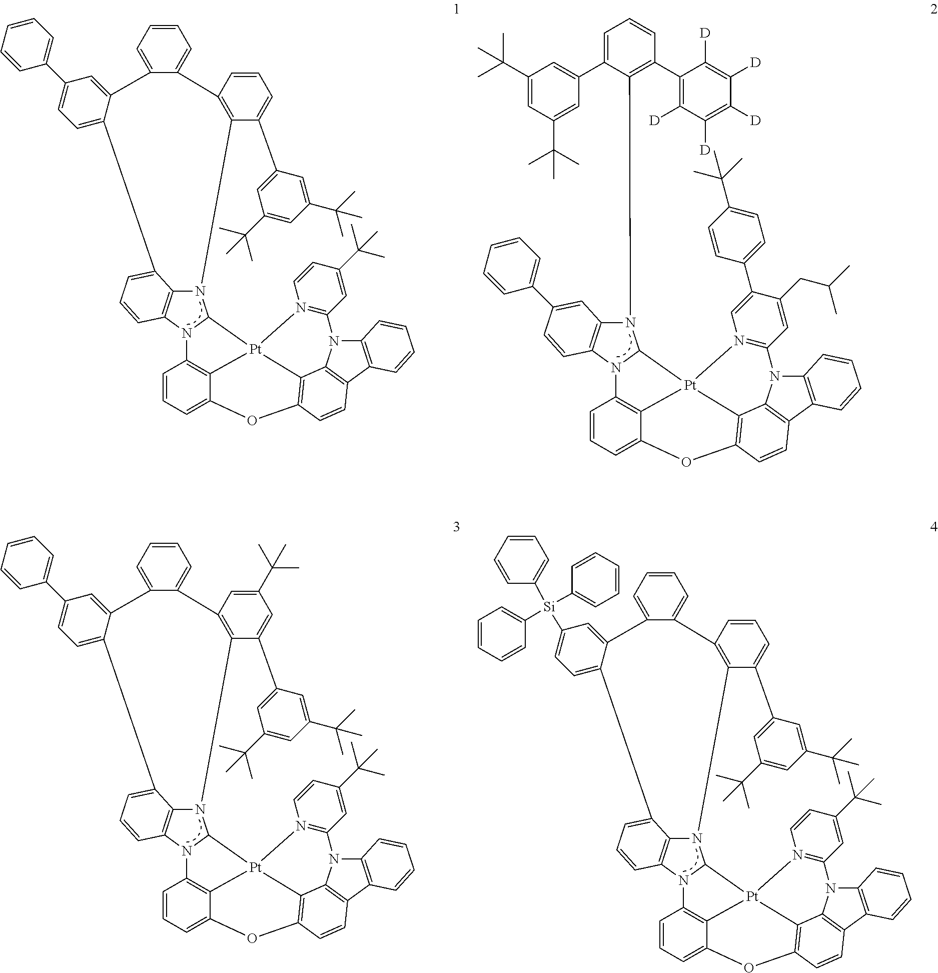

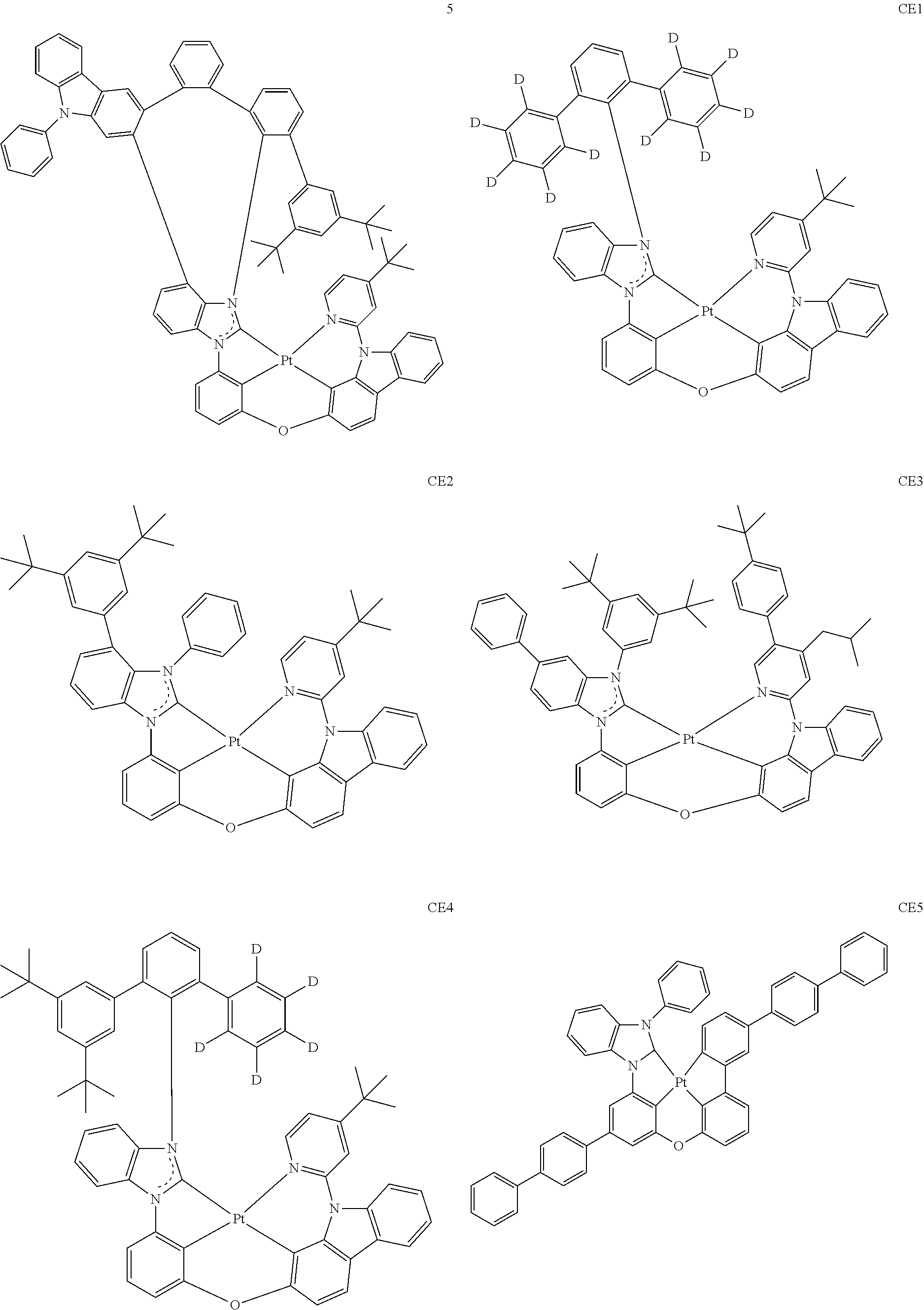

### Example A1

A glass substrate with a 1500 Å-thick indium tin oxide (ITO) electrode (first electrode, anode) thereon was cleaned by distilled water ultrasonication. After the completion of ultrasonication using distilled water, cleaning by ultrasonication using a solvent, such as isopropyl alcohol, acetone, and methanol, was performed, and the glass substrate was dried and transferred to a plasma cleaner. The glass substrate was cleaned by using oxygen plasma for 5 minutes, and then transferred to a vacuum laminator.

Compound HT1 and Compound HT-D2 were co-deposited on an ITO electrode of the glass substrate to form a hole injection layer having a thickness of 100 Å. Compound HT3 was deposited on the hole injection layer to form a hole transport layer having a thickness of 1,300 Å.

A first compound, a second compound, and an organometallic compound (weight ratio of first compound:second compound:organometallic compound is 30:57:13) were co-deposited on the hole transport layer to form an emission layer having a thickness of 400 Å. E1, H1, and Compound 1 were used as the first compound, the second compound, and the organometallic compound (emitter), respectively.

BCP was vacuum-deposited on the emission layer to form a hole blocking layer having a thickness of 100 Å. Compound ET27 and Liq were vacuum-deposited together on the hole blocking layer to form an electron transport layer having a thickness of 300 Å. Liq was deposited on the electron transport layer to form an electron injection layer having a thickness of 10 Å, and an A1 second electrode (cathode) was formed on the electron injection layer to have a thickness of 1,200 Å, thereby completing the manufacture of a light-emitting device.

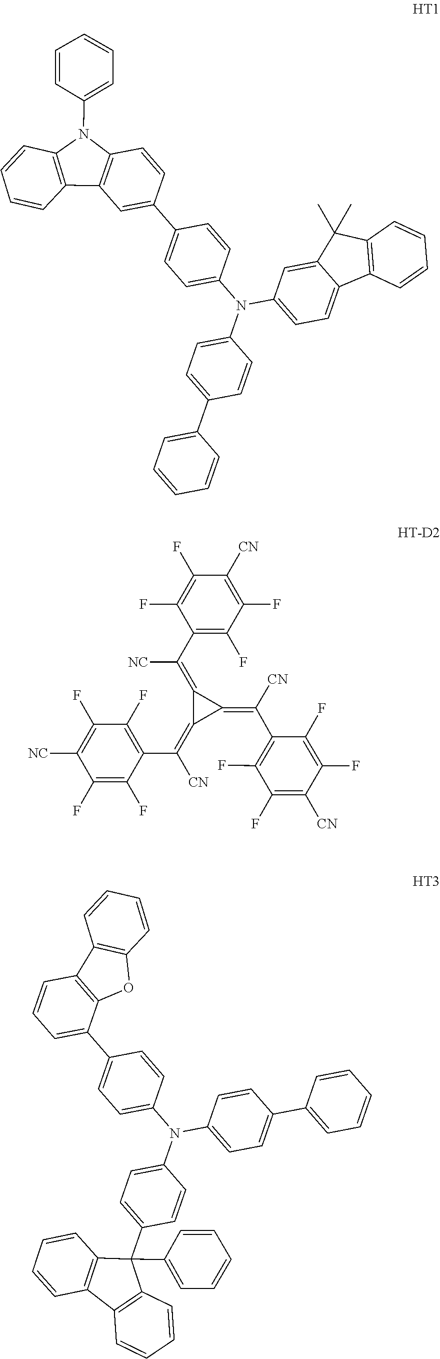 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(N(c3ccc(-c4cccc5c4oc4ccccc45)cc3)c3ccc(C4(c5ccccc5)c5ccccc5-c5ccccc54)cc3)cc2)cc1]

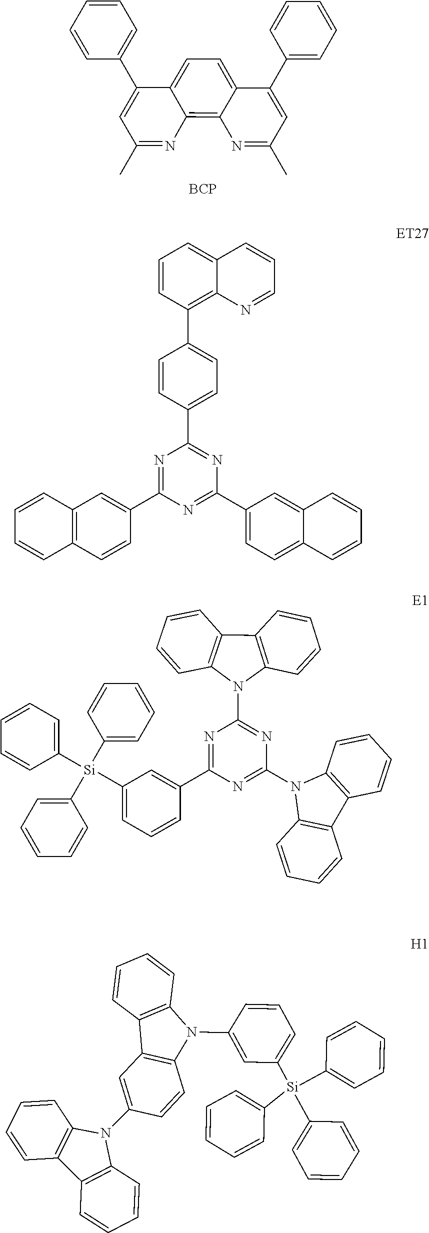

### Examples A2 to A5 and Comparative Examples A1 to A5

Light-emitting devices were manufactured in the same manner as in Example A1, except that, in forming an emission layer, the compounds shown in Table 3 were each used instead of Compound 1.

### Evaluation Example 2

The capacitance was measured by applying a voltage at an interval of 0.1 volt (V) from −2 V to 6 V to each of the light-emitting devices manufactured in Examples A1 to A5 and Comparative Examples A1 to A5 at 500 Hz using PAIOS equipment of FLUMIX, and the maximum value of the measured capacitance (Cₘₐₓ, nF) was calculated. The relative capacitance maximum value (relative Cₘₐₓ, %) is shown in Table 2 based on the capacitance maximum value of Comparative Example A1 (100%).

For example, the capacitance-voltage curve of the light-emitting device manufactured in each of Example A1 and Comparative Example A1 are shown in FIG. 2. Referring to FIG. 2, the light-emitting device of Example A1 has a hump in a high-voltage region and a reduced capacitance maximum value, compared to the light-emitting device of Comparative Example A1.

TABLE 2

| | | Minimum | Minimum | |
|---|---|---|---|---|
| | | value of | value of | |
| | | interior | side | |
| | Organometallic | angles | lengths | Relative |
| No. | compound | (°) | (Å) | Cₘₐₓ (%) |
| Example A1 | Compound 1 | 35 | 11.3 | 64 |
| Example A2 | Compound 2 | 33 | 8.5 | 97 |
| Example A3 | Compound 3 | 36 | 10.9 | 84 |
| Example A4 | Compound 4 | 29 | 11.3 | 70 |
| Example A5 | Compound 5 | 35 | 10.9 | 86 |
| Comparative | Comparative | 40 | 8.2 | 100 |
| Example A1 | Compound CE1 | | | |
| Comparative | Comparative | 39 | 10.7 | 101 |
| Example A2 | Compound CE2 | | | |
| Comparative | Comparative | 42 | 10.6 | 104 |
| Example A3 | Compound CE3 | | | |
| Comparative | Comparative | 39 | 8.2 | 100 |
| Example A4 | Compound CE4 | | | |
| Comparative | Comparative | 40 | 9.9 | 103 |
| Example A5 | Compound CE5 | | | |

From FIG. 2 and Table 3, it is shown that the light-emitting devices of Examples A1 to A5 employing the organometallic compound satisfying Conditions 1 and 2 described above have a lower capacitance maximum value (Cₘₐₓ) than the light-emitting devices of Comparative Examples A1 to A5 employing a comparative compound which does not satisfy at least one of Conditions 1 and 2. Accordingly, when the organometallic compound satisfying Conditions 1 and 2 is employed, the capacitance characteristics may be improved, and a light-emitting device having improved luminescence characteristics in a low-grayscale region may be manufactured.

### Examples B1 to B5 and Comparative Examples B1 to B5

Light-emitting devices were manufactured in the same manner as in Examples A1 to A5 and Comparative Examples A1 to A5, except that, in forming an emission layer, the first compound, the second compound, the third compound, and the organometallic compound (weight ratio of first compound:second compound:third compound: organometallic compound is 30.2:56:13:0.8) were co-deposited to form an emission layer having a thickness of 400 Å. As the first compound (electron-transporting host), the second compound (hole-transporting host), and the third compound (thermally activated delayed fluorescence material, emitter), Compound E1, Compound H1, and Compound D3 were used respectively, and as the organometallic compound (sensitizer), the compounds shown in Table 3 were each used.

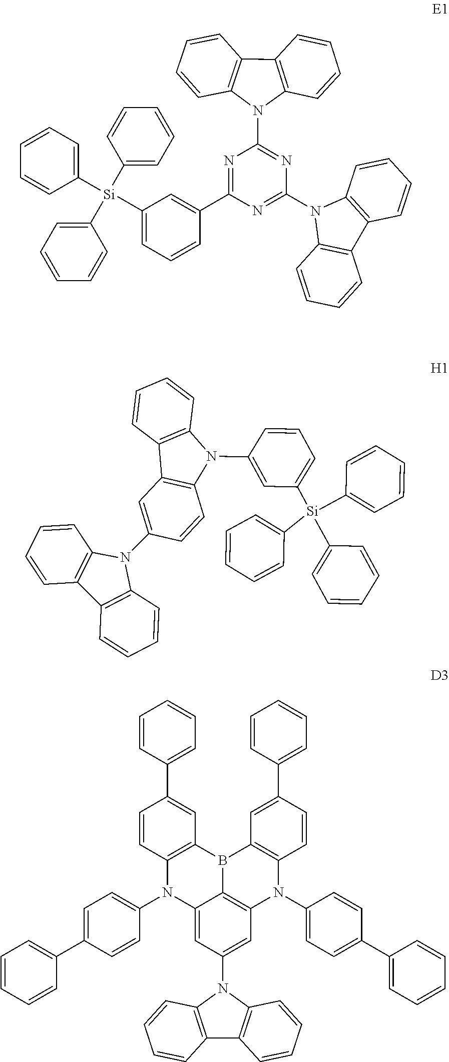 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2cccc(-n3c4ccccc4c4cc(-n5c6ccccc6c6ccccc65)ccc43)c2)cc1 ; c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1]

### Evaluation Example 3

For each of Examples B1 to B5 and Comparative Examples 85 to B5, the capacitance maximum value was measured using the same method as used in Evaluation Example 2, and each capacitance maximum value is shown in a relative value in Table 3 based on the capacitance maximum values of Comparative Example B1 (100%).

TABLE 3

| | | Minimum | Minimum | |
|---|---|---|---|---|
| | | value of | value of | |
| | | interior | side | |
| | Organometallic | angles | lengths | Relative |
| No. | compound | (°) | (Å) | Cₘₐₓ (%) |
| Example B1 | Compound 1 | 35 | 11.3 | 67 |
| Example B2 | Compound 2 | 33 | 8.5 | 93 |
| Example B3 | Compound 3 | 36 | 10.9 | 83 |
| Example B4 | Compound 4 | 29 | 11.3 | 65 |
| Example B5 | Compound 5 | 35 | 10.9 | 85 |
| Comparative | Comparative | 40 | 8.2 | 100 |
| Example B1 | Compound CE1 | | | |
| Comparative | Comparative | 39 | 10.7 | 105 |
| Example B2 | Compound CE2 | | | |
| Comparative | Comparative | 42 | 10.6 | 107 |
| Example B3 | Compound CE3 | | | |
| Comparative | Comparative | 39 | 8.2 | 103 |
| Example B4 | Compound CE4 | | | |
| Comparative | Comparative | 40 | 9.9 | 107 |
| Example B5 | Compound CE5 | | | |

As shown in Table 3, even when both of the organometallic compound and the thermally activated delayed fluorescence material are applied, the light-emitting devices of Examples B1 to B5 employing the organometallic compound satisfying Conditions 1 and 2 described above have a lower capacitance maximum value (Cₘₐₓ) than the light-emitting devices of Comparative Examples B1 to B5 employing a comparative compound which does not satisfy at least one of Conditions 1 and 2. Accordingly, when the organometallic compound satisfying Conditions 1 and 2 is employed, the capacitance characteristics may be improved, and a light-emitting device having improved luminescence characteristics in a low-grayscale region may be manufactured.

The disclosed light-emitting device has improved capacitance characteristics and thus has improved luminescence characteristics, such as prevention or reduction of light leakage in a low-grayscale region and prevention or reduction of color purity degradation, a high-quality electronic apparatus may be manufactured by using the light-emitting device.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A light-emitting device comprising:
a first electrode;
a second electrode facing the first electrode; and
an interlayer arranged between the first electrode and the second electrode and comprising an emission layer,
wherein the interlayer comprises an organometallic compound represented by Formula 1 and satisfying Condition 1 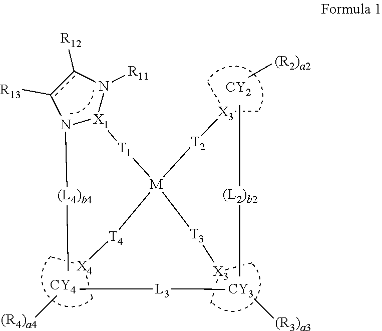
wherein, in Formula 1,
M is platinum, palladium, gold, silver, nickel, or copper,
T₁ to T₄ are each independently a single bond, oxygen, or sulfur,
X₁ to X₄ are each independently carbon or nitrogen,
ring CY₂ to ring CY₄ are each independently a C₅-C₆₀ carbocyclic group or a C₁-C₆₀ heterocyclic group,
L₂ to L₄ are each independently a single bond, O, N(Z₁), or C(Z₁)(Z₂),
b₂ and b₄ are each independently an integer from 0 to 2,
when b₂ is 0, (L₂)_{b2} is not present, and when b₄ is 0, (L₄)_{b4} is not present,
Z₁, Z₂, R₁₁ to R₁₃, and R₂ to R₄ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₅-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
adjacent two of R₁₁ to R₁₃ are optionally bonded to each other to form a C₅-C₆₀ carbocyclic group or a C₁-C₆₀ heterocyclic group,
a2 to a4 are each independently an integer from 1 to 30,
a group represented by [symbol] is a single bond or a double bond,
R₁₀ₐ is deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof,
Condition 1
a minimum value of interior angles of an imaginary triangle including three atoms Y₁ to Y₃ as vertexes in the organometallic compound is less than 39°,
wherein, in Formula 1 and Condition 1,
a plane including 3 atoms, excluding an atom farthest from M among 4 atoms of i) T₁ or X₁ when T₁ is a single bond, ii) T₂ or X₂ when T₂ is a single bond, iii) T₃ or X₃ when T₃ is a single bond, and iv) T₄ or X₄ when T₄ is a single bond is defined as a first plane,
the first plane includes an x axis, which is an imaginary straight line including M and L₃, and a y axis, which is an imaginary straight line including M and perpendicular to the x axis, wherein the x axis includes a positive direction directed from M towards L₃ and a negative direction directed from L₃ towards M,
an atom farthest from the first plane is defined as Y₁,
among atoms included in a moiety represented by 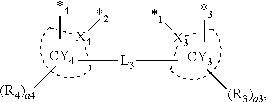
an atom farthest from the y axis in the positive direction of the x axis is defined as Y₂,
an atom farthest from the y axis in the negative direction of the x axis is defined as Y₃,
*₁ indicates a binding site to T₃ in Formula 1,
*₂ indicates a binding site to T₄ in Formula 1,
*₃ indicates a binding site to (L₂)_{b2} in Formula 1, and
*₄ indicates a binding site to (L₄)_{b4} in Formula 1.

2. The light-emitting device of claim 1, wherein the emission layer comprises the organometallic compound.

3. The light-emitting device of claim 1, wherein the emission layer emits blue light.

4. The light-emitting device of claim 1, wherein the interlayer further comprises a first compound comprising an azine group with at least one nitrogen atom.

5. The light-emitting device of claim 1, wherein the interlayer further comprises a second compound comprising at least one carbazole group.

6. The light-emitting device of claim 5, wherein an energy level of a lowest triplet excited state of the second compound is 2.8 electronvolts or greater.

7. The light-emitting device of claim 1, wherein the interlayer further comprises a third compound comprising a polycyclic group in which at least 3 single rings are condensed.

8. The light-emitting device of claim 7, wherein an energy difference between a lowest singlet excited state and a lowest triplet excited state of the third compound is less than 0.3 electronvolts.

9. An electronic apparatus comprising the light-emitting device of claim 1.

10. An organometallic compound represented by Formula 1 and satisfying Condition 1: 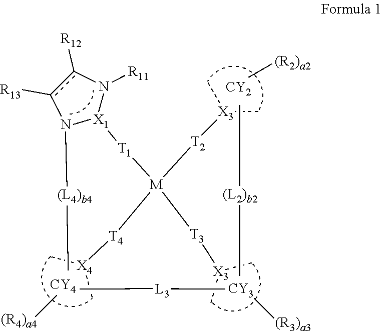
wherein, in Formula 1,
M is platinum), palladium, gold, silver, nickel, or copper,
T₁ to T₄ are each independently a single bond, oxygen, or sulfur,
X₁ to X₄ are each independently carbon or nitrogen,
ring CY₂ to ring CY₄ are each independently a C₅-C₆₀ carbocyclic group or a C₁-C₆₀ heterocyclic group,
L₂ to L₄ are each independently a single bond, O, N(Z₁), or C(Z₁)(Z₂),
b₂ and b₄ are each independently an integer from 0 to 2,
when b₂ is 0, (L₂)_{b2} is not present, and when b₄ is 0, (L₄)_{b4} is not present,
Z₁, Z₂, R₁₁ to R₁₃, and R₂ to R₄ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₅-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
adjacent two of R₁₁ to R₁₃ are optionally bonded to each other to form a C₅-C₆₀ carbocyclic group or a C₁-C₆₀ heterocyclic group,
a2 to a4 are each independently an integer from 1 to 30,
a group represented by [symbol] is a single bond or a double bond,
R₁₀ₐ is deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof,
Condition 1
a minimum value of interior angles of an imaginary triangle including three atoms Y₁ to Y₃ as vertexes in the organometallic compound is less than 39°,
wherein, in Formula 1 and Condition 1,
a plane including 3 atoms, excluding an atom farthest from M among 4 atoms of i) T₁ or X₁ when T₁ is a single bond, ii) T₂ or X₂ when T₂ is a single bond, iii) T₃ or X₃ when T₃ is a single bond, and iv) T₄ or X₄ when T₄ is a single bond is defined as a first plane,
the first plane includes an x axis, which is an imaginary straight line including M and L₃, and a y axis, which is an imaginary straight line including M and perpendicular to the x axis, wherein the x axis includes a positive direction directed from M towards L₃ and a negative direction directed from L₃ towards M,
an atom farthest from the first plane is defined as Y₁,
among atoms included in a moiety represented by 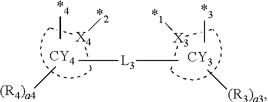
an atom farthest from the y axis in the positive direction of the x axis is defined as Y₂,
an atom farthest from the y axis in the negative direction of the x axis is defined as Y₃,
*₁ indicates a binding site to T₃ in Formula 1,
*₂ indicates a binding site to T₄ in Formula 1,
*₃ indicates a binding site to (L₂)_{b2} in Formula 1, and
*₄ indicates a binding site to (L₄)_{b4} in Formula 1.

11. The organometallic compound of claim 10, wherein the minimum value of the interior angles of the imaginary triangle including three atoms Y₁ to Y₃ as vertexes in the organometallic compound is less than 37°.

12. The organometallic compound of claim 10, wherein the organometallic compound further satisfies Condition 2:
Condition 2
a minimum value of side lengths of the imaginary triangle including three atoms Y₁ to Y₃ as vertexes in the organometallic compound is 8 angstroms or greater, and
in Condition 2, atoms Y₁ to Y₃ are as defined in Condition 1.

13. The organometallic compound of claim 10, wherein a minimum value of side lengths of the imaginary triangle including three atoms Y₁ to Y₃ as vertexes in the organometallic compound is 8.5 angstroms or greater.

14. The organometallic compound of claim 10, wherein a distance between Y₁ and Y₂ or a distance between Y₁ and Y₃ has a minimum value of the side lengths of the imaginary triangle.

15. The organometallic compound of claim 10, wherein <Y₁Y₂Y₃ or <Y₂Y₃Y₁ has a minimum value of the interior angles of the imaginary triangle.

16. The organometallic compound of claim 10, wherein M in Formula 1 is platinum.

17. The organometallic compound of claim 10, wherein Y₁ to Y₃ are each independently hydrogen or deuterium.

18. The organometallic compound of claim 10, wherein a group represented by 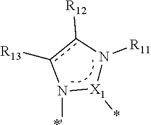
in Formula 1 is a group represented by any one of Formulae CY1-1 to CY1-4: 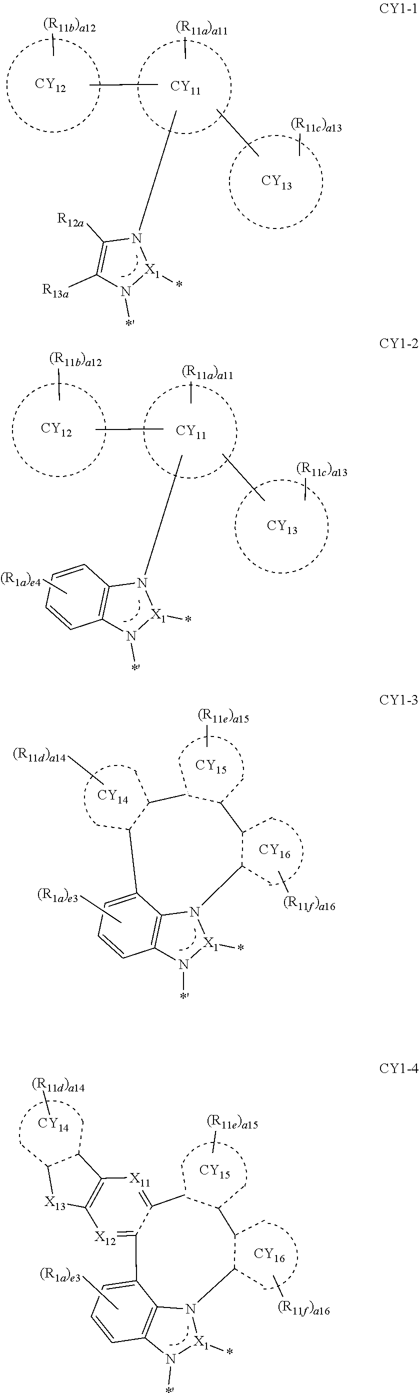
wherein, in Formulae CY1-1 to CY1-4,
X₁ is as described in connection with Formula 1,
X₁₁ is N, C(H), C(D), or C(E₁₁),
X₁₂ is N, C(H), C(D), or C(E₁₂),
X₁₃ is O, S, N(E₁₃), or C(E₁₃)(E₁₄),
D is deuterium,
R₁ₐ, R₁₁ₐ, and R_{11f} are each as described in connection with R₁₀ₐ,
R₁₂ₐ is as described in connection with R₁₂,
R₁₃ₐ is as described in connection with R₁₃,
R_{11b}, R_{11c}, R_{11d}, R₁₁ₑ, and E₁₁ to E₁₄ are each independently deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), or —P(═O)(Q₂₁)(Q₂₂),
R₁ₐ, R₁₁ₐ to R_{11f}, R₁₂ₐ, and R₁₃ₐ are not bonded to each other,
ring CY₁₁ to ring CY₁₆ are each independently a C₅-C₁₀ mono-carbocyclic group or a C₁-C₁₀ mono-heterocyclic group,
e3 is an integer from 0 to 3,
e4 is an integer from 0 to 4,
a11 to a16 are each independently an integer from 0 to 5, and
* indicates to a binding site to T₁ in Formula 1, and *′ indicates a binding site to (L₄)_{b4} in Formula 1.

19. The organometallic compound of claim 10, wherein the organometallic compound includes:
a substituted or unsubstituted terphenyl group;
a substituted or unsubstituted 9-membered ring; or
any combination thereof, and
a substituent of each of the substituted 9-membered ring and the substituted terphenyl group includes
deuterium (—D), a C₁-C₆₀ alkyl group, a phenyl group, or a triphenylsilyl group; or
a C₁-C₆₀ alkyl group or a phenyl group, each substituted with deuterium, a C₁-C₆₀ alkyl group, a phenyl group, a triphenylsilyl group, or any combination thereof.

20. The organometallic compound of claim 10, wherein the organometallic compound emits blue light.
